(19) United States
(12) Patent Application Publication
(10) Pub. No.: US 2025/0349376 A1
(43) Pub. Date: Nov. 13, 2025

(54) SHIFT REGISTER

(71) Applicant: Semiconductor Energy Laboratory Co., Ltd., Atsugi-shi, Kanagawa-ken (JP)

(72) Inventors: Koji KUSUNOKI, Isehara (JP); Susumu KAWASHIMA, Atsugi (JP); Hideaki SHISHIDO, Atsugi (JP); Tomoaki ATSUMI, Hadano (JP); Motoharu SAITO, Atsugi (JP); Hironori MATSUMOTO, Tochigi (JP); Manabu SATO, Oyama (JP)

(21) Appl. No.: 19/100,726

(22) PCT Filed: Jul. 28, 2023
(86) PCT No.: PCT/IB2023/057662

§ 371 Date: Feb. 3, 2025

(30) Foreign Application Priority Data
Aug. 10, 2022 (JP) 2022-127806
Sep. 13, 2022 (JP) 2022-145287
Nov. 11, 2022 (JP) 2022-181214

(51) Int. Cl. G11C 19/28

(52) U.S. Cl. CPC G11C 19/28

(57) ABSTRACT

A novel signal output circuit is provided. A shift register includes a signal output circuit including a vertical-channel transistor. With the use of a gate-source parasitic capacitance or a gate-drain parasitic capacitance, whichever has a larger capacitance value, of the vertical-channel transistor as a bootstrap capacitor, the signal output circuit that occupies a small area can be obtained. With the use of an oxide semiconductor for a semiconductor layer of the vertical-channel transistor, the withstand voltage between the source and the drain can be increased, so that the channel length can be decreased. In addition, stable operation can be performed even in a high-temperature environment.

### TECHNICAL FIELD

One embodiment of the invention disclosed in this specification and the like relates to an object, a method, or a manufacturing method. Alternatively, one embodiment of the invention disclosed in this specification and the like relates to a process, a machine, manufacture, or a composition of matter.

One embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also refers to all devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, an electronic device, and the like themselves are semiconductor devices and also include a semiconductor device.

### BACKGROUND ART

In recent years, demand for an integrated circuit in which transistors and the like are integrated with high density has risen with reductions in the size and weight of an electronic device. As a means of integrating transistors with high density, miniaturization of a transistor and a reduction in the area occupied thereby have been underway.

As a semiconductor material that can be used in a transistor, an oxide semiconductor using a metal oxide has been attracting attention. For example, Patent Document 1 discloses a semiconductor device whose field-effect mobility (simply referred to as mobility or uFE in some cases) is increased by stacking a plurality of oxide semiconductor layers, among which the oxide semiconductor layer serving as a channel contains indium and gallium such that the proportion of indium is higher than the proportion of gallium.

### REFERENCE

### [Patent Document]

[Patent Document 1] Japanese Published Patent Application No. 2014-7399

### SUMMARY OF THE INVENTION

### Problems to be Solved by the Invention

An object of one embodiment of the present invention is to provide a semiconductor device that occupies a small area. Another object is to provide a semiconductor device with low power consumption. Another object is to provide a semiconductor device with high reliability. Another object is to provide a novel semiconductor device.

Note that the description of these objects does not preclude the existence of other objects. Note that one embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a shift register including a plurality of signal output circuits and a first transistor in at least one of the plurality of signal output circuits. The at least one of the plurality of signal output circuits has a function of outputting a first signal through the first transistor. The shift register includes a first conductive layer including a region functioning as one of a source electrode and a drain electrode of the first transistor; a first insulating layer including a region positioned over the first conductive layer; a second conductive layer including a region functioning as the other of the source electrode and the drain electrode of the first transistor and including a region positioned over the first insulating layer; a first opening penetrating the first insulating layer and the second conductive layer and overlapping with the first conductive layer; a first semiconductor layer including a region in contact with the first insulating layer, including a region in contact with the first conductive layer, and including a region in contact with the second conductive layer; a third conductive layer including a region functioning as a gate electrode of the first transistor; and a second insulating layer including a region functioning as a gate insulating film of the first transistor and including a region sandwiched between the first semiconductor layer and the third conductive layer in the first opening. The first signal is input to the one of the source electrode and the drain electrode of the first transistor.

For example, the third conductive layer includes a region overlapping with the first conductive layer in the first opening and a region overlapping with the second conductive layer over the first insulating layer.

A second transistor may be included in the at least one of the plurality of signal output circuits. For example, the shift register may include a fourth conductive layer including a region functioning as one of a source electrode and a drain electrode of the second transistor; the first insulating layer including a region positioned over the fourth conductive layer; a fifth conductive layer including a region functioning as the other of the source electrode and the drain electrode of the first transistor and including a region positioned over the first insulating layer; a second opening penetrating the first insulating layer and the fifth conductive layer and overlapping with the fourth conductive layer; a second semiconductor layer including a region in contact with the first insulating layer, including a region in contact with the fourth conductive layer, and including a region in contact with the fifth conductive layer; a sixth conductive layer including a region functioning as a gate electrode of the second transistor and including a region positioned over the second insulating layer; and the second insulating layer including a region functioning as a gate insulating film of the second transistor and including a region sandwiched between the second semiconductor layer and the sixth conductive layer in the second opening. The fourth conductive layer and the third conductive layer are preferably electrically connected to each other.

A top surface of the fourth conductive layer and a bottom surface of the sixth conductive layer may be at different levels with respect to a bottom surface of the fourth conductive layer. The first semiconductor layer preferably includes an oxide semiconductor. The second semiconductor layer preferably includes an oxide semiconductor.

### Effect of the Invention

According to one embodiment of the present invention, a semiconductor device that occupies a small area can be provided. Alternatively, a semiconductor device with low power consumption can be provided. Alternatively, a semiconductor device with high reliability can be provided. Alternatively, a novel semiconductor device can be provided.

Note that the description of these effects does not preclude the existence of other effects. Note that one embodiment of the present invention does not need to have all of these effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A is a diagram illustrating an example of a shift register. FIG. 1B and FIG. 1C are diagrams illustrating examples of signal output circuits.

FIG. 2 is a diagram illustrating an example of a signal output circuit.

FIG. 3 is a diagram illustrating an example of a signal output circuit.

FIG. 4 is a diagram illustrating an example of a signal output circuit.

FIG. 5 is a diagram illustrating an example of a signal output circuit.

FIG. 6 is a diagram illustrating an example of a signal output circuit.

FIG. 7 is a diagram illustrating an example of a signal output circuit.

FIG. 8 is a diagram illustrating an example of a signal output circuit.

FIG. 9 is a diagram illustrating an example of a signal output circuit.

FIG. 10 is a diagram illustrating an example of a signal output circuit.

FIG. 11A is a plan view of a transistor. FIG. 11B is a cross-sectional view of the transistor. FIG. 11C is a perspective view of the transistor. FIG. 11D is an equivalent circuit diagram of the transistor.

FIG. 12A and FIG. 12B are cross-sectional views of the transistor. FIG. 12C to FIG. 12F are plan views of openings.

FIG. 13A and FIG. 13B are plan views of the transistor.

FIG. 14A is a cross-sectional view of a transistor. FIG. 14B is an equivalent circuit diagram of the transistor.

FIG. 15A is a plan view of a transistor. FIG. 15B is a cross-sectional view of the transistor. FIG. 15C is a perspective view of the transistor. FIG. 15D is an equivalent circuit diagram of the transistor.

FIG. 16A is a plan view of a transistor. FIG. 16B is a cross-sectional view of the transistor. FIG. 16C is a perspective view of the transistor. FIG. 16D is an equivalent circuit diagram of the transistor.

FIG. 17 is a plan view of a signal output circuit.

FIG. 18 is a plan view of the signal output circuit.

FIG. 19A and FIG. 19B are cross-sectional views of the signal output circuit.

FIG. 20A and FIG. 20B are cross-sectional views of the signal output circuit.

FIG. 21A and FIG. 21B are cross-sectional views of the signal output circuit.

FIG. 22 is a diagram illustrating an example of a signal output circuit.

FIG. 23 is a timing chart for explaining an example of operation of a signal output circuit.

FIG. 24 is a circuit diagram for explaining the example of operation of the signal output circuit.

FIG. 25 is a circuit diagram for explaining the example of operation of the signal output circuit.

FIG. 26 is a circuit diagram for explaining the example of operation of the signal output circuit.

FIG. 27 is a circuit diagram for explaining the example of operation of the signal output circuit.

FIG. 28 is a circuit diagram for explaining the example of operation of the signal output circuit.

FIG. 29 is a circuit diagram for explaining the example of operation of the signal output circuit.

FIG. 30 is a circuit diagram for explaining the example of operation of the signal output circuit.

FIG. 31 is a diagram illustrating an example of a signal output circuit.

FIG. 32 is a diagram illustrating an example of a signal output circuit.

FIG. 33 is a timing chart for explaining an example of operation of a shift register.

FIG. 34A is a perspective view of a display device. FIG. 34B is a block diagram of the display device.

FIG. 35A to FIG. 35D are circuit diagrams of pixel circuits.

FIG. 36A to FIG. 36D are circuit diagrams of pixel circuits.

FIG. 37A and FIG. 37B are circuit diagrams of pixel circuits.

FIG. 38A and FIG. 38B are circuit diagrams of pixel circuits.

FIG. 39A and FIG. 39B are diagrams illustrating structural examples of driver circuits.

FIG. 40A to FIG. 40G are diagrams illustrating examples of pixels.

FIG. 41A to FIG. 41K are diagrams illustrating examples of pixels.

FIG. 42A to FIG. 42F are diagrams illustrating structural examples of light-emitting devices.

FIG. 43A to FIG. 43C are diagrams illustrating structural examples of light-emitting devices.

FIG. 44A to FIG. 44D are diagrams illustrating structural examples of light-emitting elements.

FIG. 45A to FIG. 45D are diagrams illustrating structural examples of light-emitting elements.

FIG. 46A to FIG. 46C are diagrams illustrating structural examples of light-emitting elements.

FIG. 47A to FIG. 47F are diagrams illustrating examples of electronic devices.

FIG. 48A to FIG. 48F are diagrams illustrating examples of electronic devices.

FIG. 49A1 and FIG. 49A2 are schematic cross-sectional views of a transistor. FIG. 49B1 and FIG. 49B2 are diagrams showing Id-Vg characteristics of the transistor. FIG. 49C1 and FIG. 49C2 are diagrams showing Id-Vd characteristics of the transistor.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments. Note that in the structures of the invention described below, the same portions or portions having similar functions are denoted by the same reference numerals in different drawings, and repeated description thereof is omitted in some cases.

The position, size, range, and the like of each component illustrated in drawings and the like do not represent the actual position, size, range, and the like in some cases for easy understanding of the invention. Therefore, the disclosed invention is not necessarily limited to the position, size, range, and the like disclosed in the drawings and the like. For example, in the actual manufacturing process, a layer, a resist mask, and the like might be unintentionally reduced in size by treatment such as etching, which is not illustrated in some cases for easy understanding of the invention.

In this specification and the like, in the case where an etching step (a removal step) is performed after a resist mask is formed by a photolithography method, the resist mask is removed after the etching step, unless otherwise specified.

Furthermore, especially in a plan view (also referred to as a “top view”), a perspective view, and the like, the illustration of some components might be omitted for easy understanding of the invention. The illustration of some hidden lines and the like might also be omitted.

Ordinal numbers such as “first” and “second” in this specification and the like are used in order to avoid confusion among components and do not denote any priority or sequence such as the sequence of steps or the stacking sequence. A term without an ordinal number in this specification and the like may be provided with an ordinal number in the SCOPE OF CLAIMS in order to avoid confusion among components. An ordinal number provided in this specification and the like and an ordinal number provided in the SCOPE OF CLAIMS might be different from each other. Furthermore, even when a term is provided with an ordinal number in this specification and the like, the ordinal number might be omitted in the SCOPE OF CLAIMS and the like.

In this specification and the like, the terms such as “electrode”, “wiring”, and “terminal” do not limit the functions of such components. For example, an “electrode” is used as part of a “wiring” in some cases, and vice versa. Furthermore, the terms “electrode” and “wiring” can also mean that a plurality of “electrodes” and “wirings” are provided in an integrated manner. For example, a “terminal” is used as part of a “wiring” or an “electrode” in some cases, and vice versa. Furthermore, the term “terminal” can also mean that a plurality of “electrodes”, “wirings”, “terminals”, and the like are formed in an integrated manner. Therefore, for example, an “electrode” can be part of a “wiring” or a “terminal”, and a “terminal” can be part of a “wiring” or an “electrode”. Moreover, terms such as “electrode”, “wiring”, and “terminal” can sometimes be replaced with a term such as “region” depending on the case.

In this specification and the like, supply of a signal refers to supply of a predetermined potential to a wiring or the like. The term “signal” can be replaced with a term such as “potential” in some cases. A term such as “potential” can be replaced with the term “signal” in some cases. The “signal” may be a variable potential or a fixed potential. For example, it may be a power supply potential.

Note that the term “film” and the term “layer” can be interchanged with each other depending on the case or circumstances. For example, the term “conductive layer” can be replaced with the term “conductive film” in some cases. As another example, the term “insulating film” can be replaced with the term “insulating layer” in some cases.

In this specification and the like, a “capacitor element” can be, for example, a circuit element having an electrostatic capacitance value greater than 0 F, a region of a wiring having an electrostatic capacitance value greater than 0 F, parasitic capacitance, or gate capacitance of a transistor. The term “capacitor element”, “parasitic capacitance”, or “gate capacitance” can be replaced with the term “capacitor” in some cases. Conversely, the term “capacitor” can be replaced with the term “capacitor element”, “parasitic capacitance”, or “gate capacitance” in some cases. In addition, a “capacitor” (including a “capacitor” with three or more terminals) includes an insulator and a pair of conductive layers between which the insulator is interposed. Thus, the term “pair of conductive layers” of “capacitor” can be replaced with “pair of electrodes”, “pair of conductive regions”, “pair of regions”, or “pair of terminals”. The term “one of a pair of terminals” is referred to as “one terminal” or a “first terminal” in some cases. The term “the other of the pair of terminals” is referred to as “the other terminal” or a “second terminal” in some cases. Note that the electrostatic capacitance value can be greater than or equal to 0.05 fF and less than or equal to 10 pF, for example. As another example, the electrostatic capacitance value may be greater than or equal to 1 pF and less than or equal to 10 μF.

Functions of a “source” and a “drain” of a transistor are sometimes interchanged with each other when a transistor of opposite polarity is used or when the direction of current flow is changed in circuit operation, for example. Therefore, the terms “source” and “drain” can be used interchangeably in this specification and the like.

In this specification and the like, a “gate” refers to part or the whole of a gate electrode and a gate wiring. A gate wiring refers to a wiring for electrically connecting a gate electrode of at least one transistor to another electrode or another wiring.

In this specification and the like, a “source” refers to part or the whole of a source region, a source electrode, and a source wiring. A source region refers to a region in a semiconductor layer where the resistivity is lower than or equal to a given value. A source electrode refers to a conductive layer including part connected to a source region. A source wiring refers to a wiring for electrically connecting a source electrode of at least one transistor to another electrode or another wiring.

In this specification and the like, a “drain” refers to part or the whole of a drain region, a drain electrode, and a drain wiring. A drain region refers to a region in a semiconductor layer where the resistivity is lower than or equal to a given value. A drain electrode refers to a conductive layer including part connected to a drain region. A drain wiring refers to a wiring for electrically connecting a drain electrode of at least one transistor to another electrode or another wiring.

Unless otherwise specified, a transistor described in this specification and the like is an enhancement-mode (a normally-off mode) field-effect transistor. In the case where a transistor in this specification and the like is an n-channel transistor and unless otherwise specified, the threshold voltage (also referred to as “Vth”) of the transistor is higher than 0 V. In the case where the transistor in this specification and the like is a p-channel transistor and unless otherwise specified, the threshold voltage (also referred to as “Vth”) of the transistor is lower than or equal to 0 V. Unless otherwise specified, a plurality of transistors having the same conductivity type all have the same Vth.

Unless otherwise specified, an off-state current in this specification and the like refers to a current flowing between a source and a drain (also referred to as a “drain current” or “Id”) of a transistor in an off state (also referred to as a “non-conduction state” or a “cutoff state”). Unless otherwise specified, the off state of an n-channel transistor refers to a state where the potential difference between its gate and source based on the source (also referred to as a “gate voltage” or “Vg”) is lower than the threshold voltage, and the off state of a p-channel transistor refers to a state where Vg is higher than the threshold voltage. For example, the off-state current of an n-channel transistor sometimes refers to a drain current at the time when Vg is lower than Vth.

In this specification and the like, leakage current sometimes expresses the same meaning as off-state current. Furthermore, in this specification and the like, the off-state current sometimes refers to current that flows between a source and a drain of a transistor in an off state, for example.

Unless otherwise specified, an on-state current in this specification and the like refers to an Id of a transistor in an on state (also referred to as a “conduction state”). Unless otherwise specified, the on state of an n-channel transistor refers to a state where Vg is higher than or equal to Vth, and the on state of a p-channel transistor refers to a state where Vg is lower than or equal to Vth. For example, the on-state current of an n-channel transistor sometimes refers to a drain current at the time when Vg is higher than or equal to Vth.

In this specification and the like, a high power supply potential VDD (hereinafter also simply referred to as “VDD” or a “potential H”) is a power supply potential higher than a low power supply potential VSS. The low power supply potential VSS (hereinafter also simply referred to as “VSS” or a “potential L”) is a power supply potential lower than the high power supply potential VDD. In addition, a ground potential GND (hereafter also simply referred to as “GND”) can be used as VDD or VSS. For example, VSS is a potential lower than GND when VDD is GND, and VDD is a potential higher than GND when VSS is GND. Note that in this specification and the like, VSS is a reference potential unless otherwise specified.

A “voltage” usually refers to a potential difference between a given potential and a reference potential (e.g., a ground potential or a source potential). A “potential” is a relative value, and a potential supplied to a wiring or the like changes depending on the reference potential in some cases. Therefore, the terms “voltage” and “potential” can be replaced with each other in some cases.

In this specification and the like, terms for describing arrangement, such as “over”, “under”, “above”, and “below”, are sometimes used for convenience to describe the positional relationship between components with reference to drawings. The positional relationship between components changes as appropriate in accordance with a direction in which each component is described. Thus, without limitation to terms described in this specification and the like, the description can be changed appropriately depending on the situation. For example, the expression “an insulating layer positioned over a conductive layer” can be replaced with the expression “an insulating layer positioned under a conductive layer” when the direction of a drawing illustrating these components is rotated by 180°. For example, the expression “an insulating layer positioned over an opening” includes the expression “an insulating layer positioned at a side surface of an opening” in some cases.

The term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and does not exclude the state where the electrode B is formed under the insulating layer A or the state where the electrode B is formed on the right (or left) side of the insulating layer A.

The terms “adjacent” and “close” in this specification and the like do not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, the terms “identical”, “the same”, “equal”, “uniform”, or the like (including synonyms thereof) used in describing calculation values and measurement values contain an error of +20% unless otherwise specified.

In this specification and the like, an end portion of an object having a tapered shape indicates that the end portion of the object has a cross-sectional shape in which the angle between a surface on which the object is formed (a bottom surface) and a side surface (a surface) of the object is greater than 0° and less than 90° in a region of the end portion, and the thickness continuously increases from the end portion. A taper angle refers to an angle between a bottom surface (a surface on which an object is formed) and a side surface (a surface) at an end portion of the object.

In the drawings and the like for this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted with the same reference numeral, and particularly when they need to be distinguished from each other, an identification sign such as “A”, “b”, “_1”, “[n]”, or “[m,n]” is sometimes added to the reference numeral. For example, EL layers 172 are separately denoted as an EL layer 172R, an EL layer 172G, an EL layer 172B, and an EL layer 172 W in some cases.

### Embodiment 1

In this embodiment, examples of a signal output circuit, which is a kind of semiconductor device, and a shift register including the signal output circuit are described with reference to drawings.

### <Structure of Shift Register 100>

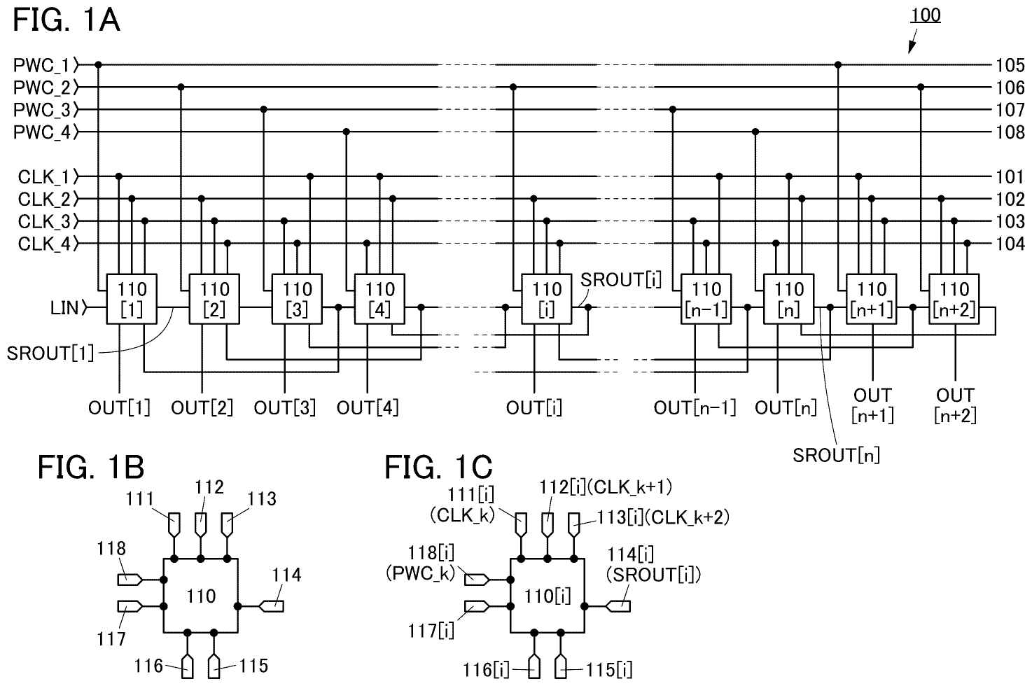

A shift register 100 illustrated in FIG. 1A includes n signal output circuits 110 (n is an integer greater than or equal to 1). In this specification and the like, the signal output circuit 110 in the first stage (the first signal output circuit 110) is referred to as a signal output circuit 110[1] in some cases, and the signal output circuit 110 in the n-th stage (the n-th signal output circuit 110) is referred to as a signal output circuit 110[n] in some cases.

The signal output circuit 110 in the i-th stage (i is an integer greater than or equal to 1 and less than or equal to n) is referred to as a signal output circuit 110[i] in some cases. Note that when a given stage is denoted by i+α and α is positive, i+α does not exceed n. In addition, when a given stage is denoted by i−α and α is positive, i−α does not become less than 1.

The shift register 100 includes two signal output circuits 110 (a signal output circuit 110[n+1] and a signal output circuit 110[n+2]) that are dummy circuits.

Note that a terminal, input and output signals, and the like of the signal output circuit 110 are denoted in a manner similar to the above in some cases. For example, a signal OUT of the signal output circuit 110[i] is referred to as a signal OUT[i] in some cases.

The shift register 100 includes a wiring 101 to a wiring 104 to which four signals CLK (a signal CLK_1 to a signal CLK_4) that are clock signals are supplied, and a wiring 105 to a wiring 108 to which four signals PWC (a signal PWC_1 to a signal PWC_4) are supplied. The signal CLK_1 is supplied to the wiring 101, the signal CLK_2 is supplied to the wiring 102, the signal CLK_3 is supplied to the wiring 103, and the signal CLK_4 is supplied to the wiring 104. The signal PWC_1 is supplied to the wiring 105, the signal PWC_2 is supplied to the wiring 106, the signal PWC_3 is supplied to the wiring 107, and the signal PWC_4 is supplied to the wiring 108.

The signal output circuits 110 each include a terminal 111 to a terminal 118 (see FIG. 1B). The terminal 111, the terminal 112, and the terminal 113 are individually electrically connected to different wirings among the wiring 101 to the wiring 104. For example, in FIG. 1A, the terminal 111 of the signal output circuit 110[1] in the first stage is electrically connected to the wiring 101, the terminal 112 thereof is electrically connected to the wiring 102, and the terminal 113 thereof is electrically connected to the wiring 103. That is, the signal CLK_1 is supplied to the terminal 111, the signal CLK_2 is supplied to the terminal 112, and the signal CLK_3 is supplied to the terminal 113.

The terminal 111 of the signal output circuit 110[2] in the second stage is electrically connected to the wiring 102, the terminal 112 thereof is electrically connected to the wiring 103, and the terminal 113 thereof is electrically connected to the wiring 104. That is, the signal CLK_2 is supplied to the terminal 111, the signal CLK_3 is supplied to the terminal 112, and the signal CLK_4 is supplied to the terminal 113.

That is, the signal CLK_k is supplied to the terminal 111[i] of the signal output circuit 110[i] (see FIG. 1C). Here, k is an integer greater than or equal to 1 and less than or equal to 4, k is equal to i when i is less than or equal to 4, and k is equal to i-4xg when i is greater than or equal to 5. Note that g is a quotient obtained by dividing i by 4.

The signal CLK_k+1 is supplied to the terminal 112[i] of the signal output circuit 110[i]. Here, k is an integer greater than or equal to 1 and less than or equal to 4, and k is 1 when k+1 is 5. When i is less than or equal to 3, k is equal to i, and when i is greater than or equal to 4, k is equal to i-4xg.

The signal CLK_k+2 is supplied to the terminal 113[i] of the signal output circuit 110[i]. Here, k+1 is an integer greater than or equal to 1 and less than or equal to 4; k+2 is 1 when k+2 is 5; and k+2 is 2 when k+2 is 6. When i is less than or equal to 2, k is equal to i, and when i is greater than or equal to 3, k is equal to i-4xg.

The terminal 114[i] is electrically connected to the terminal 117[i+1] (not illustrated) of the signal output circuit 110[i+1] (not illustrated) in the next stage. Thus, the terminal 117[i] is electrically connected to the terminal 114[i-1]. For example, the terminal 114 of the signal output circuit 110[1] is electrically connected to the terminal 117 of the signal output circuit 110[2]. A start pulse SP is supplied to the terminal 117 of the signal output circuit 110[1].

The terminal 115[i] is electrically connected to the terminal 114[i+2] (not illustrated) of the signal output circuit 110[i+2] (not illustrated) in the second subsequent stage. For example, the terminal 115 of the signal output circuit 110[1] is electrically connected to the terminal 114 of the signal output circuit 110[3], and the terminal 115 of the signal output circuit 110[2] is electrically connected to the terminal 114 of the signal output circuit 110[4]. Thus, the terminal 115 of the signal output circuit 110[n-1] is electrically connected to the terminal 114 of the signal output circuit 110[n+1], and the terminal 115 of the signal output circuit 110[n] is electrically connected to the terminal 114 of the signal output circuit 110[n+2]. Note that the signal output circuit 110[n+1] and the signal output circuit 110[n+2] do not necessarily include the terminal 115.

The terminal 118[i] is electrically connected to any of the wiring 105 to the wiring 108. For example, the terminal 118 of the signal output circuit 110[1] is electrically connected to the wiring 105, and the terminal 118 of the signal output circuit 110[2] is electrically connected to the wiring 106. In other words, the signal PWC_k is supplied to the terminal 118[i] of the signal output circuit 110[i]. Here, k is an integer greater than or equal to 1 and less than or equal to 4, k is equal to i when i is less than or equal to 4, and k is equal to i-4xg when i is greater than or equal to 5.

The signal OUT[i] is output from the terminal 116[i]. For example, the signal OUT[1] is output from the terminal 116 of the signal output circuit 110[1]. The signal OUT[n] is output from the terminal 116 of the signal output circuit 110[n] in the n-th stage. Note that “the signal OUT[i] is output from the terminal 116[i]” can be rephrased as “the signal OUT[i] is supplied to the terminal 116[i]”.

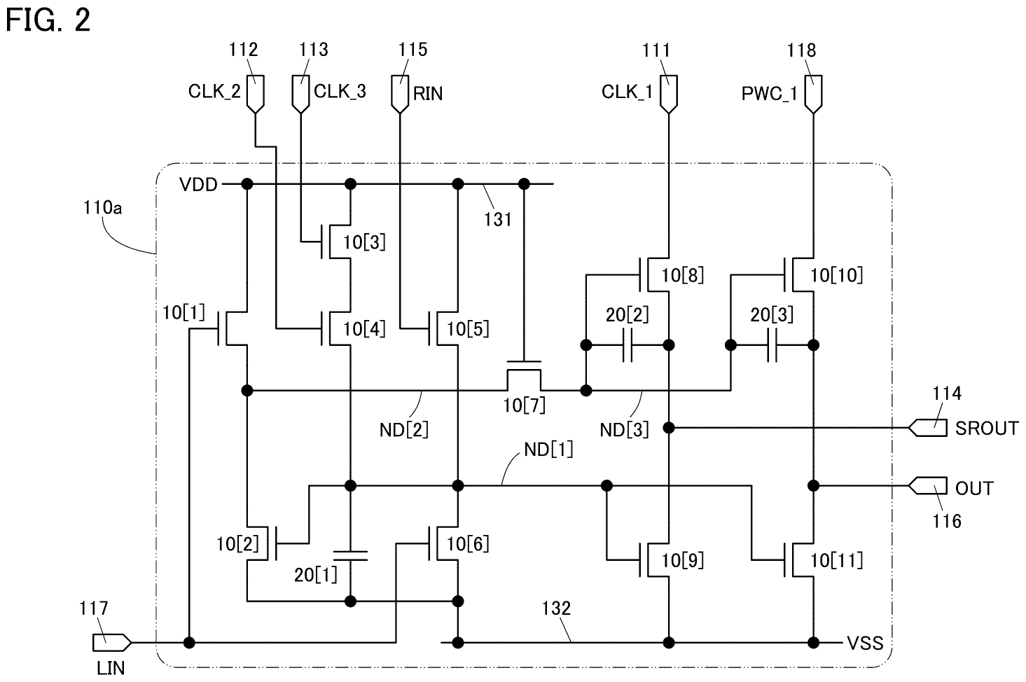

The signal SROUT[i] is supplied to the terminal 114[i]. In other words, the signal SROUT[i] is output from the terminal 114[i]. For example, the signal SROUT[1] is output from the terminal 114 of the signal output circuit 110[1]. The signal SROUT[n] is output from the terminal 114 of the signal output circuit 110[n] in the n-th stage. Note that “the signal SROUT[i] is output from the terminal 114[i]” can be rephrased as “the signal SROUT[i] is supplied to the terminal 114[i]”.

[Structural example of signal output circuit 110] Next, a structure of a signal output circuit 110a, which can be used as the signal output circuit 110, will be described (see FIG. 2). The signal output circuit 110a includes a transistor

10 [1] to a transistor 10[11] and a capacitor 20[1] to a capacitor 20[3].

A gate of the transistor 10[1] is electrically connected to the terminal 117 and a gate of the transistor 10[6]. A source of the transistor 10[1] is electrically connected to a drain of the transistor 10[2], and a drain of the transistor 10[1] is electrically connected to a wiring 131. A gate of the transistor 10[2] is electrically connected to one terminal of the capacitor 20[1]. A source of the transistor 10[2] is electrically connected to the other terminal of the capacitor 20[1], a source of the transistor 10[6], and a wiring 132.

A gate of the transistor 10[3] is electrically connected to the terminal 113, a drain of the transistor 10[3] is electrically connected to the wiring 131, and a source of the transistor 10[3] is electrically connected to a drain of the transistor 10[4]. A gate of the transistor 10[4] is electrically connected to the terminal 112, and the drain of the transistor 10[4] is electrically connected to the source of the transistor 10[3]. A source of the transistor 10[4] is electrically connected to the gate of the transistor 10[2], a gate of the transistor 10[9], and a gate of the transistor 10[11] and the one terminal of the capacitor 20[1].

Note that in this specification and the like, a region where the gates of the transistor 10 [2], the transistor 10[9], and the transistor 10[11], the source of the transistor 10[4], and the one terminal of the capacitor 20[1] are electrically connected to each other is referred to as a node ND[1]. The capacitor 20[1] has a function of inhibiting a change in the potential of the node ND[1] at the time when the node ND[1] is brought into a floating state and maintaining the potential of the node ND[1].

A gate of the transistor 10[5] is electrically connected to the terminal 115, and a drain of the transistor 10[5] is electrically connected to the wiring 131. A source of the transistor 10[5] is electrically connected to the gate of the transistor 10[2], the gate of the transistor 10[9], the gate of the transistor 10[11], and a drain of the transistor 10[6].

A gate of the transistor 10[7] is electrically connected to the wiring 131, and one of a source and a drain of the transistor 10[7] is electrically connected to the source of the transistor 10[1] and the drain of the transistor 10[2]. The other of the source and the drain of the transistor 10[7] is electrically connected to a gate of the transistor 10[8], one terminal of the capacitor 20[2], a gate of the transistor 10[10], and one terminal of the capacitor 20[3].

Note that in this specification and the like, a region where the one of the source and the drain of the transistor 10[7], the source of the transistor 10[1], and the drain of the transistor 10[2] are electrically connected to each other is referred to as a node ND[2]. In this specification and the like, a region where the other of the source and the drain of the transistor 10[7], the gate of the transistor 10[8], the one terminal of the capacitor 20[2], the gate of the transistor 10[10], and the one terminal of the capacitor 20[3] are electrically connected to each other is referred to as a node ND[3].

A drain of the transistor 10[8] is electrically connected to the terminal 111. A source of the transistor 10[8] is electrically connected to the other terminal of the capacitor 20[2], the terminal 114, and a drain of the transistor 10[9]. A drain of the transistor 10[10] is electrically

connected to the terminal 118. A source of the transistor 10[10] is electrically connected to the other terminal of the capacitor 20[3], the terminal 116, and a drain of the transistor 10[11].

A source of the transistor 10[9] and a source of the transistor 10[11] are electrically connected to the wiring 132.

Note that the drain of the transistor 10[1], the drain of the transistor 10[3], the drain of the transistor 10[5], and the gate of the transistor 10[7] may be individually electrically connected to different wirings. The source of the transistor 10[6], the source of the transistor 10[9], and the source of the transistor 10[11] may be individually electrically connected to different wirings.

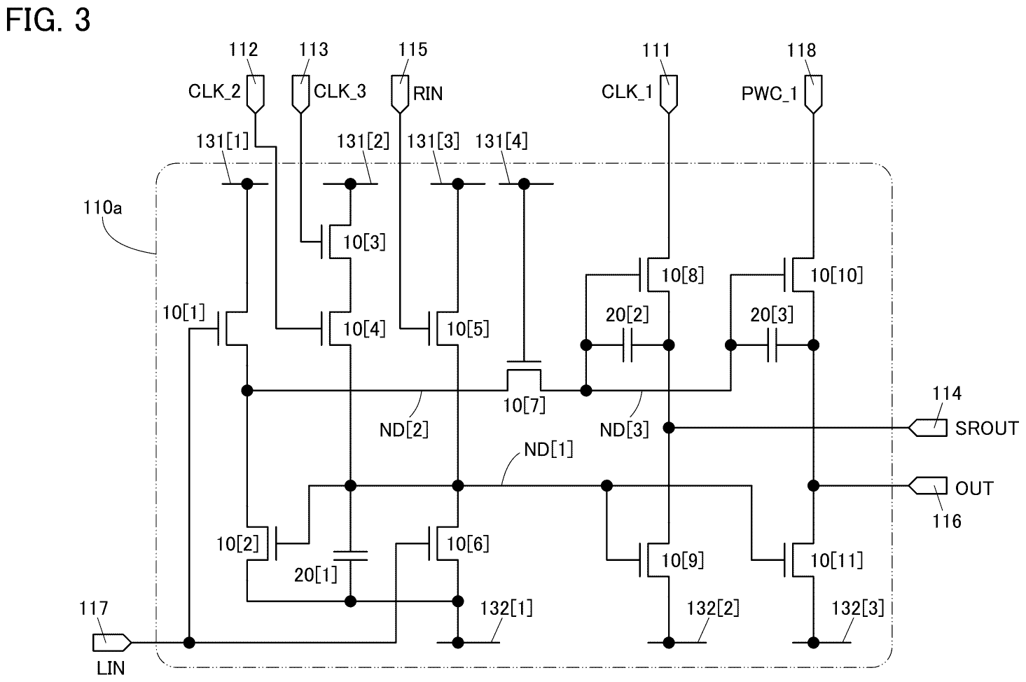

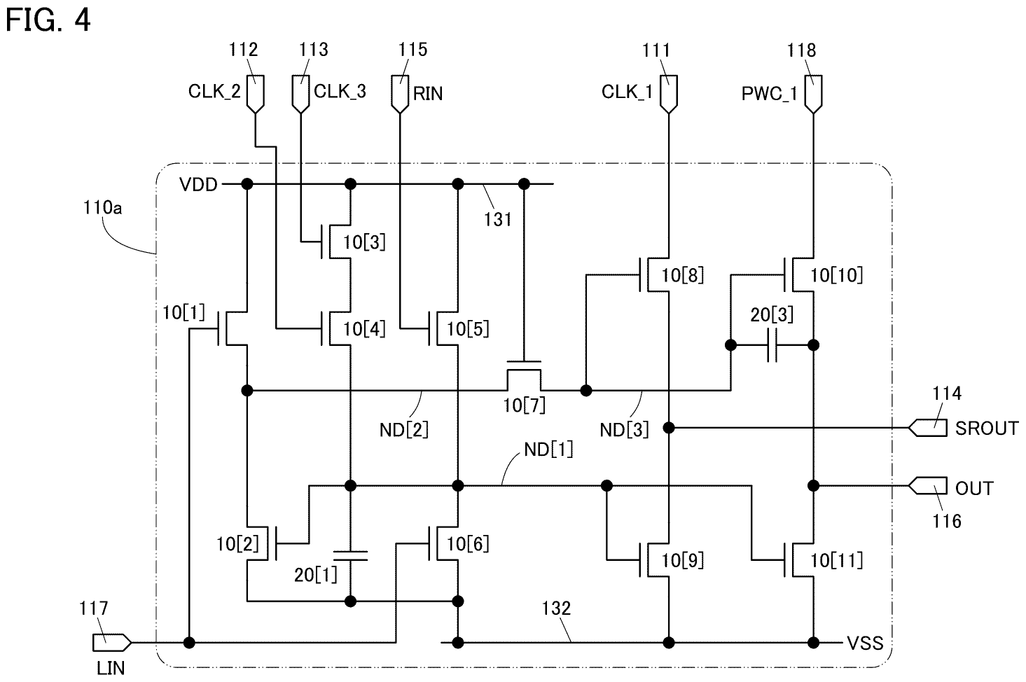

For example, as illustrated in FIG. 3, the drain of the transistor 10[1] may be electrically connected to a wiring 131[1], the drain of the transistor 10[3] may be electrically connected to a wiring 131[2], the drain of the transistor 10[5] may be electrically connected to a wiring 131[3], and the gate of the transistor 10[7] may be electrically connected to a wiring 131[4]. The source of the transistor 10[6] may be electrically connected to a wiring 132[1], the source of the transistor 10[9] may be electrically connected to a wiring 132[2], and the source of the transistor 10[11] may be electrically connected to a wiring 132[3]. Note that in the case where the capacitor 20[3] can have a sufficient capacitance, the formation of the capacitor 20[2] may be omitted as illustrated in FIG. 4.

A signal RIN is supplied to the terminal 115, a signal LIN is supplied to the terminal 117, the signal SROUT is supplied to the terminal 114, and the signal OUT is supplied to the terminal 116. In the signal output circuit 110a in the first stage, the signal CLK_1 is supplied to the terminal 111, the signal CLK_2 is supplied to the terminal 112, the signal CLK_3 is supplied to the terminal 113, and the signal PWC_1 is supplied to the terminal 118.

Note that in the signal output circuit 110a in the second stage, the signal CLK_2 is supplied to the terminal 111, the signal CLK_3 is supplied to the terminal 112, the signal CLK_4 is supplied to the terminal 113, and the signal PWC_2 is supplied to the terminal 118.

### Modification Example 1

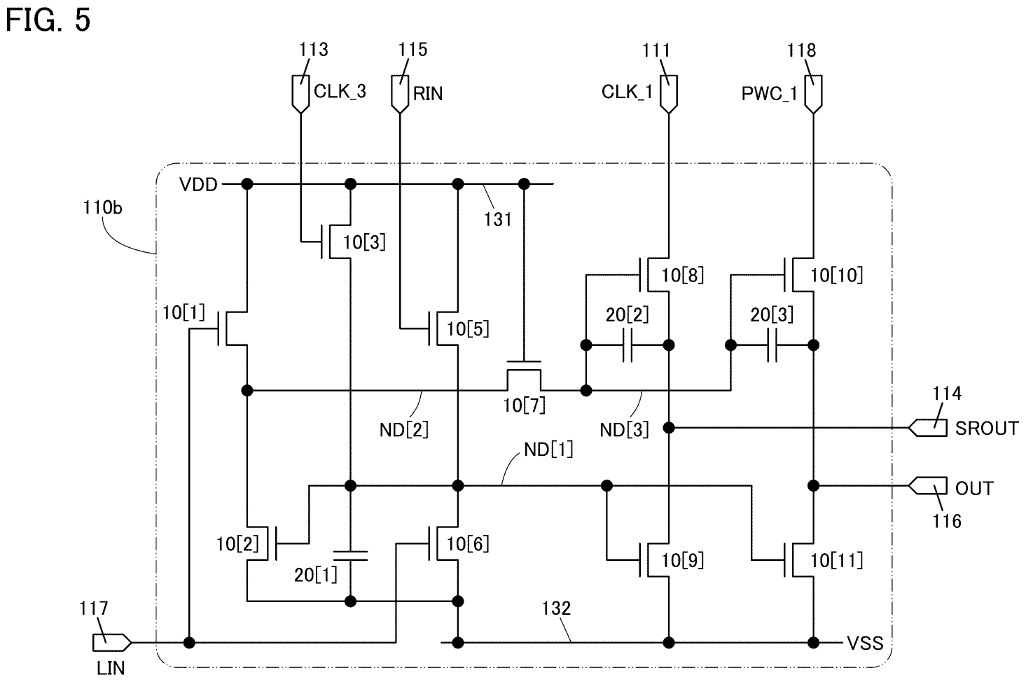

One of the transistor 10[3] and the transistor 10[4] may be omitted. FIG. 5 illustrates a circuit diagram of a signal output circuit 110b, which is a modification example of the signal output circuit 110a. The signal output circuit 110b has a structure obtained by removing the transistor 10[4] from the signal output circuit 110a. The source of the transistor 10[3] is electrically connected to the node ND[1]. The signal output circuit 110b, which occupies a small area, can be obtained by omitting one of the transistor 10[3] and the transistor 10[4].

### Modification Example 2

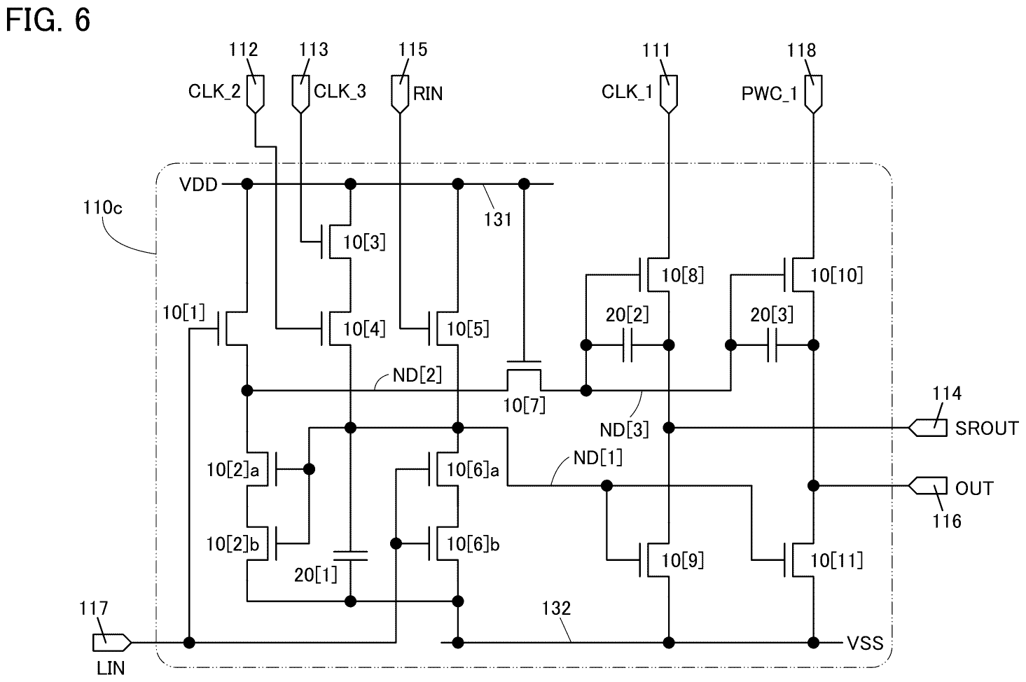

FIG. 6 illustrates a circuit diagram of a signal output circuit 110c, which is a modification example of the signal output circuit 110a. Each of the transistor 10[2] and the transistor 10[6] may be a multi-gate transistor. FIG. 6 illustrates an example in which each of the transistor 10[2] and the transistor 10[6] is constituted by a double-gate transistor, which is a type of multi-gate transistor.

A source of a transistor 10[2] a is electrically connected to a drain of a transistor 10[2] b, and a drain of the transistor 10[2] a is electrically connected to the source of the transistor 10[1] and the one of the source and the drain of the transistor 10[7]. A source of the transistor 10[2] b is electrically connected to the other terminal of the capacitor 20[1], a source of a transistor 10[6] b, and the wiring 132. A gate of the transistor 10[2] a and a gate of the transistor 10[2] b are electrically connected to each other. That is, the transistor 10[2] a and the transistor 10[2] b are connected in series and function together as one transistor 10[2]. The gate of the transistor 10[2] a and the gate of the transistor 10[2] b are electrically connected to the node ND[1]. The transistor 10[2] may be a multi-gate transistor constituted by three or more transistors connected in series.

A source of a transistor 10[6] a is electrically connected to a drain of the transistor 10[6] b, and a drain of the transistor 10[6] a is electrically connected to the node ND[1]. The source of the transistor 10[6] b is electrically connected to the other terminal of the capacitor 20[1], the source of the transistor 10[2] b, and the wiring 132. A gate of the transistor 10[6] a and a gate of the transistor 10[6] b are electrically connected to each other. That is, the transistor 10[6] a and the transistor 10[6] b are connected in series and function together as one transistor 10[6]. The gate of the transistor 10[6] a and the gate of the transistor 10[6] b are electrically connected to the gate of the transistor 10[1] and the terminal 117. The transistor 10[6] may be a multi-gate transistor constituted by three or more transistors connected in series.

The multi-gate transistor has a high source-drain withstand voltage. Thus, the reliability of a circuit using the multi-gate transistor can be improved. Consequently, the reliability of a semiconductor device including the circuit can be improved. A multi-gate transistor may be used as a transistor other than the transistor 10[2] and the transistor 10[6].

### Modification Example 3

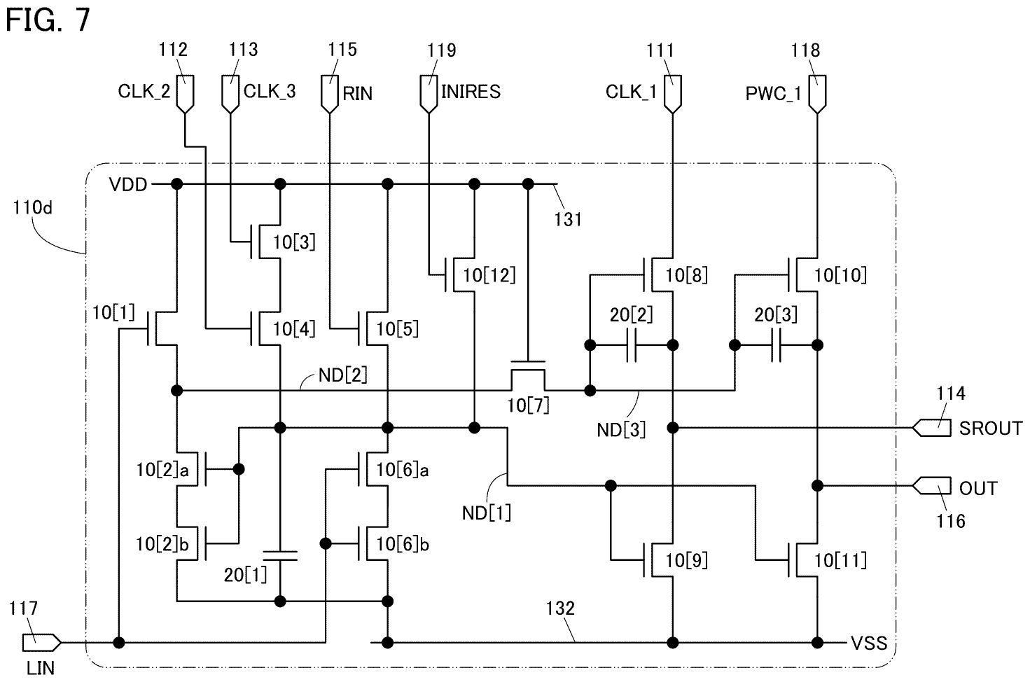

FIG. 7 illustrates a circuit diagram of a signal output circuit 110d, which is a modification example of the signal output circuit 110c. Note that the signal output circuit 110d is also a modification example of the signal output circuit 110a. The signal output circuit 110d includes a transistor 10[12]. A source of the transistor 10[12] is electrically connected to the node ND[1], and a drain thereof is electrically connected to the wiring 131. A gate of the transistor 10[12] is electrically connected to a terminal 119.

A signal INIRES is supplied to the terminal 119. The signal INIRES functions as a reset signal, and the signal OUT and the signal SROUT have a potential L while a potential H is supplied as the signal INIRES to the terminal 119. Specifically, when the potential H is supplied as the signal INIRES to the terminal 119, the transistor 10[12] is turned on and the potential of the node ND1 becomes the potential H. When the potential of the node ND1 becomes the potential H, the transistor 10[9] is turned on and the potential L is supplied to the terminal 114. The transistor 10[11] is also turned on and the potential L is supplied to the terminal 116.

When the transistor 10[12] is provided, the operation of the signal output circuit 110d can be stopped at a given timing.

### Modification Example 4

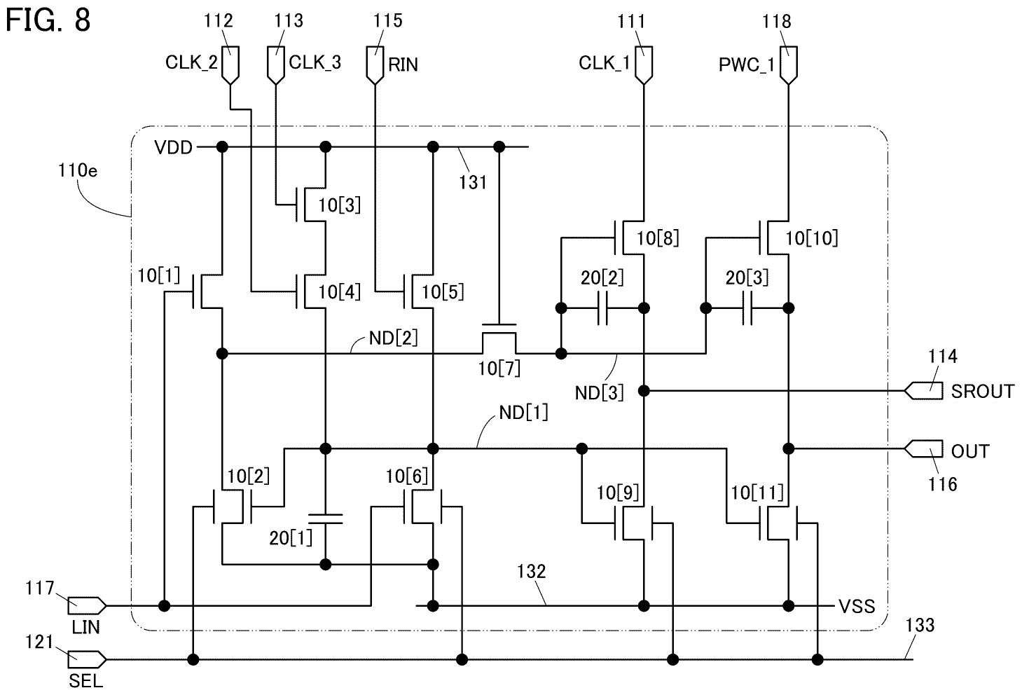

FIG. 8 illustrates a circuit diagram of a signal output circuit 110e, which is a modification example of the signal output circuit 110a. In the signal output circuit 110e, transistors including back gates are used as the transistor 10[2], the transistor 10[6], the transistor 10[9], and the transistor 10[11]. The back gates of the transistor 10[2], the transistor 10[6], the transistor 10[9], and the transistor 10[11] are electrically connected to a terminal 121 through a wiring 133.

A signal SEL is supplied to the terminal 121. The signal SEL may be a fixed potential or a variable potential. In the case where the signal SEL is set to a fixed potential, the potential is the potential L (VSS) or lower than the potential L.

Here, the reliability of a transistor is described. One of indicators for evaluating the reliability of a transistor is a GBTS (Gate Bias Temperature Stress) test in which the transistor is kept with an electric field applied to its gate. Among GBTS tests, a test in which a transistor is kept at a high temperature with a positive potential (positive bias) relative to a source potential and a drain potential supplied to its gate is referred to as a PBTS (Positive Bias Temperature Stress) test, and a test in which a transistor is kept at a high temperature with a negative potential (negative bias) supplied to its gate is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In an n-channel transistor, a positive potential is supplied to a gate in putting the transistor in an on state; thus, the amount of change in threshold voltage in the PBTS test is one important item to be focused on as an indicator of the reliability of the transistor. In a p-channel transistor, a negative potential is supplied to a gate in putting the transistor in an on state; thus, the amount of change in threshold voltage in the NBTS test is one important item to be focused on as an indicator of the reliability of the transistor. It can be said that a smaller amount of change in threshold voltage in the GBTS test means a higher reliability of the transistor.

During the operation period of the shift register 100, the potential H (VDD) is retained at the node ND[1] of the signal output circuit 110 (e.g., the signal output circuit 110a) for a long time. Thus, PBTS is applied to the transistor 10[2], the transistor 10[9], and the transistor 10[11] for a long time. In addition, NBTS is applied to the transistor 10[6] for a long time. When transistors having back gates are used as the transistor 10[2], the transistor 10[6], the transistor 10[9], and the transistor 10[11], the degradation of transistor characteristics due to NBTS and PBTS is inhibited.

Even in the case where the threshold voltages of the transistors are changed in the negative direction (to be normally on) owing to the degradation of transistor characteristics, the transistors can be surely turned off by supplying a potential lower than the potential L to the back gates. Thus, the potential of the node ND[1] can be surely retained. Thus, the operation of the signal output circuit 110 can be stabilized, and the reliability of a semiconductor device including the signal output circuit 110 can be improved.

In the case where the operation speed of the shift register 100 is low (the driving frequency is low), the node ND[1] or the like is put in a floating state for a long time. Even in such a situation, when a potential lower than the potential L is supplied to the back gates, the potential of the node ND[1] or the like can be surely retained. Thus, the operation of the signal output circuit 110 can be stabilized, and the reliability of the semiconductor device including the signal output circuit 110 can be improved.

As described above, PBTS is applied to the transistor 10[2], the transistor 10[9], and the transistor 10[11] for a long time, and NBTS is applied to the transistor 10[6] for a long time. Accordingly, a difference in degradation of transistor characteristics might be generated between the transistor 10[2], the transistor 10[9], and the transistor 10[11] and the transistor 10[6].

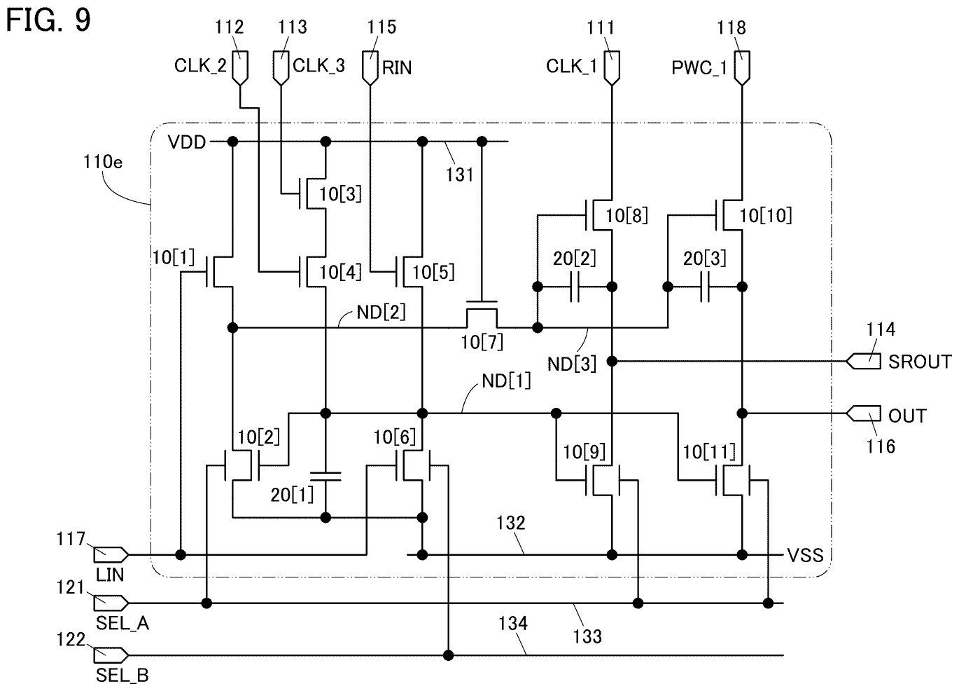

Thus, as illustrated in FIG. 9, the back gates of the transistor 10[2], the transistor 10[9], and the transistor 10[11] may be electrically connected to the terminal 121 through the wiring 133, and the back gate of the transistor 10[6] may be electrically connected to a terminal 122 through a wiring 134. In that case, a signal SEL_A is supplied as the signal SEL to the terminal 121, and a signal SEL_B is supplied as the signal SEL to the terminal 122. The potential of the signal SEL_A and the potential of the signal SEL_B may be equal to each other or different from each other. For example, the potential of the signal SEL_A and the potential of the signal SEL_B may be different from each other, so that the transistor characteristics of the transistor 10[2], the transistor 10[9], and the transistor 10[11] may be different from the transistor characteristics of the transistor 10[6].

The signal SEL_A may be synchronized with the signal RIN. For example, when the signal RIN is a potential H, the signal SEL_A is set to a potential H. When the signal RIN is a potential L, the signal SEL_A is set to a potential L or a potential lower than the potential L. When both the signal SEL_A and the signal RIN are the potential H, the operation speeds of the transistor 10[2], the transistor 10[9], and the transistor 10[11] can be increased.

The signal SEL_B may be synchronized with the signal LIN. For example, when the signal LIN is a potential H, the signal SEL_B is set to a potential H. When the signal LIN is a potential L, the signal SEL_B is set to a potential L or a potential lower than the potential L. When both the signal SEL_B and the signal LIN are the potential H, the operation speed of the transistor 10[6] can be increased.

### Modification Example 5

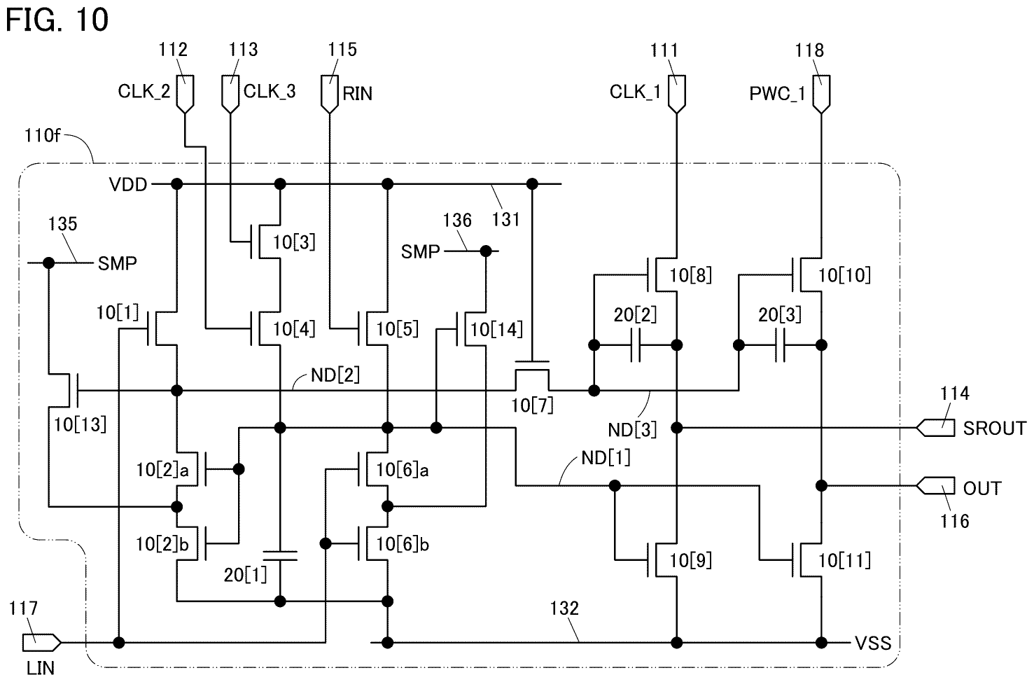

FIG. 10 illustrates a circuit diagram of a signal output circuit 110f, which is a modification example of the signal output circuit 110c. The signal output circuit 110f has a structure obtained by adding a transistor 10[13] and a transistor 10[14] to the signal output circuit 110c.

A gate of the transistor 10[13] is electrically connected to the source of the transistor 10[1], the drain of the transistor 10[2] a, and the one of the source and the drain of the transistor 10[7]. A source of the transistor 10[13] is electrically connected to the source of the transistor 10[2] a and the drain of the transistor 10[2] b. A drain of the transistor 10[13] is electrically connected to a wiring 135.

A gate of the transistor 10[14] is electrically connected to the node ND[1]. A source of the transistor 10[14] is electrically connected to the source of the transistor 10[6] a and the drain of the transistor 10[6] b. A drain of the transistor 10[14] is electrically connected to a wiring 136.

A potential SMP is supplied to the wiring 135 and the wiring 136. The potential SMP is preferably a potential higher than the potential L+Vth, further preferably a potential higher than the potential L+2×Vth.

When the potential H (more precisely, the potential H−Vth) is supplied to the node ND[2], the transistor 10[13] is turned on and the potential SMP is supplied to the source of the transistor 10[2] a. When the potential H is supplied to the node ND[1], the transistor 10[14] is turned on, and the potential SMP is supplied to the source of the transistor 10[6] a. The potential SMP is preferably a fixed potential but may be a variable potential.

When the potential SMP is set to a potential higher than the potential L, a potential difference between the source and the gate with respect to a source potential with the potential L supplied to the gate of each of the transistor 10[13] and the transistor 10[14] is negative. Thus, the transistor 10[13] and the transistor 10[14] can be surely turned off.

The signal output circuit 110 (the signal output circuit 110a, the signal output circuit 110c, and the signal output circuit 110d) of one embodiment of the present invention is a single-polarity circuit formed using transistors of the same conductivity type (n-channel type). Since transistors of a different conductivity type (p-channel type) do not need to be used, the signal output circuit can have reduced manufacturing cost and high productivity. Since steps of forming transistors of a different conductivity type are unnecessary, the manufacturing period is shortened and the manufacturing yield is improved.

Note that a p-channel transistor may be used in part of the signal output circuit 110 as needed. That is, a transistor of a different conductivity type may be used in part of the signal output circuit 110. For example, the signal output circuit 110 may include a CMOS (Complementary Metal-Oxide-Semiconductor) circuit including an n-channel transistor and a p-channel transistor. Although the example in which the signal output circuit 110 is formed using n-channel transistors is given in this embodiment, all these transistors can be replaced with p-channel transistors.

### [Structural Example of Transistor]

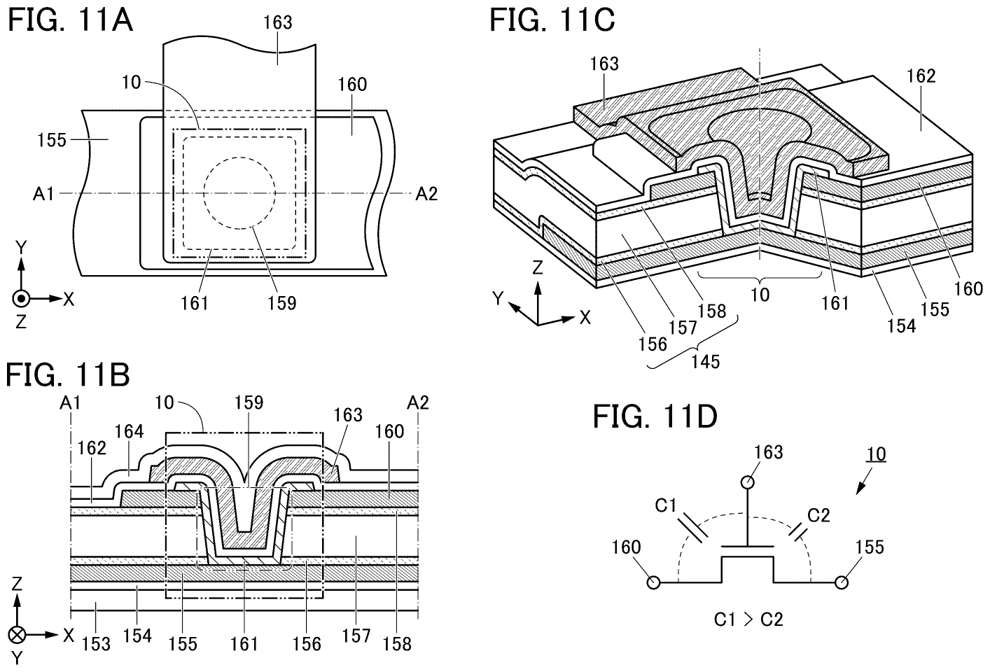

A structural example of a transistor that can be used as the transistor 10 is described here. FIG. 11A is a plan view of the transistor 10. FIG. 11B is a cross-sectional view of a portion indicated by the dashed-dotted line A1-A2 in FIG. 11A. FIG. 11C is a perspective view of the transistor 10. FIG. 11D is an equivalent circuit diagram of the transistor 10. For easy understanding of the structure of the transistor 10, some components of the transistor 10 are not illustrated in FIG. 11A or FIG. 11C. For example, an insulating layer 164 or the like illustrated in FIG. 11B is not illustrated in FIG. 11A or FIG. 11C.

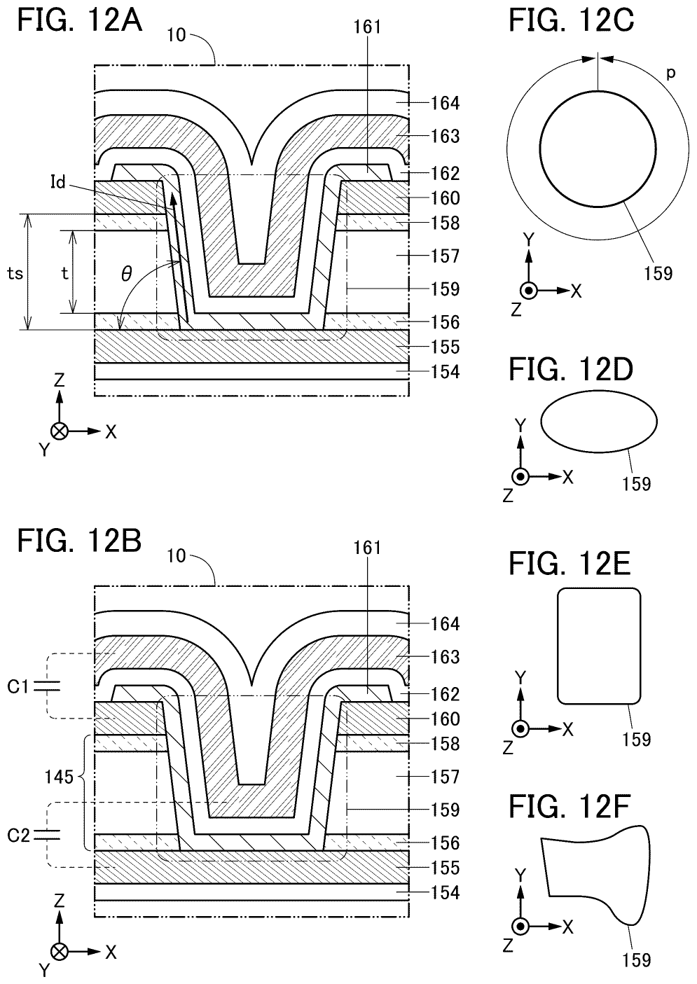

FIG. 12A and FIG. 12B are enlarged views of the transistor 10 illustrated in FIG. 11B. FIG. 12C is a view of an opening 159 seen from the Z direction.

The transistor 10 includes an insulating layer 154 over a substrate 153 and a conductive layer 155 over the insulating layer 154. An insulating layer 156 is provided over the conductive layer 155, an insulating layer 157 is provided over the insulating layer 156, and an insulating layer 158 is provided over the insulating layer 157. A conductive layer 160 is provided over the insulating layer 158. In this specification and the like, the insulating layer 156, the insulating layer 157, and the insulating layer 158 are collectively referred to as an insulating layer 145 in some cases.

In a region overlapping with part of the conductive layer 155, the opening 159 is provided in the conductive layer 160, the insulating layer 158, the insulating layer 157, and the insulating layer 156 (see FIG. 11B and FIG. 12A). A semiconductor layer 161 is provided in the opening 159. The semiconductor layer 161 includes a region overlapping with a bottom portion of the opening 159 and a region overlapping with a side surface of the opening 159. The semiconductor layer 161 includes a region in contact with the insulating layer 145 in the opening 159. Specifically, the semiconductor layer 161 includes a region in contact with a side surface of the insulating layer 158, a region in contact with a side surface of the insulating layer 157, and a region in contact with a side surface of the insulating layer 156. In the opening 159, a part of the semiconductor layer 161 is in contact with the conductive layer 160, and another part of the semiconductor layer 161 is in contact with the conductive layer 155. That is, the part of the semiconductor layer 161 is electrically connected to the conductive layer 160, and the other part of the semiconductor layer 161 is electrically connected to the conductive layer 155.

An insulating layer 162 is provided over the insulating layer 158, the conductive layer 160, and the semiconductor layer 161, and a conductive layer 163 is provided over the insulating layer 162. An insulating layer 164 is provided over the insulating layer 162 and the conductive layer 163. The insulating layer 162 includes a region overlapping with the side surface of the opening 159 with the semiconductor layer 161 therebetween. The conductive layer 163 is provided to cover the semiconductor layer 161. Thus, the conductive layer 163 includes a region extending beyond an end portion of the semiconductor layer 161. The conductive layer 163 includes also a region overlapping with the side surface of the opening 159 with the insulating layer 162 and the semiconductor layer 161 therebetween.

The conductive layer 155 includes a region functioning as one of a source electrode and a drain electrode of the transistor 10. The conductive layer 160 includes a region functioning as the other of the source electrode and the drain electrode of the transistor 10. For example, in the case where the conductive layer 155 functions as the drain electrode of the transistor 10, the conductive layer 160 functions as the source electrode of the transistor 10.

The semiconductor layer 161 includes a region functioning as a semiconductor layer of the transistor 10 where a channel is formed; the insulating layer 162 includes a region functioning as a gate insulating layer; and the conductive layer 163 includes a region functioning as a gate electrode. The transistor 10 is provided in a region including the opening 159.

In the transistor 10, the source electrode and the drain electrode are placed in the Z direction. Thus, the source and the drain of the transistor 10 are placed in different positions in the Z direction. For example, with respect to the top surface of the substrate 153, the source and the drain of the transistor 10 are placed at different distances from the top surface of the substrate 153 serving as the reference. Note that being placed in different positions in the Z direction is also expressed as “being placed at different levels”. Such a transistor is also referred to as a “vertical-channel transistor”, a “vertical transistor”, or a “VFET (Vertical Field Effect Transistor)”. In the vertical-channel transistor, a Z-direction (vertical-direction) component is included in the direction in which/d flows. For example, in the transistor 10 which is a vertical-channel transistor, the angle θ (see FIG. 12A) between the direction in which Id flows and a surface on which the semiconductor layer 161 over the conductive layer 155 is formed is larger than or equal to 5° and smaller than or equal to 110°, larger than or equal to 10° and smaller than or equal to 90°, larger than or equal to 30° and smaller than or equal to 90°, or larger than or equal to 60° and smaller than or equal to 90° when a cross section passing through the center (or center of gravity) of the opening 159 seen from the Z direction is seen from the X direction or the Y direction.

As described above, the semiconductor layer 161 includes the region in contact with the side surface of the insulating layer 157. Thus, Id flows along the side surface of the insulating layer 157. Thus, the angle θ between the direction in which Id flows and the surface on which the semiconductor layer 161 over the conductive layer 155 is formed can be rephrased as the angle θ between the side surface of the insulating layer 157 and the surface on which the semiconductor layer 161 over the conductive layer 155 is formed.

Since the source electrode and the drain electrode of a vertical-channel transistor are placed in the Z direction, the area occupied by the transistor can be reduced. With the use of the vertical-channel transistor for a semiconductor device, the area occupied by the semiconductor device can be significantly reduced.

Here, examples of materials that can be used for the transistor 10 or the semiconductor device of one embodiment of the present invention are described.

### [Substrate]

There is no particular limitation on a material used for the substrate 153 and a substrate 148 and a substrate 152 to be described later. The material is determined in accordance with the purpose in consideration of whether it has a light-transmitting property, heat resistance high enough to withstand heat treatment, or the like. For example, an insulating substrate such as a glass substrate of barium borosilicate glass, aluminoborosilicate glass, or the like, a ceramic substrate, a quartz substrate, or a sapphire substrate can be used. Alternatively, a semiconductor substrate, a flexible substrate, a laminate film, a base film, or the like may be used.

Examples of the semiconductor substrate include a semiconductor substrate using silicon, germanium, or the like as a material and a compound semiconductor substrate using silicon carbide, silicon germanium, gallium arsenide, indium phosphide, zinc oxide, or gallium oxide as a material. The semiconductor substrate may be a single crystal semiconductor or a polycrystalline semiconductor.

When the transistor 10 or the like of one embodiment of the present invention is used for a display device, a large-sized glass substrate of the 6th generation (1500 mm×1850 mm), the 7th generation (1870 mm×2200 mm), the 8th generation (2200 mm×2400 mm), the 9th generation (2400 mm×2800 mm), or the 10th generation (2950 mm×3400 mm), for example, can be used. Thus, a large-sized display device can be fabricated. With the increase in substrate size, a larger number of display devices can be produced from one substrate, which can reduce production cost.

As the materials of the flexible substrate, the laminate film, the base film, and the like, for example, a polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide imide, polyurethane, polyvinyl chloride, polyvinylidene chloride, polypropylene, polytetrafluoroethylene (PTFE), an ABS resin, cellulose nanofiber, or the like can be used.

When the above-described material is used for the substrate, a lightweight semiconductor device including the transistor 10 can be provided. Furthermore, when the above-described material is used for the substrate, a shock-resistant semiconductor device can be provided. Moreover, when the above-described material is used for the substrate, a semiconductor device that is less likely to be broken can be provided.

The flexible substrate used as the substrate preferably has a lower coefficient of linear expansion because deformation due to an environment is inhibited. For the flexible substrate used as the substrate, for example, a material whose coefficient of linear expansion is lower than or equal to 1×10⁻³/K, lower than or equal to 5×10⁻⁵/K, or lower than or equal to 1×10⁻⁵/K is used. In particular, aramid is suitable for the flexible substrate because of its low coefficient of linear expansion.

### [Conductive Layer]

As a conductive material used for not only the gate electrode, the source electrode, and the drain electrode of the transistor 10 but also conductive layers such as various wirings and electrodes included in the semiconductor device, a metal element selected from aluminum (Al), chromium (Cr), copper (Cu), silver (Ag), gold (Au), platinum (Pt), tantalum (Ta), nickel (Ni), titanium (Ti), molybdenum (Mo), tungsten (W), hafnium (Hf), vanadium (V), niobium (Nb), manganese (Mn), magnesium (Mg), zirconium (Zr), beryllium (Be), and the like; an alloy containing the above metal element as a component; an alloy containing the above metal elements in combination; or the like can be used. Furthermore, a semiconductor typified by polycrystalline silicon containing an impurity element such as phosphorus, or silicide such as nickel silicide may be used. There is no particular limitation on the formation method of the conductive material, and a variety of formation methods such as an evaporation method, an atomic layer deposition (ALD) method, a chemical vapor deposition (CVD) method, a sputtering method, and a spin coating method can be employed.

A Cu—X alloy (X is Mn, Ni, Cr, Fe, Co, Mo, Ta, or Ti) may be used as the conductive material. A layer formed using a Cu—X alloy can be processed with a wet etching process, resulting in lower manufacturing cost. Alternatively, an aluminum alloy containing one or more elements selected from titanium, tantalum, tungsten, molybdenum, chromium, neodymium, and scandium may be used as the conductive material.

As the conductive material that can be used for the conductive layer, a conductive material containing oxygen, such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added, can be used. Furthermore, a conductive material containing nitrogen, such as titanium nitride, tantalum nitride, or tungsten nitride, can be used. The conductive layer can have a stacked-layer structure with an appropriate combination of a conductive material containing oxygen, a conductive material containing nitrogen, and a material containing the above-described metal element.

For example, the conductive layer can have a single-layer structure of an aluminum layer containing silicon, a two-layer structure in which a titanium layer is stacked over an aluminum layer, a two-layer structure in which a titanium layer is stacked over a titanium nitride layer, a two-layer structure in which a tungsten layer is stacked over a titanium nitride layer, a two-layer structure in which a tungsten layer is stacked over a tantalum nitride layer, or a three-layer structure of a titanium layer, an aluminum layer stacked over the titanium layer, and a titanium layer further stacked thereover.

Furthermore, a plurality of conductive layers formed with the above-described conductive materials may be stacked and used. The conductive layer may have a stacked-layer structure in which a material containing the above-described metal element and a conductive material containing oxygen are combined, for example. The conductive layer can also have a stacked-layer structure combining a material containing the above-described metal element and a conductive material containing nitrogen. Alternatively, a stacked-layer structure in which a material containing the above-described metal element, a conductive material containing oxygen, and a conductive material containing nitrogen are combined may be used.

For example, the conductive layer may have a three-layer structure in which a conductive layer containing copper is stacked over a conductive layer containing oxygen and at least one of indium and zinc, and a conductive layer containing oxygen and at least one of indium and zinc is stacked thereover. In that case, a side surface of the conductive layer containing copper is preferably covered with the conductive layer containing oxygen and at least one of indium and zinc. Alternatively, a plurality of conductive layers containing oxygen and at least one of indium and zinc may be stacked and used as the conductive layer, for example.

### [Insulating Layer]

For each of the insulating layers, a single layer or a stack layer of insulating materials selected from aluminum nitride, aluminum oxide, aluminum nitride oxide, aluminum oxynitride, magnesium oxide, silicon nitride, silicon oxide, silicon nitride oxide, silicon oxynitride, gallium oxide, germanium oxide, yttrium oxide, zirconium oxide, lanthanum oxide, neodymium oxide, hafnium oxide, tantalum oxide, aluminum silicate, and the like is used. Furthermore, a material in which two or more materials selected from an oxide material, a nitride material, an oxynitride material, and a nitride oxide material are mixed may be used.

There is no particular limitation on the formation method of the insulating material, and a variety of formation methods such as an evaporation method, an ALD method, a CVD method, a sputtering method, and a spin coating method can be employed.

Note that in this specification and the like, a nitride oxide refers to a material that contains more nitrogen than oxygen. An oxynitride refers to a material that contains more oxygen than nitrogen. Note that the content of each element can be measured by Rutherford backscattering spectrometry (RBS), for example.

For example, it is preferable that the insulating layer 154 and the insulating layer 164 be formed using an insulating material through which impurities are less likely to pass. For example, a single layer or a stacked layer of an insulating material containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Examples of the insulating material through which impurities are less likely to pass include aluminum oxide, aluminum nitride, aluminum oxynitride, aluminum nitride oxide, gallium oxide, germanium oxide, yttrium oxide, zirconium oxide, lanthanum oxide, neodymium oxide, hafnium oxide, tantalum oxide, and silicon nitride.

When the insulating material through which impurities are less likely to pass is used for the insulating layer 154, impurity diffusion from the substrate 153 side can be inhibited, and the reliability of the transistor 10 can be improved. That is, the reliability of a semiconductor device including the transistor 10 can be improved. When the insulating material through which impurities are less likely to pass is used for the insulating layer 164, impurity diffusion from above the insulating layer 164 can be inhibited, and the reliability of the transistor 10 can be improved. That is, the reliability of a semiconductor device including the transistor 10 can be improved.

As the insulating layer, an insulating layer that can function as a planarization layer may be used. Examples of materials of the insulating layer that functions as a planarization layer include an acrylic resin, polyimide, an epoxy resin, polyamide, polyimide amide, a siloxane resin, a benzocyclobutene resin, a phenol resin, and precursors of these resins. Other than the above-described organic materials, it is also possible to use a low-dielectric constant material (a low-k material), a siloxane resin, PSG (phosphosilicate glass), BPSG (borophosphosilicate glass), or the like. Note that a plurality of insulating layers formed of these materials may be stacked.

Note that the siloxane resin corresponds to a resin including a Si—O—Si bond formed using a siloxane-based material as a starting material. The siloxane resin may include an organic group (e.g., an alkyl group or an aryl group) or a fluoro group as a substituent. In addition, the organic group may include a fluoro group.

A surface of the insulating layer or the like may be subjected to CMP treatment. By the CMP treatment, unevenness of a surface of the insulating layer or the like can be reduced, and coverage with an insulating layer and a conductive layer that are formed later can be increased.

### [Semiconductor Layer]

For the semiconductor layer 161, a single crystal semiconductor, a polycrystalline semiconductor, a microcrystalline semiconductor, an amorphous semiconductor, or the like can be used alone or in combination. As a semiconductor material, a semiconductor material having a band gap (a semiconductor material that is not a zero-gap semiconductor) such as silicon or germanium can be used, for example. For example, a single element semiconductor, a compound semiconductor, or a layered substance (also referred to as an atomic layer substance, a two-dimensional material, or the like) is preferably used as a semiconductor material. As the compound semiconductor, an organic substance having semiconductor characteristics or a metal oxide having semiconductor characteristics (also referred to as an oxide semiconductor) can be used. Note that these semiconductor materials may contain an impurity as a dopant.

For example, single crystal silicon, polycrystalline silicon, microcrystalline silicon, or amorphous silicon may be used for the semiconductor layer 161. As the polycrystalline silicon, low-temperature polysilicon (LTPS) may be used, for example.

The transistor using amorphous silicon for the semiconductor layer 161 can be formed over a large-sized glass substrate, and can be fabricated at low cost. A transistor using polycrystalline silicon for the semiconductor layer 161 has high field-effect mobility and can operate at high speed. The transistor using microcrystalline silicon for the semiconductor layer 161 has higher field-effect mobility and can operate at higher speed than the transistor using amorphous silicon.

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

The semiconductor layer 161 may contain a layered substance functioning as a semiconductor. The layered substance is a general term for a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the above-described transition metal chalcogenide for the semiconductor layer enables a memory device with a high on-state current to be provided.

An oxide semiconductor has a band gap of 2 eV or more; thus, a transistor using an oxide semiconductor, which is a kind of metal oxide, for a semiconductor layer where a channel is formed (also referred to as an “OS transistor”) has an extremely low off-state current. Thus, the power consumption of a semiconductor device including an OS transistor can be reduced. The OS transistor operates stably even in a high-temperature environment and has a small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment.

Thus, the semiconductor device including the OS transistor can operate stably and have high reliability even in a high-temperature environment.

Note that an OS transistor is preferably used as the transistor 10 in this embodiment and the like. Since an OS transistor has a high withstand voltage between the source and the drain, the channel length can be shortened. Thus, the on-state current can be increased. An OS transistor is suitably used as a vertical-channel transistor.

The channel length can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L can be greater than or equal to 100 nm and less than or equal to 1 μm.

Examples of the metal oxide that can be used for the semiconductor layer of the OS transistor include indium oxide, gallium oxide, and zinc oxide. The metal oxide preferably contains at least indium (In) or zinc (Zn). The metal oxide preferably contains two or three selected from indium, an element M, and zinc. Note that the element M is a metal element or metalloid element that has a high bonding energy with oxygen, such as a metal element or metalloid element whose bonding energy with oxygen is higher than that of indium, for example.

Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (Ga—Zn oxide, also referred to as GZO), an aluminum zinc oxide (Al—Zn oxide, also referred to as AZO), an indium aluminum zinc oxide (In—Al—Zn oxide, also referred to as IAZO), an indium tin zinc oxide (In—Sn—Zn oxide), an indium titanium zinc oxide (In—Ti—Zn oxide), an indium gallium zinc oxide (In—Ga—Zn oxide, also referred to as IGZO), an indium gallium tin zinc oxide

(In—Ga—Sn—Zn oxide, also referred to as IGZTO), and an indium gallium aluminum zinc oxide (In—Ga—Al—Zn oxide, also referred to as IGAZO or IAGZO) can be used. Alternatively, an indium tin oxide containing silicon, a gallium tin oxide (Ga—Sn oxide), an aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium or in addition to indium, one or more kinds of metal elements with larger period numbers. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6.

Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of the metal elements among the main constituent elements contained in the metal oxide, the metal oxide has high crystallinity, so that diffusion of impurities in the metal oxide can be inhibited. Consequently, a change in electrical characteristics of the transistor is suppressed, and the reliability of the transistor can be improved.

By increasing the proportion of the element M atoms in the total number of atoms of the metal elements among the main constituent elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

Electrical characteristics and reliability of a transistor depend on the composition of the metal oxide used for the semiconductor layer. Therefore, by changing the composition of the metal oxide in accordance with the electrical characteristics and reliability required for the transistor, a semiconductor device having both good electrical characteristics and high reliability can be obtained.

In the case of using In—Zn oxide for the semiconductor layer of the OS transistor, a metal oxide in which the atomic proportion of indium is higher than or equal to the atomic proportion of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, In:Zn=10:1, or the neighborhood thereof.

In the case of using In—Sn oxide for the semiconductor layer of the OS transistor, a metal oxide in which the atomic proportion of indium is higher than or equal to the atomic proportion of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, In:Sn=10:1, or the neighborhood thereof.

In the case of using In—Sn—Zn oxide for the semiconductor layer of the OS transistor, a metal oxide in which the atomic proportion of indium is higher than the atomic proportion of tin can be used. It is further preferable to use a metal oxide in which the atomic proportion of zinc is higher than the atomic proportion of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8,

In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, In:Sn:Zn=40:1:10, or the neighborhood thereof.

In the case of using In—Al—Zn oxide for the semiconductor layer of the OS transistor, a metal oxide in which the atomic proportion of indium is higher than the atomic proportion of aluminum can be used. It is further preferable to use a metal oxide in which the atomic proportion of zinc is higher than the atomic proportion of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7,

In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, In:Al:Zn=40:1:10, or the neighborhood thereof.

In the case of using In—Ga—Zn oxide for the semiconductor layer of the OS transistor, a metal oxide in which the proportion of the number of indium atoms in the number of atoms of the metal elements is higher than the proportion of the number of gallium atoms can be used. It is further preferable to use a metal oxide in which the atomic proportion of zinc is higher than the atomic proportion of gallium. For example, it is possible to use a metal oxide in which the atomic ratio of metal elements is In:Ga:Zn=2:1:3, In:Ga:Zn=3:1:2, In:Ga:Zn=4:2:3, In:Ga:Zn=4:2:4.1,

In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or the neighborhood thereof.

In the case of using In-M-Zn oxide for the semiconductor layer of the OS transistor, a metal oxide in which the proportion of the number of indium atoms in the number of atoms of the metal elements is higher than the proportion of the number of element M atoms can be used. It is further preferable to use a metal oxide in which the atomic proportion of zinc is higher than the atomic proportion of the element M. For example, it is possible to use a metal oxide in which the atomic ratio of metal elements is In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or the neighborhood thereof.

In the case where a plurality of metal elements are contained as the element M, the sum of the proportions of the numbers of atoms of the metal elements can be the proportion of the number of element M atoms. In the case of In—Ga—Al—Zn oxide in which gallium and aluminum are contained as the element M, for example, the sum of the proportion of the number of gallium atoms and the proportion of the number of aluminum atoms can be the proportion of the number of element M atoms. The atomic ratio of indium to the element M to zinc is preferably within the ranges given above.

It is preferable to use a metal oxide in which the proportion of the number of indium atoms in the total number of atoms of the metal elements among the main constituent elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, in the case of using In-M-Zn oxide for the semiconductor layer, the proportion of the number of indium atoms in the sum of the numbers of atoms of indium, the element M, and zinc is preferably within the ranges given above.

As described above, when the proportion of the number of indium atoms in the total number of atoms of the metal elements among the main constituent elements contained in the metal oxide is increased, the field-effect mobility of the transistor can be increased. With the use of such a transistor, a circuit capable of high-speed operation can be fabricated. Furthermore, the area occupied by the circuit can be reduced. The application of the transistor to a large-sized display device or a high-definition display device can reduce signal delay in wirings and reduce display unevenness even if the number of wirings is increased, for example. In addition, since the area occupied by the circuit can be reduced, the bezel of the display device can be narrowed.

For analysis of the composition of a metal oxide, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an ALD method is suitable for forming the metal oxide. Note that in the case where the metal oxide is formed by a sputtering method, the atomic ratio of a target may be different from the atomic ratio of the metal oxide. In particular, the atomic proportion of zinc in the metal oxide is lower than the atomic proportion of zinc in the target in some cases. Specifically, the atomic proportion of zinc contained in the metal oxide may be approximately 40% to 90% of the atomic proportion of zinc contained in the target.

With use of a metal oxide that does not contain gallium or has low gallium content percentage in the semiconductor layer, the transistor can be highly reliable against positive bias application. In other words, the amount of change in the threshold voltage of the transistor in the PBTS test can be small. In the case of using a metal oxide that contains gallium, the gallium content percentage is preferably lower than the indium content percentage. Thus, a highly reliable transistor can be obtained.

One of the factors in change in the threshold voltage in the PBTS test is a defect state at the interface between a semiconductor layer and a gate insulating layer or in the vicinity of the interface. As the density of defect states increases, degradation in the PBTS test becomes more significant. Generation of the defect states can be inhibited by reducing the gallium content percentage in a region of the semiconductor layer that is in contact with the gate insulating layer.

The following can be given as an example of the reason why the amount of change in the threshold voltage in the PBTS test can be reduced when a metal oxide that does not contain gallium or has a low gallium content percentage is used for the semiconductor layer. Gallium contained in the metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, carrier (here, electron) trap sites are probably generated easily. This might cause the change in the threshold voltage when a positive potential is supplied to the gate and carriers are trapped at the interface between the semiconductor layer and the gate insulating layer.

Specifically, in the case where an In—Ga—Zn oxide is used for the semiconductor layer, a metal oxide in which the atomic proportion of indium is higher than that of gallium can be used as the semiconductor layer. It is further preferable to use a metal oxide in which the atomic proportion of zinc is higher than the atomic proportion of gallium. In other words, a metal oxide in which the atomic ratios of metal elements satisfy In >Ga and Zn>Ga is preferably used as the semiconductor layer.

For example, it is possible to use, for the semiconductor layer of the OS transistor, a metal oxide in which the atomic ratio of metal elements is In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, or the neighborhood thereof.

It is preferable to use, for the semiconductor layer of the OS transistor, a metal oxide in which the proportion of the number of gallium atoms in the number of atoms of the metal elements contained is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the proportion of the number of gallium atoms in the number of atoms of the metal elements in the semiconductor layer enables the transistor to be highly resistant to the PBTS test. Note that an oxygen vacancy (Vo) is less likely to be generated in the metal oxide when the metal oxide contains gallium.

A metal oxide not containing gallium may be used for the semiconductor layer of the OS transistor. For example, an In—Zn oxide can be used for the semiconductor layer. In that case, when the proportion of the number of indium atoms in the number of atoms of the metal elements contained in the metal oxide is increased, the field-effect mobility of the transistor can be increased. By contrast, when the proportion of the number of zinc atoms in the number of atoms of the metal elements contained in the metal oxide is increased, the metal oxide has high crystallinity; thus, a change in the electrical characteristics of the transistor can be inhibited and the reliability can be improved. Alternatively, a metal oxide that contains neither gallium nor zinc, such as indium oxide, can be used for the semiconductor layer. The use of a metal oxide not containing gallium can make a change in the threshold voltage particularly in the PBTS test extremely small. For example, an oxide containing indium and zinc can be used for the semiconductor layer. In that case, for example, a metal oxide where the atomic ratio of metal elements is In:Zn=2:3, In:Zn=4:1, or the neighborhood thereof can be used.

Although the case of using gallium is described as a typical example, the same applies to the case where the element M is used instead of gallium. A metal oxide in which the atomic proportion of indium is higher than the atomic proportion of the element Mis preferably used for the semiconductor layer. Furthermore, a metal oxide in which the atomic proportion of zinc is higher than the atomic proportion of the element M is preferably used.

The use of a metal oxide having a low content percentage of the element M for the semiconductor layer enables the transistor to be highly reliable against positive bias application.

The use of the transistor as a transistor that is required to have high reliability against positive bias application enables a semiconductor device to have high reliability.

Next, the reliability of a transistor against light is described.

Light incidence on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in an NBTIS test, for example.

The high content percentage of the element M in the metal oxide used for the semiconductor layer enables the transistor to be highly reliable against light. In other words, the amount of change in the threshold voltage of the transistor in the NBTIS test can be small.

Specifically, in a metal oxide in which the atomic proportion of the element M is higher than or equal to the atomic proportion of indium, the band gap is increased and accordingly the amount of change in the threshold voltage of the transistor in the NBTIS test can be reduced. The band gap of the metal oxide in the semiconductor layer is preferably greater than or equal to 2.0 eV, further preferably greater than or equal to 2.5 eV, still further preferably greater than or equal to 3.0 eV, yet further preferably greater than or equal to 3.2 eV, yet still further preferably greater than or equal to 3.3 eV, yet still further preferably greater than or equal to 3.4 eV, yet still further preferably greater than or equal to 3.5 eV.

For example, it is possible to use, for the semiconductor layer, a metal oxide in which the atomic ratio of the metal elements is In:M:Zn=1:1:1, In:M:Zn=1:1:1.2, In:M:Zn=1:3:2, In:M:Zn=1:3:3, In:M:Zn=1:3:4, or the neighborhood thereof.

For the semiconductor layer, it is particularly preferable to use a metal oxide in which the proportion of the number of element M atoms in the number of atoms of the metal elements contained is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet further preferably higher than or equal to 50 atomic % and lower than or equal to 60 atomic %.

In the case where In—Ga—Zn oxide is used for the semiconductor layer, a metal oxide in which the proportion of the number of indium atoms in the number of atoms of the metal elements is lower than or equal to the proportion of the number of gallium atoms can be used. For example, it is possible to use a metal oxide in which the atomic ratio of the metal elements is In:Ga:Zn=1:1:1, In:Ga:Zn=1:1:1.2, In:Ga:Zn=1:3:2, In:Ga:Zn=1:3:3, In:Ga:Zn=1:3:4, or the neighborhood thereof.

For the semiconductor layer, it is particularly preferable to use a metal oxide in which the proportion of the number of gallium atoms in the number of atoms of the metal elements contained is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, still further preferably higher than or equal to 40 atomic % and lower than or equal to 60 atomic %, yet further preferably higher than or equal to 50 atomic % and lower than or equal to 60 atomic %.

The use of a metal oxide having a high content percentage of the element M for the semiconductor layer enables the transistor to be highly reliable against light. The use of the transistor as a transistor that is required to have high reliability against light enables a semiconductor device to have high reliability.

The semiconductor layer may have a stacked-layer structure including two or more metal oxide layers. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the semiconductor layer may have different compositions. For example, a stacked-layer structure of two layers of a first metal oxide layer having a composition of In:M:Zn=1:3:4 [atomic ratio] or the neighborhood thereof and a second metal oxide layer having a composition of In:M:Zn=1:1:1 [atomic ratio] or the neighborhood thereof and overlapping with the first metal oxide layer may be employed. In particular, gallium or aluminum is preferably used as the element M. A stacked-layer structure of any one selected from indium oxide, indium gallium oxide, and IGZO and any one selected from IAZO, IAGZO, and ITZO (registered trademark) may be employed, for example.

For example, a stacked-layer structure of a first metal oxide layer having a composition of In:M:Zn=1:1:1 [atomic ratio] or the neighborhood thereof and a second metal oxide layer having a composition of In:Zn=4:1 [atomic ratio] or the neighborhood thereof and being provided over the first metal oxide layer may be employed.

For example, a stacked-layer structure of three layers in which a semiconductor layer having an atomic ratio of metal elements of In:Ga:Zn=1:1:1 is the first layer, a semiconductor layer having an atomic ratio of metal elements of In:Zn=4:1 is the second layer, and a semiconductor layer having an atomic ratio of metal elements of In:Ga:Zn=1:1:1 is the third layer may be employed. Note that the band gaps of the first and third semiconductor layers are preferably larger than the band gap of the second semiconductor layer. With this structure, the main current path can be the second layer, so that what is called a buried channel structure can be obtained.

It is preferable to use a metal oxide layer having crystallinity as the semiconductor layer. For example, a metal oxide layer having a CAAC (c-axis aligned crystal) structure, a polycrystalline structure, a nano-crystal (nc) structure, or the like can be used. With use of a metal oxide layer having crystallinity as the semiconductor layer, the density of defect states in the semiconductor layer can be reduced, which enables the display device to have high reliability.

The higher the crystallinity of the metal oxide layer used as the semiconductor layer is, the lower the density of defect states in the semiconductor layer can be. By contrast, the use of a metal oxide layer having low crystallinity enables a transistor to allow the flow of a large amount of current.

In the case where the metal oxide layer is formed by a sputtering method, the higher the substrate temperature (the stage temperature) in the formation is, the higher the crystallinity of the metal oxide layer can be. The crystallinity of the metal oxide layer can be increased as the proportion of a flow rate of an oxygen gas to the whole deposition gas (hereinafter, also referred to as oxygen flow rate ratio) used in formation becomes higher.

The semiconductor layer of the OS transistor may have a stacked-layer structure of two or more metal oxide layers having different crystallinities. For example, in a stacked-layer structure of a first metal oxide layer and a second metal oxide layer provided over the first metal oxide layer, the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer may have the same composition or substantially the same compositions. Employing a stacked-layer structure of metal oxide layers having the same composition can reduce the manufacturing cost because the metal oxide layers can be formed using the same sputtering target. For example, with the use of the same sputtering target and different oxygen flow rate ratios, a stacked-layer structure of two or more metal oxide layers having different crystallinities can be formed. Note that the two or more metal oxide layers included in the semiconductor layer may have different compositions.

The channel length L of the transistor 10 described in this embodiment is determined by the thickness of the insulating layer provided between the conductive layer 160 and the conductive layer 155. Thus, a transistor with a short channel length I can be fabricated with high accuracy. Furthermore, variations in characteristics among the transistors 10 are also reduced. Accordingly, the operation of the semiconductor device including the transistor 10 can be stabilized and the reliability thereof can be improved. When the variations in characteristics are reduced, the circuit design flexibility of the semiconductor device is increased and the operation voltage can be reduced. Thus, the power consumption of the semiconductor device can be reduced.

In the case where an oxide semiconductor is used for the semiconductor layer 161, a material containing hydrogen is preferably used for the insulating layer 156 and the insulating layer 158. When the insulating layer containing hydrogen is in contact with the oxide semiconductor, a region of the oxide semiconductor that is in contact with the insulating layer becomes n-type and can function as a source region or a drain region. For this insulating layer, a material containing silicon, nitrogen, and hydrogen is used, for example. Specifically, silicon nitride containing hydrogen, silicon nitride oxide containing hydrogen, or the like is used.

In the case where an oxide semiconductor is used for the semiconductor layer 161, a conductive material that makes the oxide semiconductor have n-type conductivity is preferably used for the conductive layer 155 in contact with the semiconductor layer 161 and the conductive layer 160 in contact with the semiconductor layer 161. For example, a conductive material containing nitrogen may be used. For example, a conductive material containing nitrogen and titanium or tantalum is used. Another conductive material may be provided so as to overlap with the conductive material containing nitrogen.

In contrast, for the insulating layer 157, a material which contains oxygen and in which the amount of hydrogen is reduced is preferably used. For example, a material containing silicon and oxygen is used. Specifically, silicon oxide, silicon oxynitride, or the like is used. Since hydrogen is an impurity element in an oxide semiconductor, when the semiconductor layer 161 which is an oxide semiconductor and the insulating layer 157 in which the amount of hydrogen is reduced are in contact with each other, the semiconductor layer 161 is less likely to become n-type. Furthermore, when the semiconductor layer 161 which is an oxide semiconductor and the insulating layer 157 containing oxygen are in contact with each other, oxygen vacancies in the semiconductor layer 161 are reduced and the transistor 10 has stable characteristics, improving the reliability.

When an oxide semiconductor is used for the semiconductor layer 161, the insulating layer 157 preferably contains excess oxygen. In this specification and the like, “excess oxygen” refers to oxygen that is released by heating. In the case where a material containing excess oxygen is used for the insulating layer 157, a material through which oxygen is less likely to pass is preferably used for the insulating layer 156 and the insulating layer 158. Examples of the material through which oxygen is less likely to pass include a nitride of silicon and an oxide containing aluminum and/or hafnium. With the use of the material through which oxygen is less likely to pass for the insulating layer 156 and the insulating layer 158, excess oxygen contained in the insulating layer 157 is less likely to be released to a lower layer or an upper layer. Thus, sufficient oxygen can be supplied to the oxide semiconductor. For example, an insulating layer containing silicon and oxygen (the insulating layer 157) is provided between two insulating layers containing silicon and nitrogen (the insulating layer 156 and the insulating layer 158).

In the case where an oxide semiconductor is used for the semiconductor layer 161 and a material containing hydrogen is used for the insulating layer 156 and the insulating layer 158, a region of the semiconductor layer 161 in contact with the conductive layer 160 and a region of the semiconductor layer 161 in contact with the insulating layer 158 serve as one of a source (a source region) and a drain (a drain region). A region of the semiconductor layer 161 in contact with the conductive layer 155 and a region of the semiconductor layer 161 in contact with the insulating layer 156 serve as the other of the source (the source region) and the drain (the drain region). Thus, a thickness/of the insulating layer 157 determines the channel length L of the transistor 10 (see FIG. 12A).

A material that contains no hydrogen or an extremely small amount of hydrogen may be used for the insulating layer 156 and the insulating layer 158. For example, silicon nitride that contains an extremely small amount of hydrogen or silicon nitride oxide that contains an extremely small amount of hydrogen may be used. In that case, the region of the semiconductor layer 161 in contact with the insulating layer 156 and the region of the semiconductor layer 161 in contact with the insulating layer 158 do not become n-type. Thus, the region of the semiconductor layer 161 in contact with the conductive layer 160 serves as one of a source (a source region) and a drain (a drain region). The region of the semiconductor layer 161 in contact with the conductive layer 155 serves as the other of the source (the source region) and the drain (the drain region). In that case, a thickness ts obtained by combining the thicknesses of the insulating layer 156, the insulating layer 157, and the insulating layer 158 corresponds to the channel length L of the transistor 10 (see FIG. 12A).

The channel length L can be controlled by adjusting the thicknesses of the insulating layer 156, the insulating layer 157, and the insulating layer 158. The channel length L can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length I. can be greater than or equal to 100 nm and less than or equal to 1 μm.

Although an example in which three insulating layers (the insulating layer 156, the insulating layer 157, and the insulating layer 158) are provided between the conductive layer 155 and the conductive layer 160 is shown in this embodiment, the number of insulating layers between the conductive layer 155 and the conductive layer 160 is not limited thereto. The number of insulating layers between the conductive layer 155 and the conductive layer 160 may be one, two, four, or more.

Since the semiconductor layer 161 is provided in the opening 159, a length p of the perimeter of the opening 159 corresponds to the channel width W of the transistor 10 (see FIG. 12C). The length p of the perimeter is obtained at a position corresponding to the half (½) of the thickness/of the insulating layer 157 or the half (ts/2) of the thickness ts, for example. Note that the length of the perimeter of the opening 159 at an arbitrary position may be regarded as the channel width W as necessary. For example, the length p of the perimeter at the lowermost portion of the opening 159 may be regarded as the channel width W, or the length p of the perimeter at the uppermost portion of the opening 159 may be regarded as the channel width W.

The outline (the planar shape) of the opening 159 seen from the Z direction is illustrated as being circular in FIG. 12C but is not limited to this. For example, the outline of the opening 159 seen from the Z direction may be elliptical (see FIG. 12D) or rectangular (see FIG. 12E). Note that FIG. 12E illustrates a rectangle having rounded corner portions. For example, the outline of the opening 159 seen from the Z direction may have a shape including a straight portion and/or a curved portion (see FIG. 12F).

In the transistor 10 of one embodiment of the present invention, the capacitance value of parasitic capacitance generated between the gate and the source and the capacitance value of parasitic capacitance generated between the gate and the drain are different from each other.

Specifically, the capacitance value of a capacitor C1 generated in a region where the conductive layer 160 and the conductive layer 163 overlap with each other over the insulating layer 145 is larger than the capacitance value of a capacitor C2 generated in a region where the conductive layer 155 and the conductive layer 163 overlap with each other in the opening 159 (see FIG. 11D and FIG. 12B).

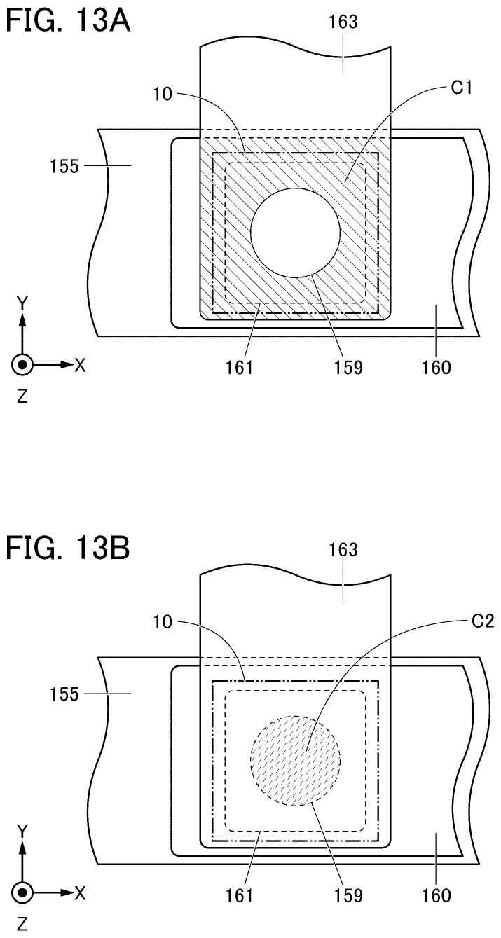

FIGS. 13A and 13B illustrate plan views similar to FIG. 11A. When the transistor 10 of one embodiment of the present invention is seen from the Z direction, the conductive layer 163 overlaps with the conductive layer 160 in the periphery of the opening 159 to surround the opening 159, and overlaps with the conductive layer 160 in the bottom portion of the opening 159.

In FIG. 13A, a region functioning as the capacitor C1 when seen from the Z direction is hatched. A region where the conductive layer 160 and the conductive layer 163 overlap with each other with the semiconductor layer 161 and the insulating layer 162 interposed therebetween over the insulating layer 145 functions as the capacitor C1 (see FIG. 12B and FIG. 13A). Note that the insulating layer 145 and the insulating layer 162 are not illustrated in FIG. 13A.

In FIG. 13B, a region functioning as the capacitor C2 when seen from the Z direction is hatched. In the bottom portion of the opening 159, a region where the conductive layer 155 and the conductive layer 163 overlap with each other with the semiconductor layer 161 and the insulating layer 162 interposed therebetween functions as the capacitor C2 (see FIG. 12B and FIG. 13B). Note that the insulating layer 145 and the insulating layer 162 are not illustrated in FIG. 13B.

According to FIG. 13A and FIG. 13B, the region functioning as the capacitor C1 has a larger area than the region functioning as the capacitor C2. When the area of the region functioning as the capacitor C1 is larger than the area of the region functioning as the capacitor C2, the capacitance value of the capacitor C1 is larger than that of the capacitor C2.

When the area where the conductive layer 155 and the conductive layer 163 overlap with each other is changed in order to change the capacitance value of the capacitor C2, the shape of the opening 159 is changed; that is, the length p of the perimeter of the opening 159 is changed. Since the change in the length p of the perimeter directly influences the electrical characteristics of the transistor 10, the capacitance value of the capacitor C2 is difficult to control.

In contrast, the area where the conductive layer 163 and the conductive layer 160 overlap with each other is easy to control and less likely to influence the electrical characteristics of the transistor 10. For example, by increasing the area where the conductive layer 163 and the conductive layer 160 overlap with each other, the capacitance value of the capacitor C1 can be increased.

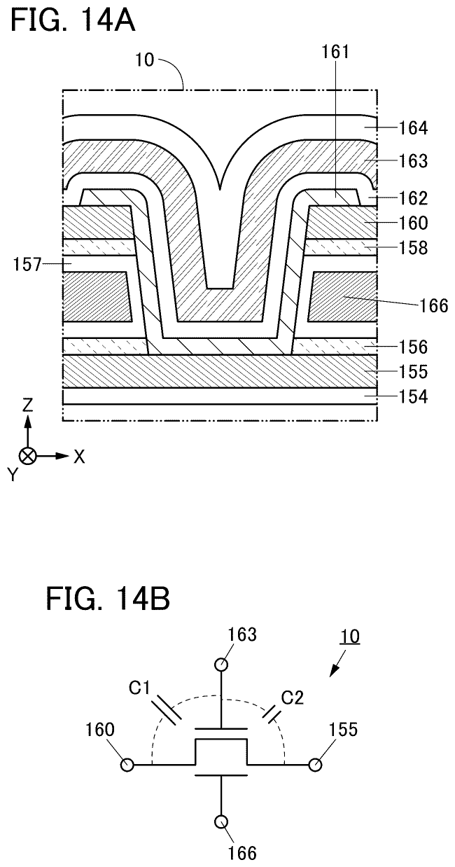

As illustrated in a cross-sectional view in FIG. 14A, a conductive layer 166 which is close to the semiconductor layer 161 may be provided in the insulating layer 157. The conductive layer 166 is provided not to be in contact with the semiconductor layer 161. The conductive layer 166 is preferably provided to surround the semiconductor layer 161. The conductive layer 166 can function as a back gate electrode of the transistor 10 when provided close to the semiconductor layer 161 without being in contact with the semiconductor layer 161. Thus, the transistor 10 illustrated in FIG. 14A functions as a transistor having a back gate (a back gate electrode). Note that FIG. 14B is an equivalent circuit diagram of the transistor 10 illustrated in FIG. 14A.

Here, a back gate electrode is described. In general, a back gate electrode is formed using a conductive layer and positioned so that a channel formation region in a semiconductor layer is sandwiched between the gate electrode and the back gate electrode. Thus, the back gate electrode can function in a manner similar to that of the gate electrode. The potential of the back gate electrode may be equal to the potential of the gate electrode or may be a GND potential or a given potential. When the gate electrode and the back gate electrode are electrically connected to each other, the on-state current of the transistor can be increased. When the potential of the back gate electrode is not equal to and is changed independently of the potential of the gate electrode, the threshold voltage of the transistor can be changed.

In addition, the gate electrode and the back gate electrode are formed using conductive layers and thus each have a function of preventing an electric field generated outside the transistor from affecting the channel formation region in the semiconductor layer (in particular, an electric field blocking function against static electricity and the like). As a result, variations in characteristics among transistors are reduced. Furthermore, degradation of transistor characteristics due to the GBTS test is inhibited. For example, with the back gate electrode, a change in threshold voltage in the GBTS test can be inhibited. The transistor including the back gate electrode has a smaller amount of change in threshold voltage in the GBTS test than a transistor including no back gate electrode.

Note that the GBTS (NBTS and PBTS) test is a kind of accelerated test and can evaluate, in a short time, a change by long-term use (i.e., a change over time) in characteristics of a transistor. In particular, the amount of change in the threshold voltage of the transistor in the GBTS test is an important indicator for examination of the reliability. The smaller the amount of change in the threshold voltage in the GBTS test is, the higher the reliability of the transistor becomes.

In the case where light enters from the back gate electrode side, when the back gate electrode is formed using a light-blocking conductive film, the light can be prevented from entering the semiconductor layer from the back gate electrode side. Similarly, when the gate electrode is formed using a light-blocking conductive film, light can be prevented from entering the semiconductor layer from the gate electrode side. When one or both of the gate electrode and the back gate electrode is/are formed using a light-blocking conductive film, photodegradation of the semiconductor layer can be prevented and degradation in electrical characteristics of the transistor, such as a shift of the threshold voltage, can be prevented.

In addition, the gate electrode and the back gate electrode can block an electric field generated from the drain electrode so that the electric field do not influence the semiconductor layer. Thus, a change in the rising voltage of on-state current due to a change in drain voltage can be inhibited. Note that this effect is significant when a potential is supplied to each of the gate electrode and the back gate electrode.

When a plurality of transistors 10 are connected in parallel, an apparent channel width W of the transistor 10 can be increased. A larger channel width W of the transistor 10 leads to a smaller resistance value between the source and the drain in an on state and thus/d in the on state can be increased.

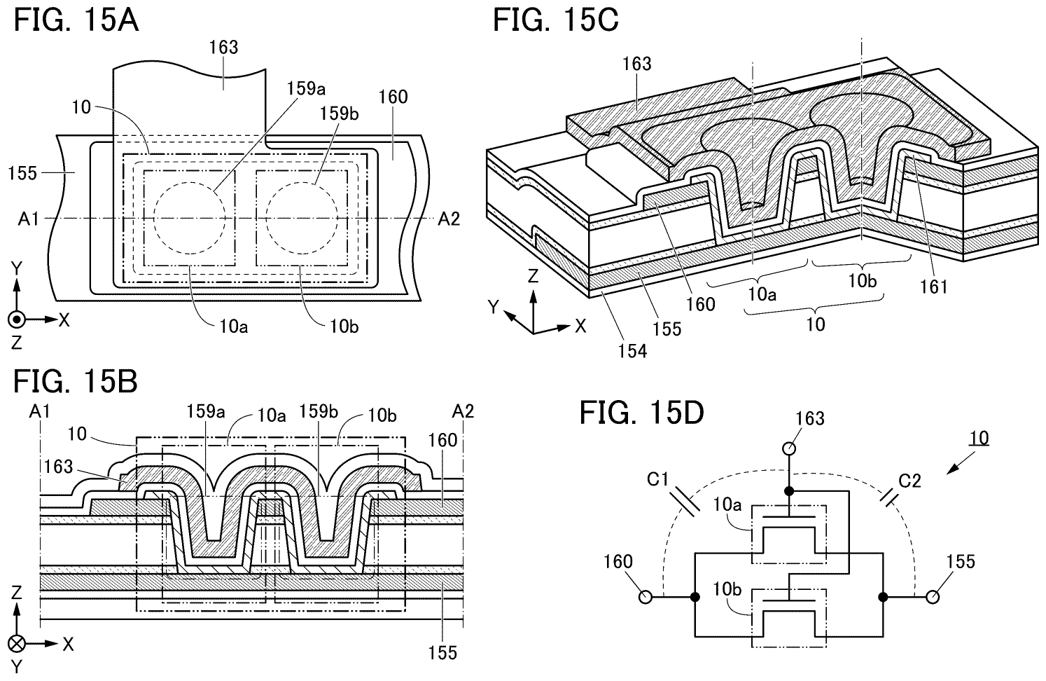

FIG. 15A is a plan view of a transistor 10 including a transistor 10a and a transistor 10b. FIG. 15B is a cross-sectional view of a portion indicated by the dashed-dotted line Al-A2 in FIG. 15A. FIG. 15C is a perspective view of the transistor 10 including the transistor 10a and the transistor 10b. FIG. 15D is an equivalent circuit diagram of the transistor 10 including the transistor 10a and the transistor 10b. For easy understanding of the structure of the transistor 10, some components of the transistor 10 are not illustrated in FIG. 15A or FIG. 15C.

Each of the transistor 10a and the transistor 10b has a structure similar to that of the transistor 10 described with reference to FIG. 11 and FIG. 12. The transistor 10a is provided in a region including an opening 159a, and the transistor 10b is provided in a region including an opening 159b. The opening 159a and the opening 159b can be formed in a manner similar to that of the opening 159.

A part of the conductive layer 155 functions as one of a source electrode and a drain electrode of the transistor 10a, and another part of the conductive layer 155 functions as one of a source electrode and a drain electrode of the transistor 10b. A part of the conductive layer 160 functions as the other of the source electrode and the drain electrode of the transistor 10a, and another part of the conductive layer 160 functions as the other of the source electrode and the drain electrode of the transistor 10b. A part of the conductive layer 163 functions as a gate electrode of the transistor 10a, and another part of the conductive layer 163 functions as a gate electrode of the transistor 10b.

As illustrated in the equivalent circuit diagram in FIG. 15D, the one of the source and the drain of the transistor 10a and the one of the source and the drain of the transistor 10b are electrically connected to each other, and the other of the source and the drain of the transistor 10a and the other of the source and the drain of the transistor 10b are electrically connected to each other. The gate of the transistor 10a and the gate of the transistor 10b are electrically connected to each other. Thus, the transistor 10a and the transistor 10b switch between on and off states at the same time and function as one transistor 10.

When a plurality of transistors 10 (here, the transistor 10a and the transistor 10b) are connected in series, an apparent channel length/of the transistor 10 can be increased. A larger channel length/leads to better saturation characteristics of the transistor 10.

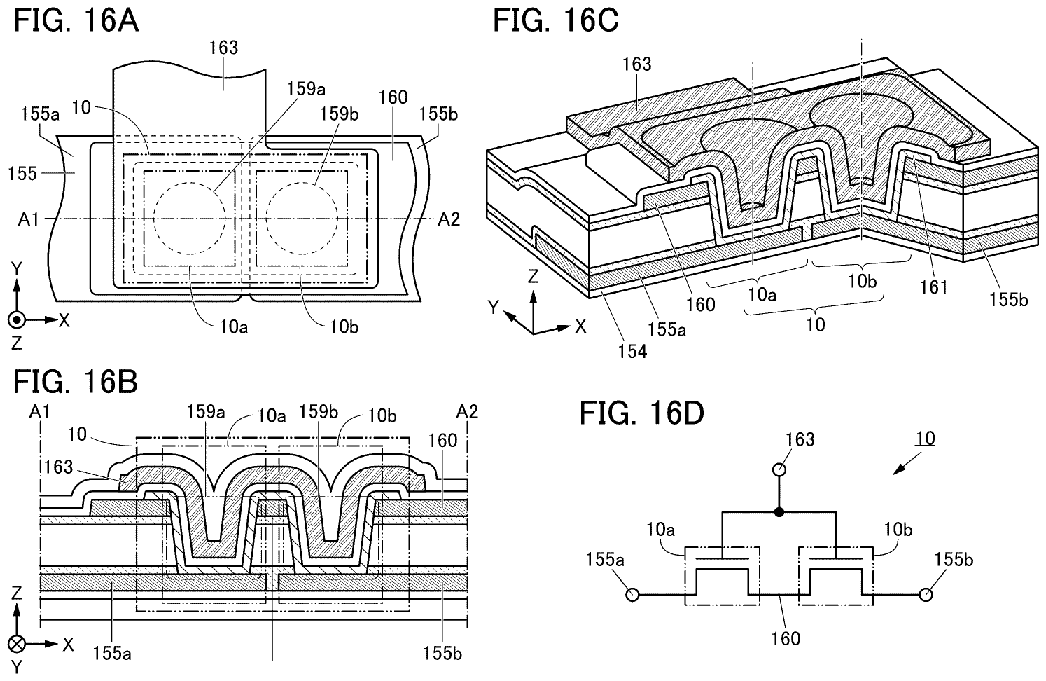

FIG. 16A is a plan view of a transistor 10 including a transistor 10a and a transistor 10b. FIG. 16B is a cross-sectional view of a portion indicated by the dashed-dotted line Al-A2 in FIG. 16A. FIG. 16C is a perspective view of the transistor 10 including the transistor 10a and the transistor 10b. FIG. 16D is an equivalent circuit diagram of the transistor 10 including the transistor 10a and the transistor 10b. For easy understanding of the structure of the transistor 10, some components of the transistor 10 are not illustrated in FIG. 16A or FIG. 16C.

Each of the transistor 10a and the transistor 10b has a structure similar to that of the transistor 10 described with reference to FIG. 15, but is different in that the conductive layer 155 is divided into a conductive layer 155a and a conductive layer 155b.

The conductive layer 155a functions as one of a source electrode and a drain electrode of the transistor 10a, and a part of the conductive layer 160 functions as the other of the source electrode and the drain electrode of the transistor 10a. Another part of the conductive layer 160 functions as one of a source electrode and a drain electrode of the transistor 10b, and the conductive layer 155b functions as the other of the source electrode and the drain electrode of the transistor 10b. As in the transistor 10 described with reference to FIG. 15, a part of the conductive layer 163 functions as a gate electrode of the transistor 10a, and another part of the conductive layer 163 functions as a gate electrode of the transistor 10b.

In the equivalent circuit diagram in FIG. 16D, the other of the source and the drain of the transistor 10a and the one of the source and the drain of the transistor 10b are electrically connected to each other, and the gate of the transistor 10a and the gate of the transistor 10b are electrically connected to each other. Thus, the transistor 10a and the transistor 10b switch between on and off states at the same time and function as one transistor 10.

[Planar and cross-sectional structural examples of signal output circuit 110]

Next, planar and cross-sectional structural examples of the signal output circuits 110 will be described with reference to drawings. In this embodiment, planar and cross-sectional structural examples of the signal output circuit 110a illustrated in FIG. 2 among the signal output circuits 110 will be described.

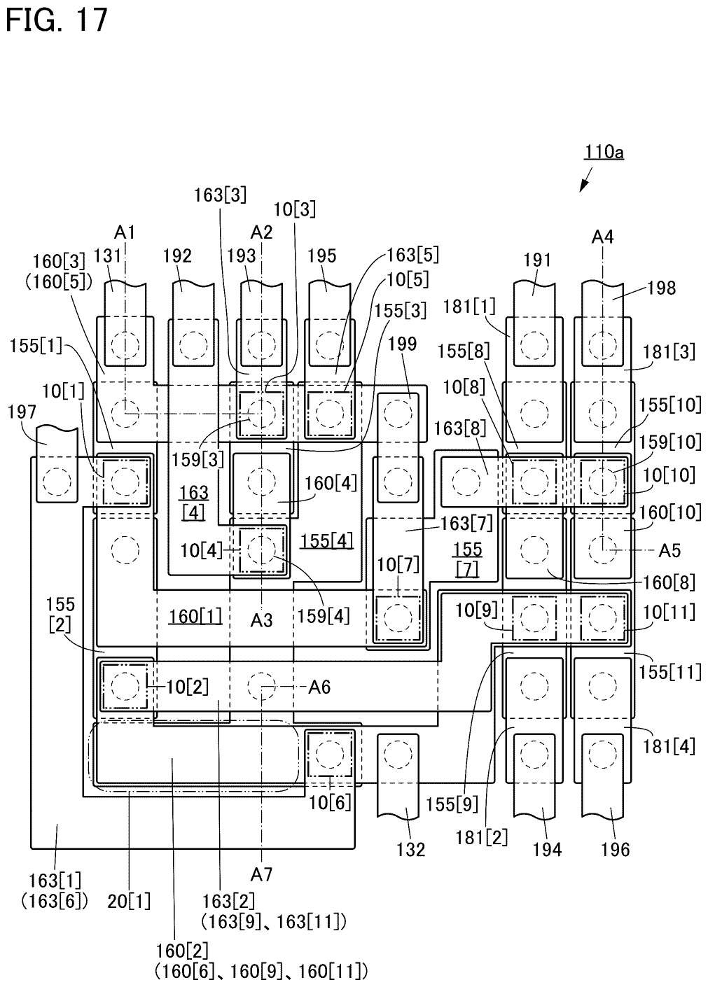

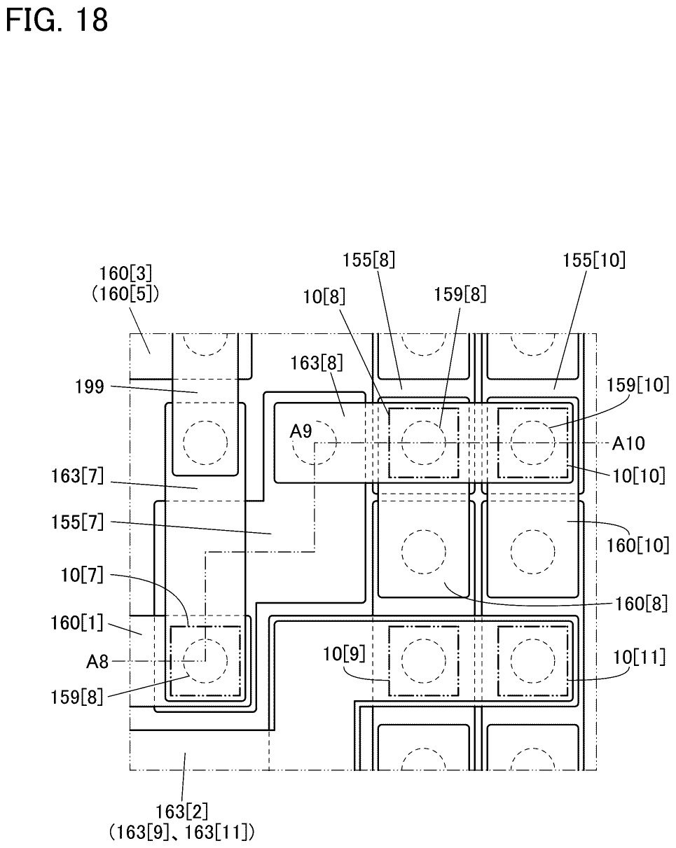

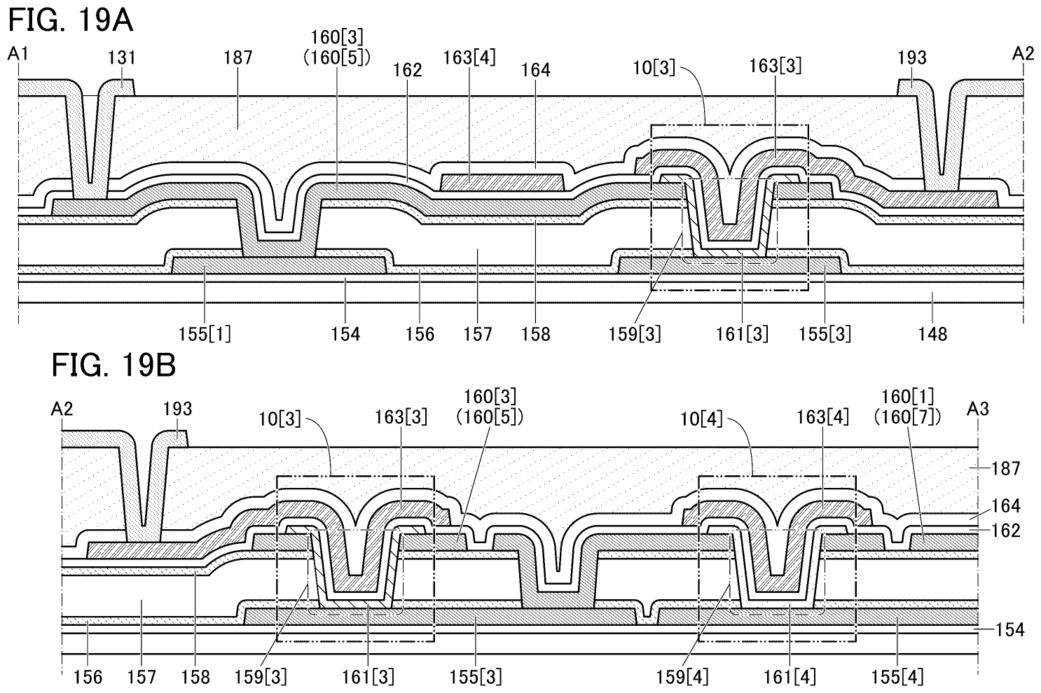

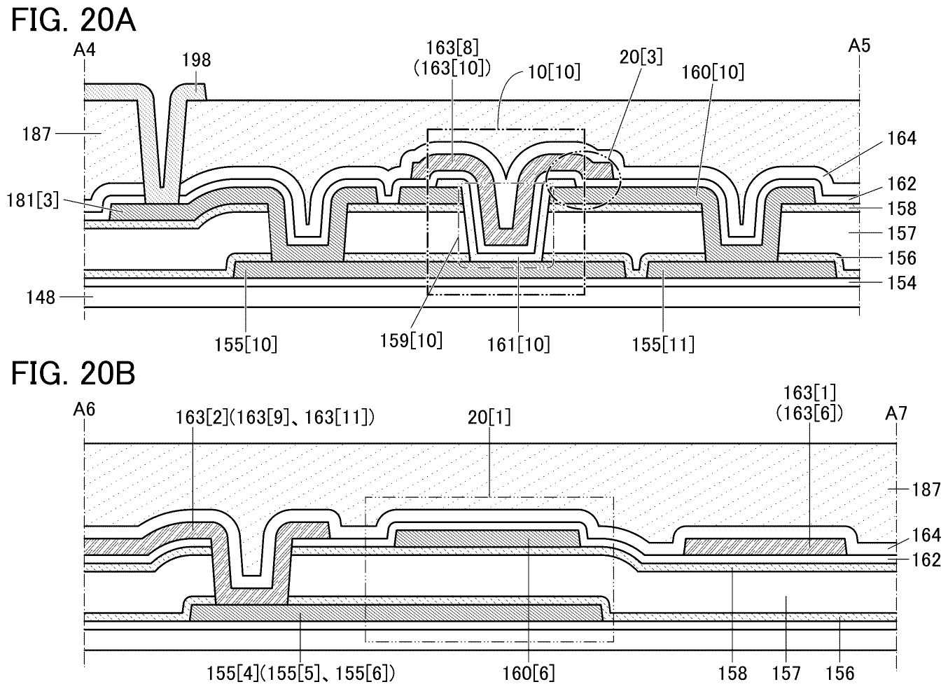

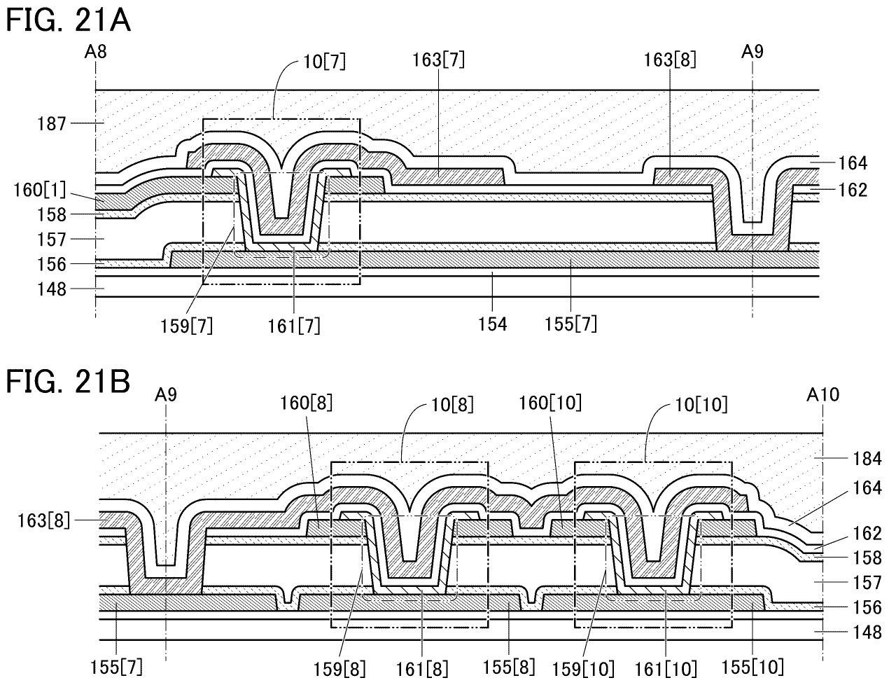

FIG. 17 is a diagram illustrating a planar structural example of the signal output circuit 110a. FIG. 18 is an enlarged plan view of a region including the transistor 10[7] to the transistor 10[11] in FIG. 17. FIG. 19A is a diagram illustrating a cross-sectional structural example of a portion indicated by the dashed-dotted line along Al-A2 in FIG. 17. FIG. 19B is a diagram illustrating a cross-sectional structural example of a portion indicated by the dashed-dotted line along A2-A3 in FIG. 17. FIG. 20A is a diagram illustrating a cross-sectional structural example of a portion indicated by the dashed-dotted line along A4-A5 in FIG. 17. FIG. 20B is a diagram illustrating a cross-sectional structural example of a portion indicated by the dashed-dotted line along A6-A7 in FIG. 17. FIG. 21A is a diagram illustrating a cross-sectional structural example of a portion indicated by the dashed-dotted line along A8-A9 in FIG. 18. FIG. 21B is a diagram illustrating a cross-sectional structural example of a portion indicated by the dashed-dotted line along A9-Al0 in FIG. 18.

In this embodiment, a structural example in which the above-described VFET is used as the transistor 10 of the signal output circuit 110a is described. The signal output circuit 110a includes the insulating layer 154 over the substrate 148 and the conductive layer 155 (e.g., a conductive layer 155[1] and a conductive layer 155[3] in FIG. 19A, a conductive layer 155[3] and

a conductive layer 155[4] in FIG. 19B, and a conductive layer 155[10] and a conductive layer 155[11] in FIG. 20) over the insulating layer 154.

Note that the stacked-layer structure of the signal output circuit 110a in which the above-described VFET is used as the transistor 10 has a portion in common with the above-described structural example of the transistor 10. Thus, a portion different from the above-described structural example of the transistor 10 will be mainly described here.

In this specification and the like, an identifying reference numeral[1] is sometimes added to a reference numeral for a component related to the transistor 10[1]. For example, the conductive layer 163 functioning as the gate electrode of the transistor 10[1] is sometimes referred to as a conductive layer 163[1]. Note that an identifying reference numeral for any of the plurality of transistors 10 is sometimes added to a reference numeral for a component commonly related to the plurality of transistors 10. For example, the conductive layer 163 functioning as the gate

electrode of each of the transistor 10[2], the transistor 10[9], and the transistor 10[11] is sometimes referred to as a conductive layer 163[2].

For example, the opening 159 and the semiconductor layer 161 related to the transistor 10[3] are sometimes referred to as an opening 159[3] and a semiconductor layer 161[3]. For example, the opening 159 and the semiconductor layer 161 related to the transistor 10[4] are sometimes referred to as an opening 159[4] and a semiconductor layer 161[4]. For example, the opening 159 and the semiconductor layer 161 related to the transistor 10[7] are sometimes referred to as an opening 159[7] and a semiconductor layer 161[7]. For example, the opening 159 and the semiconductor layer 161 related to the transistor 10[8] are sometimes referred to as an opening 159[8] and a semiconductor layer 161[8]. For example, the opening 159 and the semiconductor

layer 161 related to the transistor 10[10] are sometimes referred to as an opening 159[10] and a semiconductor layer 161[10].

The signal output circuit 110a includes a conductive layer 181[1] to a conductive layer 181[4] over the insulating layer 158 (see FIG. 17 and FIG. 20A). The conductive layer 181 (the conductive layer 181[1] to the conductive layer 181[4]) can be formed using a material and a method similar to those for the conductive layer 160. The conductive layer 181 can be formed at the same time as the conductive layer 160.

The signal output circuit 110a includes an insulating layer 187 over the insulating layer 164. The insulating layer 187 preferably functions as a planarization layer for reducing a difference in level generated by a transistor, a capacitor, a wiring, or the like formed in a lower layer. An organic insulating film is suitable as a material functioning as a planarization layer. After the insulating layer 187 is formed with an inorganic material or an organic material, planarization treatment using a chemical mechanical polishing (CMP) method or the like may be performed on the insulating layer 187.

The signal output circuit 110a includes a conductive layer 191 to a conductive layer 199, the wiring 131, and the wiring 132 over the insulating layer 187 (see FIG. 17, FIG. 19A, FIG. 19B, and FIG. 20A). The conductive layer 191 to the conductive layer 199, the wiring 131, and the wiring 132 can be formed using a material and a method similar to those for other conductive layers. The conductive layer 191 functions as the terminal 111, the conductive layer 192 functions as the terminal 112, the conductive layer 193 functions as the terminal 113, the conductive layer 194 functions as the terminal 114, the conductive layer 195 functions as the terminal 115, the conductive layer 196 functions as the terminal 116, the conductive layer 197 functions as the terminal 117, and the conductive layer 198 functions as the terminal 118.

In the signal output circuit 110a, an opening that penetrates the insulating layer 162, the insulating layer 164, and the insulating layer 187 is provided over each of the conductive layer 160[2], the conductive layer 160[3], the conductive layer 181[1], the conductive layer 181[2], the conductive layer 181[3], and the conductive layer 181[4].

Through the opening provided over the conductive layer 160[2], the wiring 132 and the conductive layer 160[2] are electrically connected to each other. More specifically, the wiring 132 and the conductive layer 160[2] are electrically connected to each other in the bottom portion of the opening provided over the conductive layer 160[2].

Two openings are provided over the conductive layer 160[3]. Through one of the two openings, the wiring 131 and the conductive layer 160[3] are electrically connected to each other. Through the other of the two openings, the conductive layer 199 and the conductive layer 160[3] are electrically connected to each other.

Through the opening provided over the conductive layer 181[1], the conductive layer 191 and the conductive layer 181[1] are electrically connected to each other. Through the opening provided over the conductive layer 181[2], the conductive layer 194 and the conductive layer 181[2] are electrically connected to each other. Through the opening provided over the conductive layer 181[3], the conductive layer 198 and the conductive layer 181[3] are electrically connected to each other. Through the opening provided over the conductive layer 181[4], the conductive layer 196 and the conductive layer 181[4] are electrically connected to each other.

In the signal output circuit 110a, an opening that penetrates the insulating layer 164 and the insulating layer 187 is provided over each of the conductive layer 163[1], the conductive layer 163[3], the conductive layer 163[4], the conductive layer 163[5], and the conductive layer 163[7].

Through the opening provided over the conductive layer 163[1], the conductive layer 197 and the conductive layer 163[1] are electrically connected to each other. Through the opening provided over the conductive layer 163[3], the conductive layer 193 and the conductive layer 163[3] are electrically connected to each other. Through the opening provided over the conductive layer 163[4], the conductive layer 192 and the conductive layer 163[4] are electrically connected to each other. Through the opening provided over the conductive layer 163[5], the conductive layer 195 and the conductive layer 163[5] are electrically connected to each other. Through the opening provided over the conductive layer 163[7], the conductive layer 199 and the conductive layer 163[7] are electrically connected to each other. Note that the conductive layer 160[3] and the conductive layer 163[7] are electrically connected to each other through the conductive layer 199.

In the signal output circuit 110a, an opening that penetrates the insulating layer 156, the insulating layer 157, and the insulating layer 158 is provided over each of the conductive layer 155[1], the conductive layer 155[2], the conductive layer 155[3], the conductive layer 155[4], the conductive layer 155[8], the conductive layer 155[9], the conductive layer 155[10], and the conductive layer 155[11].

Through the opening provided over the conductive layer 155[1], the conductive layer 160[3] and the conductive layer 155[1] are electrically connected to each other. Through the opening provided over the conductive layer 155[2], the conductive layer 160[1] and the conductive layer 155[2] are electrically connected to each other. Through the opening provided over the conductive layer 155[3], the conductive layer 160[4] and the conductive layer 155[3] are electrically connected to each other.

Through the opening provided over the conductive layer 155[8], the conductive layer 181[1] and the conductive layer 155[8] are electrically connected to each other. Through the opening provided over the conductive layer 155[10], the conductive layer 181[3] and the conductive layer 155[10] are electrically connected to each other.

Two openings are provided over the conductive layer 155[9]. Through one of the two openings, the conductive layer 160[8] and the conductive layer 155[9] are electrically connected to each other. Through the other of the two openings, the conductive layer 181[2] and the conductive layer 155[9] are electrically connected to each other.

Two openings are provided over the conductive layer 155[11]. Through one of the two openings, the conductive layer 160[10] and the conductive layer 155[11] are electrically connected to each other. Through the other of the two openings, the conductive layer 181[4] and the conductive layer 155[11] are electrically connected to each other.

In the signal output circuit 110a, an opening that penetrates the insulating layer 156, the insulating layer 157, and the insulating layer 158 is provided over each of the conductive layer 155[4] and the conductive layer 155[7].

Through the opening provided over the conductive layer 155[4], the conductive layer 163[2] and the conductive layer 155[4] are electrically connected to each other (see FIG. 20B). Through the opening provided over the conductive layer 155[7], the conductive layer 163[8] and the conductive layer 155[7] are electrically connected to each other (see FIG. 21A and FIG. 21B).

Note that the conductive layer 155[4] functions also as the conductive layer 155[5] and the conductive layer 155[6]. The conductive layer 160[1] functions also as the conductive layer 160[7]. The conductive layer 160[2] functions also as the conductive layer 160[6], the conductive

layer 160[9], and the conductive layer 160[11]. The conductive layer 160[3] functions also as the conductive layer 160[5]. The conductive layer 163[1] functions also as the conductive layer 163[6]. The conductive layer 163[2] functions also as the conductive layer 163[9] and the conductive layer 163[11]. The conductive layer 163[8] functions also as the conductive layer 163[10].

A region where the conductive layer 155[4] and the conductive layer 160[6] overlap with each other with the insulating layer 156, the insulating layer 157, and the insulating layer 158 therebetween functions as the capacitor 20[1].

The electrical connection between the conductive layer 160[8] and the conductive layer 155[9] enables the capacitor C1 of the transistor 10[8] to be used as the capacitor 20[2]. With the use of the capacitor C1 of the transistor 10[8] as the capacitor 20[2], the capacitor 20[2] does not need to be additionally provided, so that a semiconductor device occupying a smaller area can be obtained (see FIG. 17). Thus, the VFET of one embodiment of the present invention is preferably used as the transistor 10[8].

The electrical connection between the conductive layer 160[10] and the conductive layer 155[11] enables the capacitor C1 of the transistor 10[10] to be used as the capacitor 20[3]. With the use of the capacitor C1 of the transistor 10[10] as the capacitor 20[3], the capacitor 20[3] does not need to be additionally provided, so that a semiconductor device occupying a smaller area can be obtained (see FIG. 17 and FIG. 20A). Thus, the VFET of one embodiment of the present invention is preferably used as the transistor 10[10].

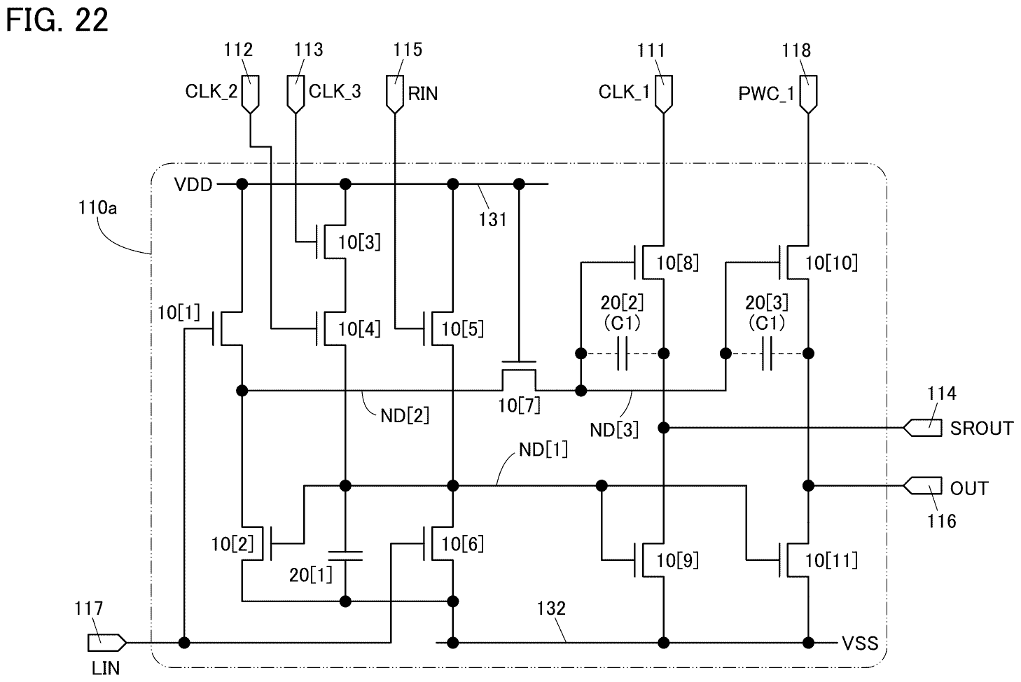

FIG. 22 illustrates a circuit diagram of the signal output circuit 110a of the case where the capacitor C1 of the transistor 10[8] is used as the capacitor 20[2] and the capacitor C1 of the transistor 10[10] is used as the capacitor 20[3].

Transistors other than the VFET may be used as the transistor 10[10] and a transistor other than the transistor 10[10]. However, a large number of the transistors of one embodiment of the present invention are preferably used for the signal output circuit 110a in order to obtain a semiconductor device occupying a small area. Therefore, all the transistors included in the signal output circuit 110a are preferably the transistors of one embodiment of the present invention.

### [Example of Operation of Signal Output Circuit]

Next, an example of operation of the signal output circuit 110 will be described with reference to drawings. In this embodiment, an example of operation of the signal output circuit 110a illustrated in FIG. 2 among the signal output circuits 110 will be described.

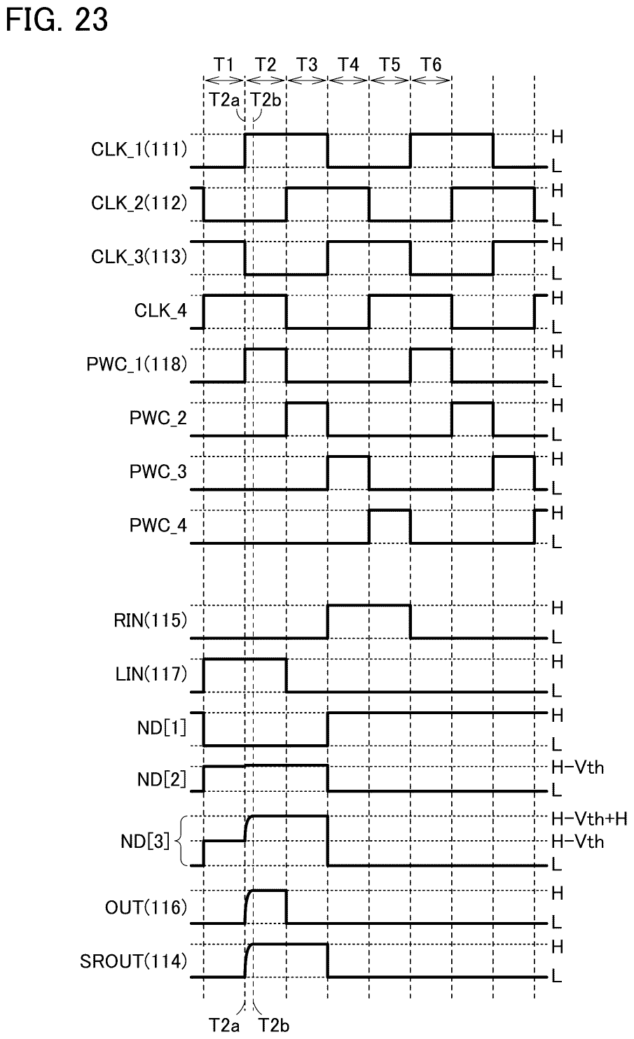

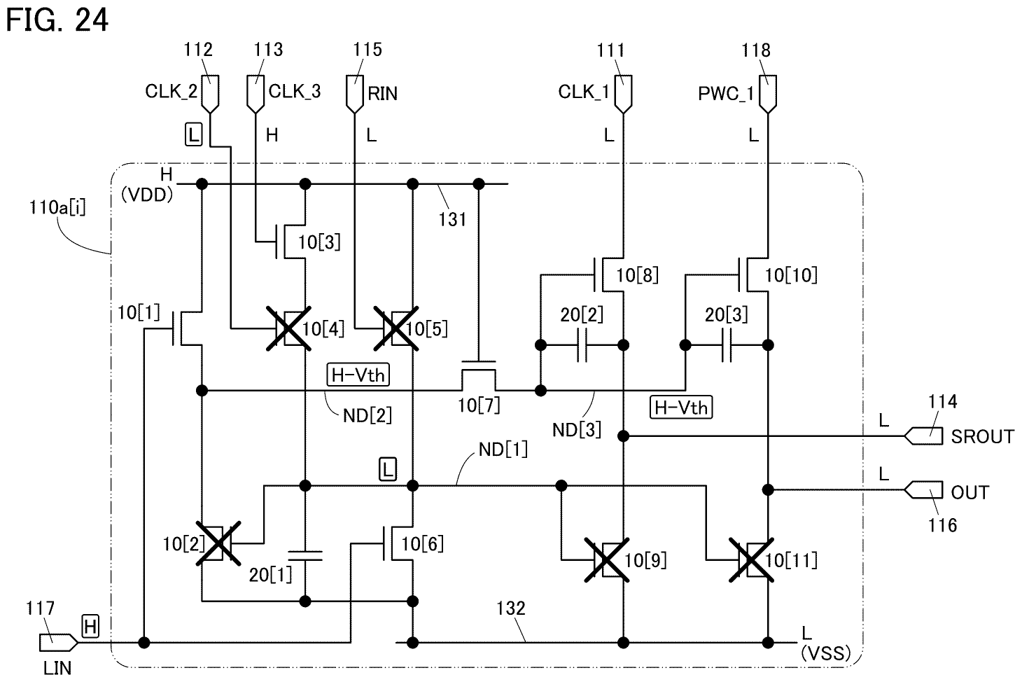

FIG. 23 is a timing chart for explaining an example of operation of a signal output circuit 110a [i]. FIG. 24 to FIG. 30 are circuit diagrams for explaining the example of operation of the signal output circuit 110a [i].

In the drawings and the like, for showing the potential of a wiring or the like, “H” representing a potential H or “L” representing a potential L is sometimes written near the wiring or the like. In addition, enclosed “H” or “L” is sometimes written near an electrode or the like whose potential changes. Moreover, in the case where a transistor is in an off state, a symbol “x” is sometimes written on the transistor.

The potential H (VDD) is supplied to the wiring 131, and the potential L (VSS) is supplied to the wiring 132. The signal CLK_1 is supplied to the terminal 111, the signal CLK_2 is supplied to the terminal 112, the signal CLK_3 is supplied to the terminal 113, and the signal PWC_1 is supplied to the terminal 118.

In a state shortly before a period T1, the signal CLK_1 is set to a potential L; the signal CLK_2, a potential H; the signal CLK_3, a potential H; the signal PWC_1, a potential L; and the signal LIN, a potential L. The transistor 10[2], the transistor 10[3], the transistor 10[4], the transistor 10[9], and the transistor 10[11] are in an on state. The transistor 10[1], the transistor 10[5], the transistor 10[6], the transistor 10[7], the transistor 10[8], and the transistor 10[10] are in an off state.

The signal CLK_4 and the signal PWC_2 to the signal PWC_4 are each set to a potential L. Note that the signal CLK_4 and the signal PWC_2 to the signal PWC_4 are not related to the operation of the signal output circuit 110a [i] explained here and are thus not used in the explanation of operation of the signal output circuit 110a [i].

In the period T1, the signal CLK_2 becomes a potential L and the signal LIN becomes a potential H (see FIG. 23 and FIG. 24). Then, the transistor 10[1] and the transistor 10[6] are turned on. Then, the potential of the node ND[1] becomes the potential L, and the transistor 10[2], the transistor 10[9], and the transistor 10[11] are turned off.

The potentials of the node ND[2] and the node ND[3] each become a potential lower than the potential H by Vth of the transistor 10[1] (the potential H−Vth). Here, the value of the potential H−Vth is higher than or equal to Vth of the transistor. Thus, the transistor 10[8] and the transistor 10[10] are turned on. The potential L is output as the signal OUT from the terminal 116, and the potential L is output as the signal SROUT from the terminal 114.

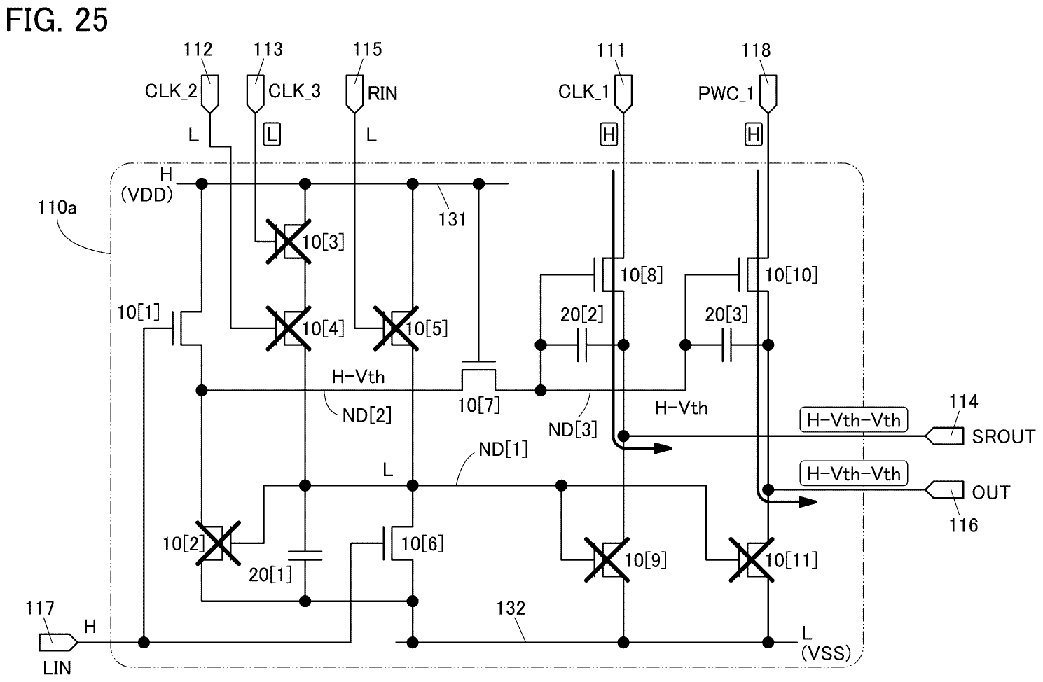

In a period T2, the signal CLK_1 becomes a potential H, the signal CLK_3 becomes a potential L, and the signal PWC_1 becomes a potential H. Then, the transistor 10[3] is turned off. At a time T2a (see FIG. 23 and FIG. 25) at the start of the period T2, the potential of the node ND[3] is the potential H−Vth; thus, the potential of the terminal 114 becomes the potential H-Vth-Vth and the potential of the terminal 116 becomes the potential H−Vth-Vth.

Meanwhile, the terminal 114 and the node ND[3] are connected (capacitively coupled) to each other through the capacitor 20[2]. The terminal 116 and the node ND[3] are connected to each other through the capacitor 20[3]. The capacitor 20[2] and the capacitor 20[3] function as bootstrap capacitors. Thus, the potential of the node ND[3] increases with increasing potentials of the terminal 114 and the terminal 116.

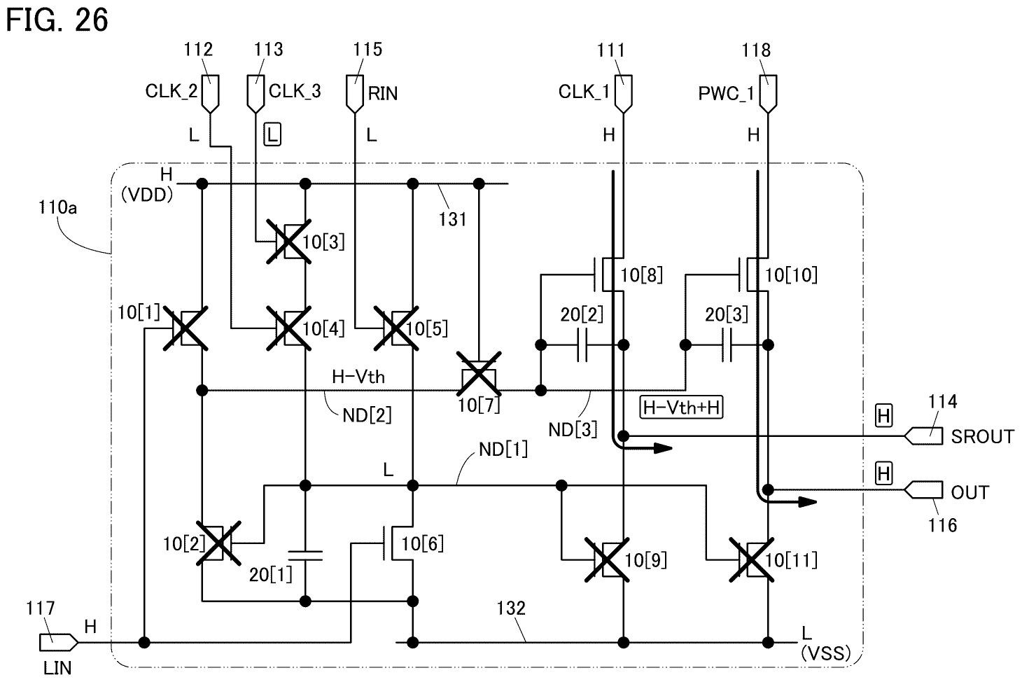

At this time, the potential of the node ND[2] also increases. At the moment when the potential of the node ND[2] exceeds the potential H−Vth, the transistor 10[1] and the transistor 10[7] are turned off, and the node ND[2] and the node ND[3] are brought into a floating state. The potential of the node ND[3] increases to the potential H−Vth+the potential H (2× the potential H−Vth) (at a time T2b, see FIG. 23 and FIG. 26). Since this potential is higher than the potential H+Vth, the potentials of the terminal 114 and the terminal 116 can each be set to the potential H.

Here, in the case where the signal output circuit 110a does not include the transistor 10[7], a voltage of 2×the potential H−Vth-Vss is applied to the drain of the transistor 10[2]. Since Vss is applied to the source of the transistor 10[2], an excessive voltage (2×the potential H−Vth−Vss) is applied between the source and the drain of the transistor 10[2]. As a result, degradation of the characteristics of the transistor 10[2] or damage thereto is likely to occur.

With the transistor 10[7] provided between the drain of the transistor 10[2] and the node ND[3], the potential of the node ND[2] (the drain of the transistor 10[2]) does not increase even when the potential of the node ND[3] becomes 2×the potential H−Vth; thus, degradation of the characteristics of the transistor 10[2] and damage thereto can be prevented.

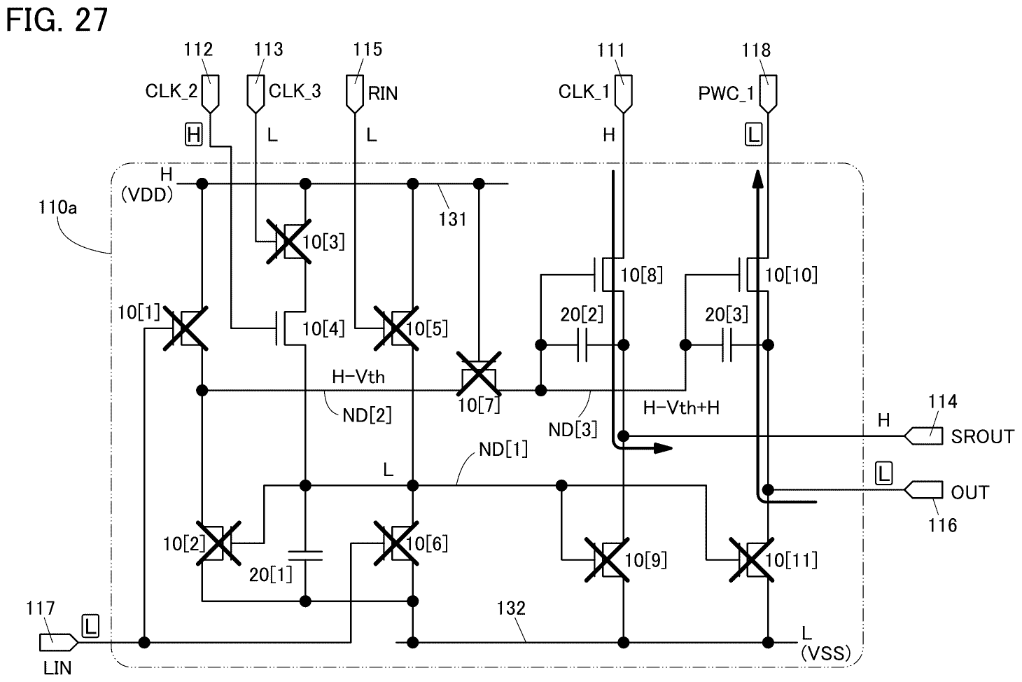

In a period T3, the signal CLK_2 becomes the potential H, the signal PWC_1 becomes the potential L, and the signal LIN becomes the potential L (see FIG. 23 and FIG. 27). Then, the transistor 10[4] is turned on. The potential of the terminal 116 becomes the potential L. The transistor 10[6] is turned off, and the node ND[1] and the node ND[2] are brought into a floating state.

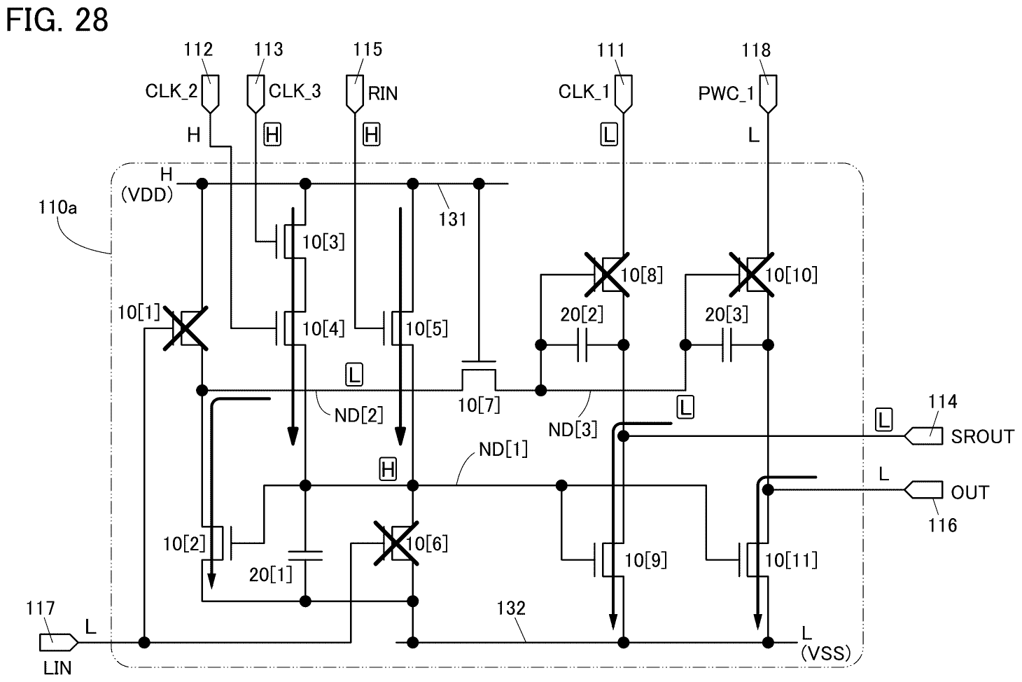

In a period T4, the signal CLK_1 becomes the potential L, the signal CLK_3 becomes the potential H, and the signal RIN becomes a potential H (see FIG. 23 and FIG. 28). Then, the transistor 10[3] and the transistor 10[5] are turned on, and the potential of the node ND[1] becomes the potential H. When the potential of the node ND[1] becomes the potential H, the transistor 10[2], the transistor 10[9], and the transistor 10[11] are turned on.

When the transistor 10[2] is turned on, the potential of the node ND[2] becomes the potential L. Then, the transistor 10[7] is turned on, and the potential of the node ND[3] also becomes the potential L. Thus, the transistor 10[8] and the transistor 10[10] are turned off. When the transistor 10[9] and the transistor 10[11] are turned on, the potential L is supplied to the terminal 114 and the potential of the terminal 116 (the potential L) is maintained.

As illustrated in FIG. 18, FIG. 21A, and FIG. 21B, the conductive layer 163[8] and the conductive layer 155[7] are electrically connected to each other in the signal output circuit 110a of one embodiment of the present invention. The conductive layer 163[8] functions as the gate electrodes of the transistor 10[8] and the transistor 10[10]. The conductive layer 155[7] functions as the drain electrode (or the source electrode) of the transistor 10[7]. The conductive layer 155[7] functions as the node ND[3]. The conductive layer 160[1] functions as the source electrode (or the drain electrode) of the transistor 10[7]. The conductive layer 160[1] functions as the node ND[2].

As described later in an example, in the case where the conductive layer 155[7] is used as the drain (the drain electrode), the on-state current of the transistor 10[7] can be increased as compared with the case where the conductive layer 155[7] is used as the source (the source electrode).

When one or both of the capacitor 20[2] and the capacitor 20[3] is/are connected to the node ND[3], the charge time and the discharge time required for changing the potential of the node ND[3] become long. The charge time and the discharge time required for changing the potential of the node ND[3] are shortened when the on-state current of the transistor 10[7] is increased.

Since the conductive layer 163[8] and the conductive layer 155[7] are electrically connected to each other, the conductive layer 155[7] functions as the drain and the conductive layer 160[1] functions as the source in the period T3. Thus, when the transistor 10[7] is turned on in the period T4, the potential of the node ND[3] can be rapidly set to the potential L. Thus, the operation speed of the signal output circuit 110a can be increased. In addition, the operation speed of a semiconductor device using the signal output circuit 110a can be increased.

When the potential of the node ND[3] is not surely set to the potential L in and after the period T4, a shoot-through current sometimes flows between the terminal 118 and the wiring 132. Similarly, a shoot-through current sometimes flows between the terminal 111 and the wiring 132. With the conductive layer 163[8] and the conductive layer 155[7] electrically connected to each other, the potential of the node ND[3] can be surely set to the potential L in the period T4. Thus, the power consumption of the signal output circuit 110a can be reduced. In addition, the power consumption of the semiconductor device using the signal output circuit 110a can be reduced.

When the conductive layer 163[8] and the conductive layer 160[1] (the conductive layer 160[7]) are electrically connected to each other, the conductive layer 155[7] functions as the source and the conductive layer 160[1] functions as the drain in the period shortly before the period T1. Thus, the time required for the potential change of the node ND[3] can be shortened in the period T1. That is, the potential of the node ND[3] can be rapidly set to the potential H-Vth. Thus, the operation speed of the signal output circuit 110a can be increased. In addition, the operation speed of the semiconductor device using the signal output circuit 110a can be increased.

Meanwhile, the effect of reducing power consumption is less likely to be obtained in the case where the conductive layer 155[7] functions as the source of the transistor 10[7] and the conductive layer 160[1] functions as the drain of the transistor 10[7]. Thus, it is preferable that the conductive layer 155[7] function as the drain of the transistor 10[7] and the conductive layer 160[1] function as the source of the transistor 10[7]. It is preferable that the conductive layer 163[8] and the conductive layer 155[7] be electrically connected to each other.

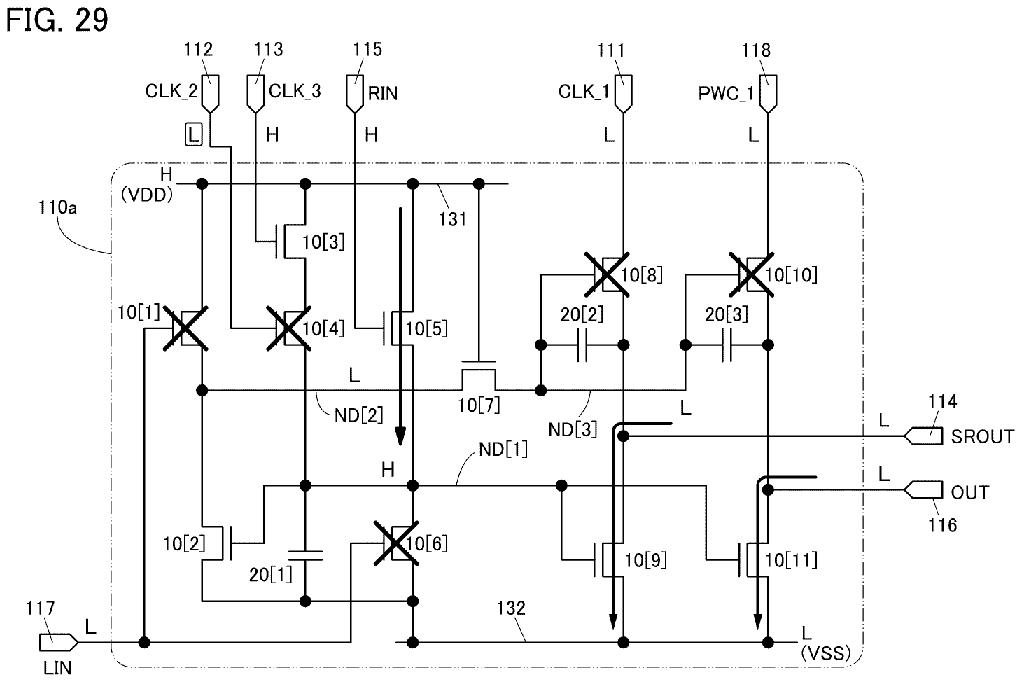

In a period T5, the signal CLK_2 becomes the potential L (see FIG. 23 and FIG. 29). Then, the transistor 10[4] is turned off.

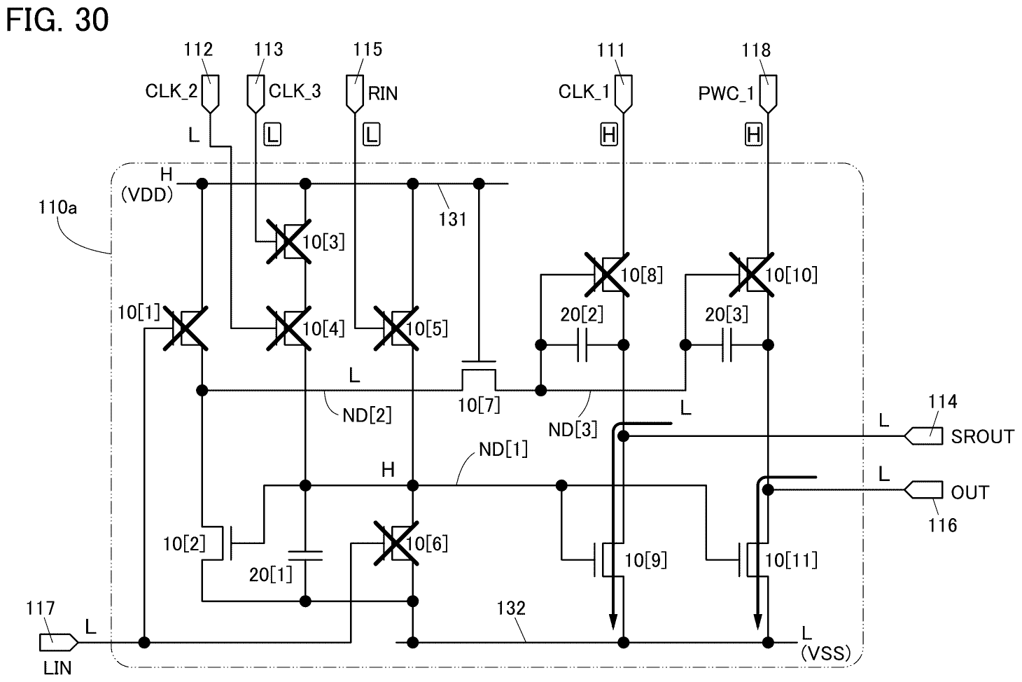

In a period T6, the signal CLK_3 and the signal RIN each become the potential L (see FIG. 23 and FIG. 30). Then, the transistor 10[3] and the transistor 10[5] are turned off. When the transistor 10[5] is turned off, the node ND[1] is brought into a floating state.

After that, the potential L is supplied to each of the terminal 114 and the terminal 116 until the potential H is supplied as the signal LIN to the terminal 117. That is, the potential L is output as each of the signal OUT and the signal SROUT until the potential H is supplied as the signal LIN to the terminal 117.

In this manner, the signal output circuit[i] can output pulse signals from the terminal 114 and the terminal 116 in synchronization with a combination of specific signals. Note that the pulse width (the time during which the potential H is output) of the signal SROUT, which is a pulse signal output from the terminal 114, changes with the signals CLK. The pulse width (the time during which the potential H is output) of the signal OUT, which is a pulse signal output from the terminal 116, changes with the signals PWC.

The signal output circuit[i] of one embodiment of the present invention includes the capacitor elements functioning as bootstrap capacitors and thus can surely output a power supply potential (the potential H) from each of the terminal 114 and the terminal 116. Thus, the signal output circuit[i] of one embodiment of the present invention has a low output impedance and can surely supply the potential H to a load such as a circuit connected to the terminal 114 or the terminal 116. Thus, the operation of the semiconductor device including the signal output circuit [i] of one embodiment of the present invention can be stabilized, and the reliability of the semiconductor device can be improved.

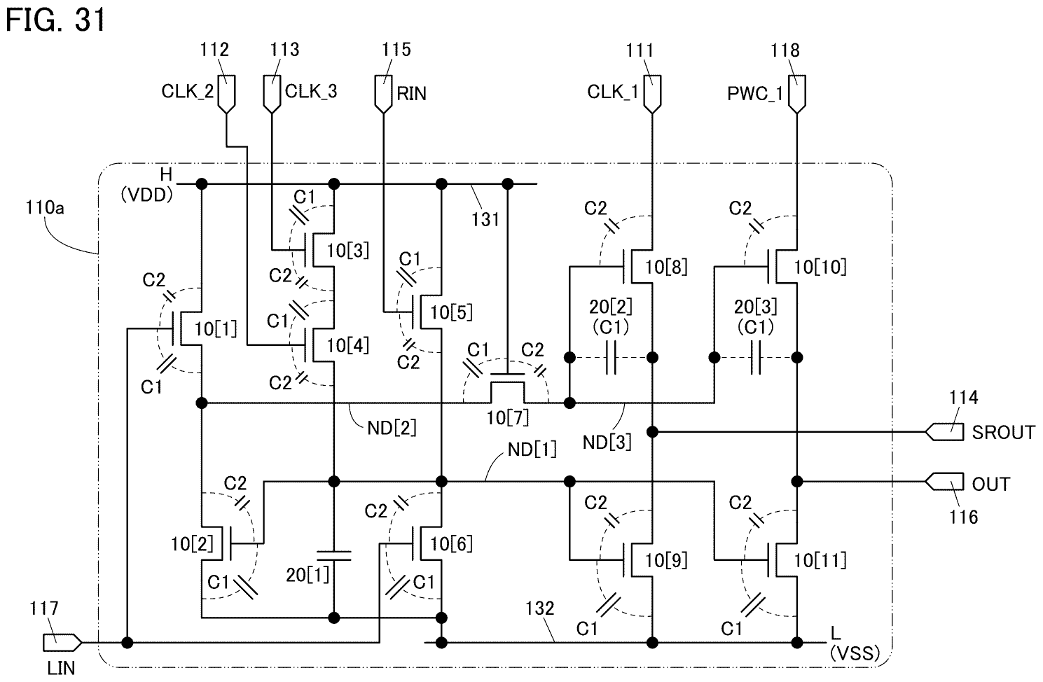

The capacitor C1 of the transistor 10[1] is preferably formed between the node ND[1] and the gate of the transistor 10[1]. The capacitor C2 of the transistor 10[1] is preferably formed between the wiring 131 to which the power supply potential is supplied and the gate of the transistor 10[1] (see FIG. 31).

The node ND[1] is in a floating state in a period other than a period in which each of the signal CLK_2 and the signal CLK_3 is the potential H. In order to inhibit a potential change of the node ND[1] in this period and operate the signal output circuit[i] of one embodiment of the present invention more stably, it is preferable that the capacitor C1 of each of the transistor 10[2], the transistor 10[6], the transistor 10[9], and the transistor 10[11] be formed between the gate and the wiring 132 to which a power supply potential is supplied. Specifically, it is preferable that the conductive layer 160[2] be electrically connected to the wiring 132 (see FIG. 17). The conductive layer 160[2] functions as the source electrode of each of the transistor 10[2], the transistor 10[6], the transistor 10[9], and the transistor 10[11].

When the capacitor C1 of each of the transistor 10[2], the transistor 10[9], and the transistor 10[11] is formed between the gate and the wiring 132, each capacitor C1 is connected in parallel with the capacitor 20[1]. Thus, the effect of inhibiting a potential change of the node ND[1] can be enhanced (see FIG. 31).

In the case where the capacitor C2 of the transistor 10[6] is formed between the node ND[1] and the gate of the transistor 10[6], the influence of a potential change of the signal input to the gate of the transistor 10[6] on the node ND[1] can be reduced as compared with the case where the capacitor C1 is formed between the node ND[1] and the gate of the transistor 10[6].

In order to inhibit a potential change of the node ND[1] and operate the signal output circuit[i] of one embodiment of the present invention more stably, the capacitor C2 of each of the transistor 10[4] and the transistor 10[5] is preferably formed between the gate and the node ND[1]. The capacitor C1 of the transistor 10[5] is preferably formed between the gate and the wiring 131 to which the power supply potential is supplied. Specifically, it is preferable that the conductive layer 160[3] be electrically connected to the wiring 131 (see FIG. 17). The conductive layer 160[3] functions as the drain electrode of the transistor 10[5].

The capacitor C1 of the transistor 10[4] is preferably formed between the drain and the gate of the transistor 10[4]. The capacitor C1 of the transistor 10[3] is preferably formed between the wiring 131 and the gate of the transistor 10[3]. Specifically, it is preferable that the conductive layer 160[3] be electrically connected to the wiring 131 (see FIG. 17). The conductive layer 160[3] functions as the drain electrode of the transistor 10[3]. The capacitor C2 of the transistor 10[3] is preferably formed between the source and the gate of the transistor 10[3].

In order to operate the signal output circuit[i] of one embodiment of the present invention more stably, the capacitance value of parasitic capacitance generated between the node ND[3] and the gate of the transistor 10[7] is preferably smaller than the capacitance value of each of the capacitor 20[2] and the capacitor 20[3]. Thus, in the transistor 10[7], the capacitor C1 is preferably generated between the gate and one of the source and the drain of the transistor 10[7], and the capacitor C2 is preferably generated between the gate and the other of the source and the drain of the transistor 10[7] (see FIG. 31).

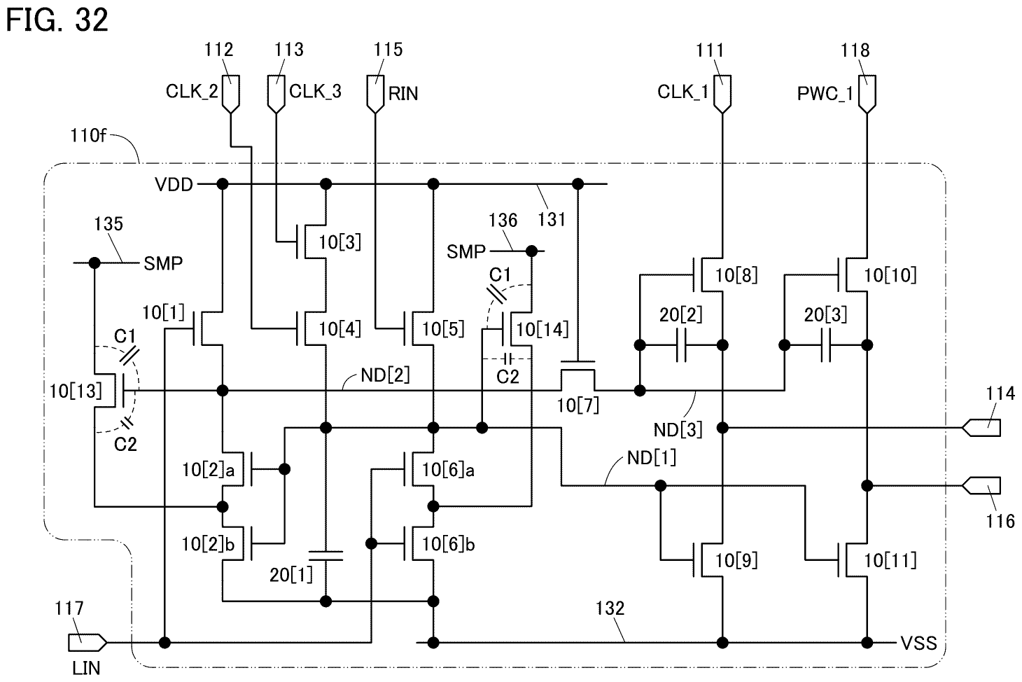

The signal output circuit 110f illustrated in FIG. 10 includes the transistor 10[13] and the transistor 10[14]. The capacitor C1 of the transistor 10[13] is preferably formed between the wiring 135 and the gate of the transistor 10[13] (see FIG. 32). In other words, the capacitor C1 of the transistor 10[13] is preferably formed between the drain and the gate of the transistor 10[13]. Thus, the capacitor C2 of the transistor 10[13] is preferably formed between the source and the gate of the transistor 10[13].

The potential SMP supplied to the wiring 135 is set to a fixed potential, and the gate of the transistor 10[13] is electrically connected to the node ND[2]. When the capacitor C1 is formed between the wiring 135 and the gate of the transistor 10[13], the effect of inhibiting a potential change of the node ND[2] when the node ND[2] is brought into a floating state can be enhanced.

The capacitor C1 of the transistor 10[14] is preferably formed between the wiring 136 and the gate of the transistor 10[14]. That is, the capacitor C1 of the transistor 10[14] is preferably formed between the drain and the gate of the transistor 10[14] (see FIG. 32). Thus, the capacitor C2 of the transistor 10[14] is preferably formed between the source and the gate of the transistor 10[14].

The potential SMP supplied to the wiring 136 is set to a fixed potential, and the gate of the transistor 10[14] is electrically connected to the node ND[1]. When the capacitor C1 is formed between the wiring 136 and the gate of the transistor 10[14], the effect of inhibiting a potential change of the node ND[1] when the node ND[1] is brought into a floating state can be enhanced.

### Example of Operation of Shift Register 100

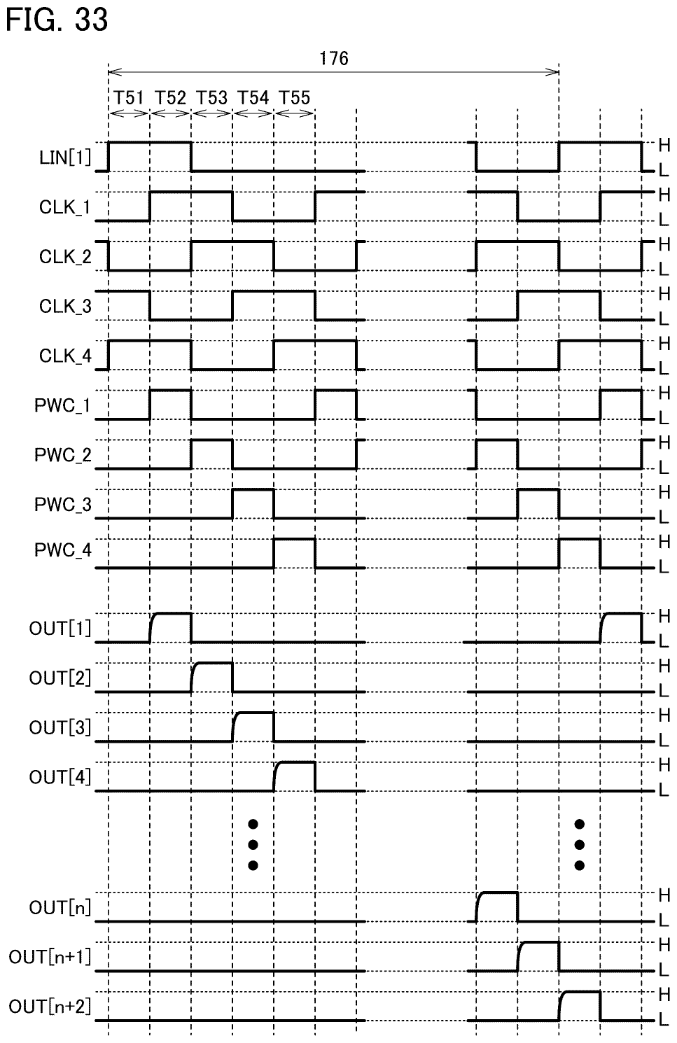

Next, an example of operation of the shift register 100 illustrated in FIG. 1A will be described with reference to FIG. 33. FIG. 33 is a timing chart for explaining the example of operation of the shift register 100. FIG. 33 shows potential changes of the signal CLK_1 to the signal CLK_4, which are clock signals; the signal PWC_1 to the signal PWC_4, which determine the pulse width of the signal OUT; the signal LIN[1], which is input to the signal output circuit 110[1]; the signal OUT[1] to the signal OUT[4], which are output from the signal output circuit 110[1] to the signal output circuit 110[4]; the signal OUT[n], which is output from the signal output circuit 110[n]; the signal OUT[n+1], which is output from the signal output circuit 110[n+1]; and the signal OUT[n+2], which is output from the signal output circuit 110[n+2].

First, in a period T51, the signal LIN[1] of a potential H is supplied to the signal output circuit 110[1]. In a period T52, a potential H is output as the signal OUT[1] in synchronization with the signal LIN[1], the signal CLK_1, the signal CLK_4, and the signal PWC_1.

Next, in a period T53, a potential L is output as the signal OUT[1]. A potential H is output as the signal OUT[2] in synchronization with the signal CLK_1, the signal CLK_2, and the signal PWC_2.

Next, in a period T54, a potential L is output as the signal OUT[2]. A potential H is output as the signal OUT[3] in synchronization with the signal CLK_3, the signal CLK_4, and the signal PWC_3.

Next, in a period T55, a potential L is output as the signal OUT[3]. A potential H is output as the signal OUT[4] in synchronization with the signal CLK_3, the signal CLK_4, and the signal PWC_4. In this manner, the potential His output as the signal OUT sequentially from the first stage to the n+2-th stage.

After that, the potential H is supplied again as the signal LIN[1] to the signal output circuit 110[1], so that the shift register 100 can perform the above operation repeatedly. Note that a period from the input of the potential H as the signal LIN[1] to the signal output circuit 110[1] to the input of the potential H again as the signal LIN[1] is sometimes referred to as a frame period 176. The signal LIN input to the signal output circuit 110[1] is sometimes referred to as a “start pulse SP”

Note that a transistor having a structure other than the VFET, such as a planar or staggered transistor, may be used as a transistor used in a semiconductor device such as the signal output circuit of one embodiment of the present invention. Alternatively, a combination of the VFET and a transistor having a structure other than the VFET may be used.

Note that the signal output circuit 110 used in the shift register 100 is not limited to the structures disclosed in this specification and the like. A variety of circuit structures can be used for the signal output circuit 110 used in the shift register 100.

The structure described in this embodiment can be used in an appropriate combination with the structures described in the other embodiments.

### Embodiment 2

Described in this embodiment is a metal oxide (hereinafter also referred to as an oxide semiconductor) that can be used in the OS transistor described in the above embodiment.

The metal oxide used in the OS transistor preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

In particular, M is preferably one or more kinds selected from gallium, aluminum, yttrium, antimony, and tin, and M is further preferably gallium.

The metal oxide can be formed by a sputtering method, a CVD method such as a metal organic chemical vapor deposition (MOCVD) method, an ALD method, or the like.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. An ALD method includes a thermal ALD method, which is a deposition method using heat, and a plasma ALD (PEALD:Plasma Enhanced ALD) method, which is a deposition method using plasma. The use of plasma is sometimes preferable because deposition at a lower temperature is possible. Note that a precursor used in an ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or secondary ion mass spectrometry (SIMS).

Unlike a deposition method in which particles ejected from a target or the like are deposited, an ALD method is a deposition method in which a film is formed by reaction at a surface of an object. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (polycrystal) structures can be given as examples of crystal structures of an oxide semiconductor.

Note that the crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of an In—Ga—Zn oxide film having a crystal structure has a bilaterally asymmetrical shape. The bilaterally asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

The crystal structure of a film or a substrate can be evaluated with a diffraction pattern observed by a nanobeam electron diffraction (NBED) method (such a pattern is also referred to as a nanobeam electron diffraction pattern). For example, a halo pattern is observed in the diffraction pattern of a quartz glass substrate, which indicates that quartz glass is in an amorphous state. Furthermore, not a halo pattern but a spot-like pattern is observed in the diffraction pattern of an In—Ga—Zn oxide film deposited at room temperature. This suggests that the In—Ga—Zn oxide deposited at room temperature is in an intermediate state, which is neither a single crystal nor polycrystal nor an amorphous state, and it cannot be concluded that the In—Ga—Zn oxide is in an amorphous state.

### [Structure of Oxide Semiconductor]

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Note that indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear grain boundary cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, and/or the like, the CAAC-OS can also be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### [Composition of Oxide Semiconductor]

Next, the above-described CAC-OS is described in detail. Note that the CAC-OS relates to the material composition.

[CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratio of In, Ga, and Zn to the metal elements contained in the CAC-OS in an In—Ga—Zn oxide are denoted by[In],[Ga], and[Zn], respectively. For example, the first region in the CAC-OS in the In—Ga—Zn oxide is a region having[In] higher than[In] in the composition of the CAC-OS film. Moreover, the second region is a region having[Ga] higher than[Ga] in the composition of the CAC-OS film. Alternatively, for example, the first region is a region having[In] higher than[In] in the second region and[Ga] lower than[Ga] in the second region. Moreover, the second region is a region having[Ga] higher than[Ga] in the first region and[In] lower than[In] in the first region.

Specifically, the first region is a region containing indium oxide, indium zinc oxide, or the like as its main component. The second region is a region containing gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated intentionally, for example. In addition, in the case of forming the CAC-OS by a sputtering method, one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide can be found to have a structure in which the region containing In as its main component (the first region) and the region containing Ga as its main component (the second region) are unevenly distributed and mixed.

Here, the first region is a region having a higher conductivity than the second region. That is, when carriers flow through the first region, the conductivity of a metal oxide is exhibited. Accordingly, when the first regions are distributed in a metal oxide like a cloud, high field-effect mobility (u) can be achieved.

On the other hand, the second region is a region having a higher insulating property than the first region. That is, when the second regions are distributed in a metal oxide, leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (u), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

<Transistor including oxide semiconductor>

Next, the case where the above oxide semiconductor is used for a transistor is described.

When the above oxide semiconductor is used for a transistor, a transistor with high field-effect mobility can be obtained. In addition, a transistor with high reliability can be obtained.

It is particularly preferable to use an oxide containing indium (In), gallium (Ga), and zinc (Zn) (also referred to as “IGZO”) for a semiconductor layer where a channel is formed. Alternatively, an oxide containing indium (In), aluminum (Al), and zinc (Zn) (also referred to as “IAZO”) may be used for the semiconductor layer. Alternatively, an oxide containing indium (In), aluminum (Al), gallium (Ga), and zinc (Zn) (“IAGZO”) may be used for the semiconductor layer.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state.

Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, an element other than the main components of the oxide semiconductor. For example, an element with a concentration lower than 0.1 atomic % can be regarded as an impurity.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the carbon concentration in the channel formation region of the oxide semiconductor, which is obtained by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is obtained by SIMS, is set lower than or equal to 1×10¹⁸ atoms/cm³, preferably lower than or equal to 2×10¹⁶ atoms/cm³.

When the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen in the channel formation region of the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the concentration of hydrogen in the channel formation region of the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

When an oxide semiconductor with sufficiently reduced impurities is used for the channel formation region of the transistor, the transistor can have stable electrical characteristics.

### <Microwave Treatment>

Note that the impurity concentration in the oxide semiconductor can be reduced by performing microwave treatment in an oxygen-containing atmosphere after the formation of the oxide semiconductor. The microwave treatment refers to, for example, treatment using an apparatus including a power source that generates high-density plasma with the use of a microwave.

The microwave treatment in an oxygen-containing atmosphere can convert an oxygen gas into plasma using a high-frequency wave such as a microwave or RF and activate the oxygen plasma. Oxygen that acts on the oxide semiconductor has any of a variety of forms such as an oxygen atom, an oxygen molecule, an oxygen ion, and an oxygen radical (also referred to as O radical, which is an atom, a molecule, or an ion having an unpaired electron). Note that the oxygen that acts on the oxide semiconductor has any one or more of the above forms, particularly suitably an oxygen radical.

The aforementioned microwave treatment in an oxygen-containing atmosphere is preferably performed while the substrate is heated, in which case the impurity concentration in the oxide semiconductor can be further reduced. The substrate heating temperature is higher than or equal to 100° C. and lower than or equal to 650° C., preferably higher than or equal to 200° C. and lower than or equal to 600° C., and further preferably higher than or equal to 300° C. and lower than or equal to 450° C.

When the microwave treatment in an oxygen-containing atmosphere is performed while the substrate is heated, the carbon concentration in the oxide semiconductor, which is obtained by SIMS, can be lower than or equal to 1×10²⁰ atoms/cm³, preferably lower than or equal to 1×10¹⁹ atoms/cm³, further preferably lower than or equal to 1×10¹⁸ atoms/cm³.

Although the microwave treatment in an oxygen-containing atmosphere is performed on the oxide semiconductor in the above-described example, one embodiment of the present invention is not limited thereto. For example, the microwave treatment in an oxygen-containing atmosphere may be performed on an insulating layer, specifically a silicon oxide layer, which is positioned in the vicinity of the oxide semiconductor. When the silicon oxide layer is subjected to microwave treatment in an oxygen-containing atmosphere, hydrogen contained in the silicon oxide layer can be released as H₂O to the outside. Release of hydrogen from the silicon oxide layer positioned in the vicinity of the oxide semiconductor can improve the reliability of a transistor using the oxide semiconductor as its semiconductor layer. Therefore, a semiconductor device with high reliability can be provided.

In addition, the microwave treatment sometimes promotes crystallization of the oxide semiconductor. That is, the microwave treatment on the oxide semiconductor or the insulating layer positioned in the vicinity of the oxide semiconductor can improve the crystallinity of the oxide semiconductor.

The structure described in this embodiment can be used in an appropriate combination with the structures described in the other embodiments.

### Embodiment 3

In this embodiment, a structural example of a display device 200 in which the transistor 10, the shift register 100, the signal output circuit 110, and the like of one embodiment of the present invention can be used will be described.

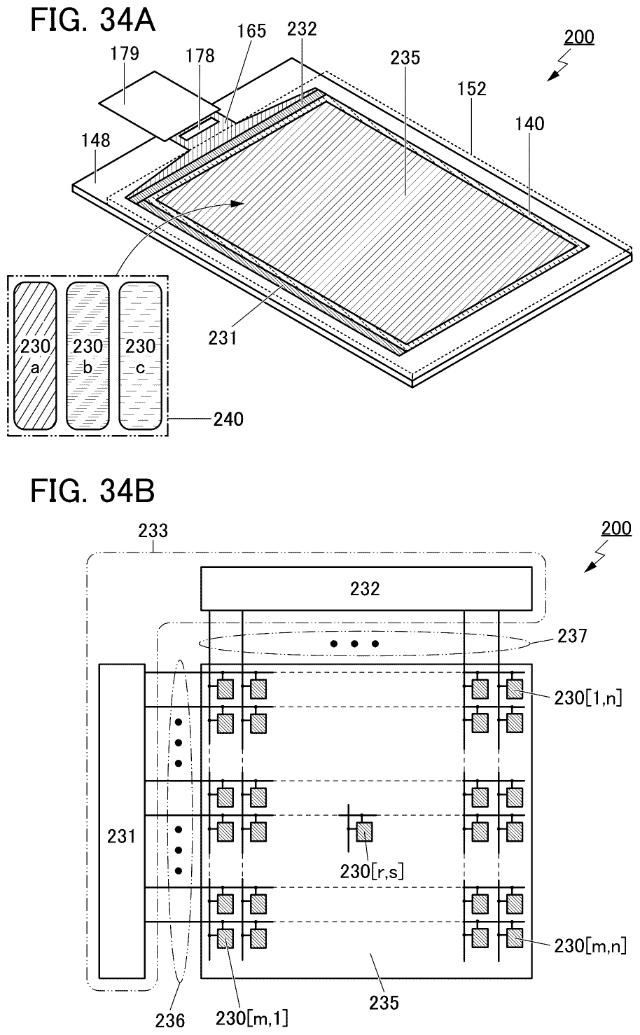

FIG. 34A illustrates a perspective view of the display device 200. The display device 200 has a structure in which the substrate 152 and the substrate 148 are bonded to each other. In FIG. 34A, the substrate 152 is denoted by a dashed line.

The display device 200 includes a display portion 235, a connection portion 140, a first driver circuit portion 231, a second driver circuit portion 232, a wiring 165, and the like. FIG. 34A illustrates an example in which an IC 178 and an FPC 179 are mounted on the display device 200. Thus, the structure illustrated in FIG. 34A can also be regarded as a display module including the display device 200, the IC (integrated circuit), and the FPC.

The connection portion 140 is provided outside the display portion 235. The connection portion 140 can be provided along one or more sides of the display portion 235. The number of the connection portions 140 can be one or more. FIG. 34A illustrates an example in which the connection portion 140 is provided to surround the four sides of the display portion. A common electrode of a light-emitting device is electrically connected to a conductive layer in the connection portion 140, so that a potential can be supplied to the common electrode.

The wiring 165 has a function of supplying a signal and electric power to the display portion 235, the first driver circuit portion 231, and the second driver circuit portion 232. The signal and electric power are input to the wiring 165 from the outside through the FPC 179 or input to the wiring 165 from the IC 178.

FIG. 34A illustrates an example where the IC 178 is provided over the substrate 148 by a COG (Chip On Glass) method, a COF (Chip On Film) method, or the like. The IC 178 may include a scan line driver circuit or a signal line driver circuit, for example. Note that the display device 200 and the display module are not necessarily provided with an IC. The IC may be mounted on the FPC by a COF method or the like.

The display portion 235 includes a plurality of pixels 230 arranged in a matrix of m rows (m is an integer greater than or equal to 1) and n columns (n is an integer greater than or equal to 1). The plurality of pixels 230 are classified into, for example, pixels 230a, pixels 230b, and pixels 230c. The pixel 230a, the pixel 230b, and the pixel 230c have a function of emitting light of different colors. For example, the pixel 230a may have a function of emitting red (R) light, the pixel 230b may have a function of emitting green (G) light, and the pixel 230c may have a function of emitting blue (B) light. Alternatively, for example, the pixel 230a may have a function of emitting yellow (Y) light, the pixel 230b may have a function of emitting cyan (C) light, and the pixel 230c may have a function of emitting magenta (M) light.

One pixel 230a, one pixel 230b, and one pixel 230c form one pixel 240, which achieves full-color display. Thus, the pixel 230 functions as a subpixel. The display device 200 illustrated in FIG. 34A shows an example in which the pixels 230 each functioning as a subpixel are arranged in a stripe pattern. The number of subpixels for forming one pixel 240 is not limited to three, and may be four or more. For example, four subpixels which emit light of R, G, B, and white (W) may be included. Alternatively, four subpixels which emit light of four colors, R, G, B, and Y may be included.

FIG. 34B is a block diagram illustrating the display device 200. The display device 200 includes the display portion 235, the first driver circuit portion 231, and the second driver circuit portion 232. In FIG. 34B, the pixel 230 in the first row and the n-th column is denoted as a pixel 230[1,n], the pixel 230 in the m-th row and the first column is denoted as a pixel 230[m,1], and the pixel 230 in the m-th row and the n-th column is denoted as a pixel 230[m,n]. A given pixel 230 included in the display portion 235 is denoted as a pixel 230[r,s] in some cases. Note that r is an integer greater than or equal to 1 and less than or equal to m, and s is an integer greater than or equal to 1 and less than or equal to n.

A circuit included in the first driver circuit portion 231 functions as, for example, a scan line driver circuit. A circuit included in the second driver circuit portion 232 functions as, for example, a signal line driver circuit. Note that some sort of circuit may be provided at a position facing the first driver circuit portion 231 with the display portion 235 positioned therebetween. Some sort of circuit may be provided at a position facing the second driver circuit portion 232 with the display portion 235 positioned therebetween. Note that circuits included in the first driver circuit portion 231 and the second driver circuit portion 232 are collectively referred to as a peripheral driver circuit 233.

The first driver circuit portion 231 functioning as a scan line driver circuit has a function of selecting the pixels 230 row by row. A plurality of pixels 230 arranged in the first row to a plurality of pixels 230 arranged in the m-th row are sequentially selected by the first driver circuit portion 231, and an image signal supplied from the second driver circuit portion 232 is written to the selected pixels 230, whereby an image displayed on the display portion 235 can be rewritten.

A period from the selection of the pixels 230 in the first row to the selection of the pixels 230 in the m-th row by the first driver circuit portion 231 is referred to as a “frame period”. Thus, a frame period is required for rewriting an image displayed on the display portion 235 once. The number of times of rewriting images per second is referred to as a “frame frequency”. The frame frequency corresponds to the reciprocal of the frame period. Note that “frame frequency” is sometimes referred to as “driving frequency”.

The frame frequency is preferably high in the case where a moving image is displayed on the display device 200. Specifically, the frame frequency is higher than or equal to 60 Hz, preferably higher than or equal to 120 Hz, further preferably higher than or equal to 240 Hz. Meanwhile, as the frame frequency increases, the power consumption of the display device 200 increases.

Any of various circuits such as a shift register circuit, a level shifter circuit, an inverter circuit, a latch circuit, an analog switch circuit, a multiplexer circuit, a demultiplexer circuit, and a logic circuit can be used as the peripheral driver circuit 233.

In the peripheral driver circuit 233, the transistor 10 or the like of one embodiment of the present invention can be used. In the shift register circuit, the shift register 100, the signal output circuit 110, or the like of one embodiment of the present invention can be used. Note that transistors included in the peripheral driver circuit may be formed through the same process as the transistors included in the pixels 230. The use of the transistor 10 or the like of one embodiment of the present invention in the peripheral driver circuit 233 can reduce the area occupied by the peripheral driver circuit 233.

The display device 200 includes m wirings 236 which are arranged approximately parallel to each other and whose potentials are controlled by the circuit included in the first driver circuit portion 231, and n wirings 237 which are arranged approximately parallel to each other and whose potentials are controlled by the circuit included in the second driver circuit portion 232.

Note that FIG. 34B illustrates an example in which the wirings 236 and the wirings 237 are connected to the pixels 230. Note that the wirings 236 and the wirings 237 are examples, and the wirings connected to the pixels 230 are not limited to the wirings 236 and the wirings 237.

### <Display Element>

The display device 200 can employ various modes or include various display elements. Examples of display elements include an EL (electroluminescence) element (an organic EL element, an inorganic EL element, or an EL element containing organic and inorganic materials), an LED (e.g., a white LED, a red LED, a green LED, or a blue LED), a transistor (a transistor that emits light depending on current), an electron emitter, a liquid crystal element, electronic ink, an electrophoretic element, a grating light valve (GLV), a display element using MEMS (micro electro mechanical systems), a digital micromirror device (DMD), a DMS (digital micro shutter), MIRASOL (registered trademark), an IMOD (interferometric modulation) element, a MEMS shutter display element, an optical-interference-type MEMS display element, an electrowetting element, a piezoelectric ceramic display, a display element using a carbon nanotube, and the like, which are elements including a display medium whose contrast, luminance, reflectance, transmittance, or the like is changed by an electrical or magnetic effect. Alternatively, quantum dots may be used as the display element.

Examples of display devices using EL elements include an EL display. Examples of display devices using electron emitters include a field emission display (FED) and an SED-type flat panel display (SED: Surface-conduction Electron-emitter Display). Examples of display devices using quantum dots include a quantum dot display. Examples of display devices using liquid crystal elements include a liquid crystal display (a transmissive liquid crystal display, a transflective liquid crystal display, a reflective liquid crystal display, a direct-view liquid crystal display, or a projection liquid crystal display). Examples of display devices using electronic ink, Electronic Liquid Powder (registered trademark), or an electrophoretic element include electronic paper. The display device may be a plasma display panel (PDP).

Note that for obtaining a transflective liquid crystal display or a reflective liquid crystal display, some or all of pixel electrodes function as reflective electrodes. For example, some or all of pixel electrodes contain aluminum, silver, or the like. Moreover, in such a case, a memory circuit such as an SRAM can be provided under the reflective electrodes. Thus, the power consumption can be further reduced.

Note that in the case where an LED is used, graphene or graphite may be provided under an electrode or a nitride semiconductor of the LED. Graphene or graphite may be a multilayer film in which a plurality of layers are stacked. Providing graphene or graphite as described above facilitates deposition of a nitride semiconductor, such as an n-type GaN semiconductor layer containing crystals, thereover. Furthermore, a p-type GaN semiconductor layer containing crystals or the like can be provided thereover to form the LED. Note that an AlN layer may be provided between graphene or graphite and the n-type GaN semiconductor layer containing crystals. The GaN semiconductor layer included in the LED may be deposited by MOCVD. Note that when graphene is provided, the GaN semiconductor layer included in the LED can be deposited by a sputtering method.

### <Structural Example of Pixel Circuit>

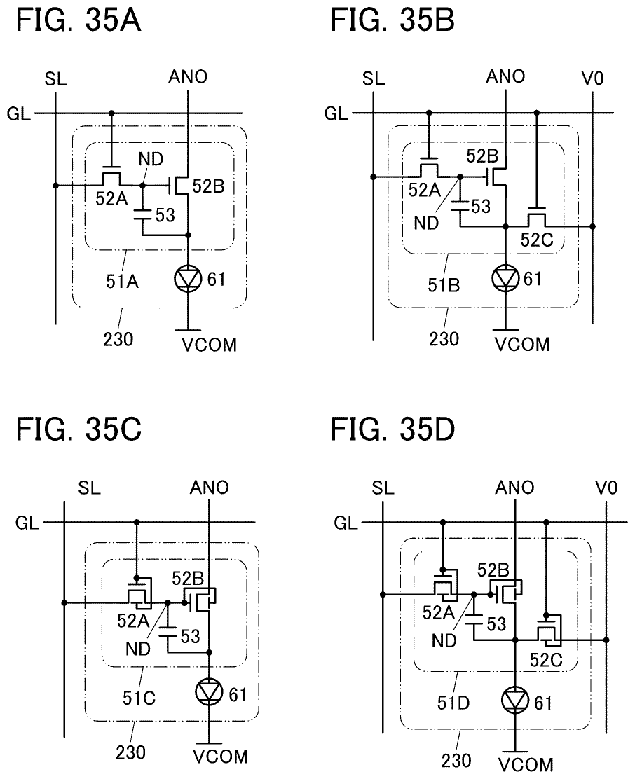

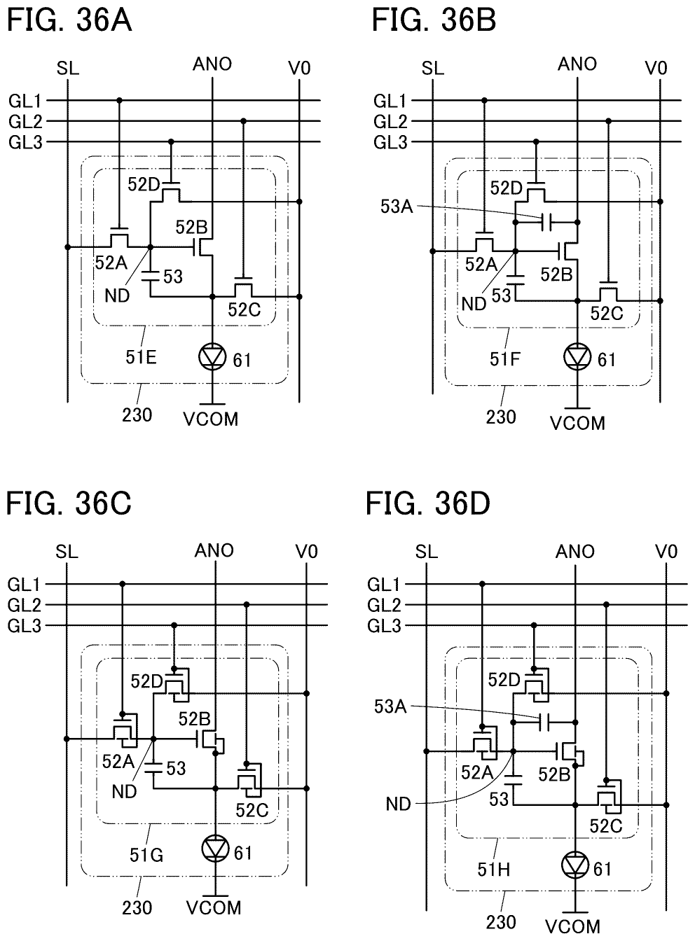

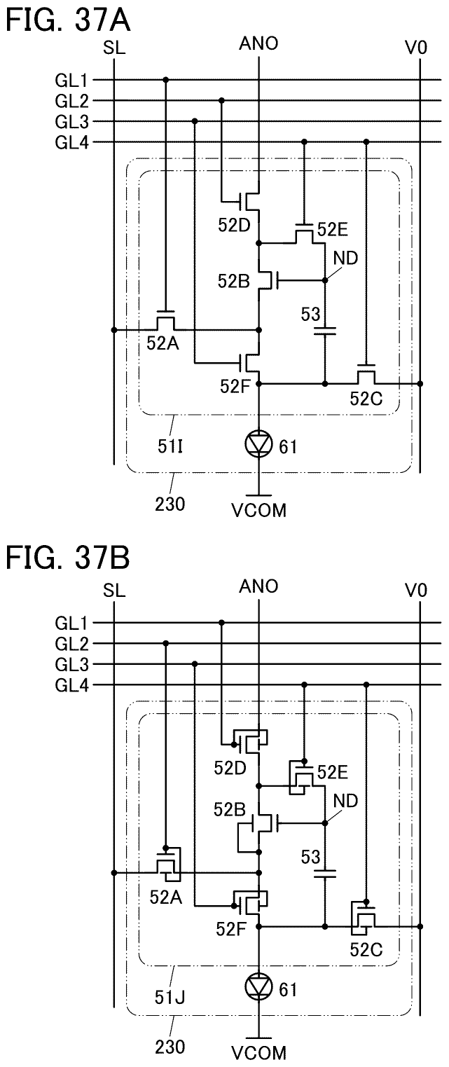

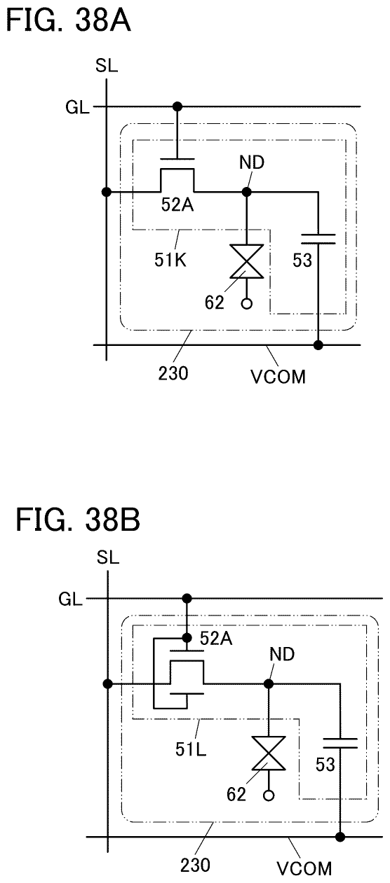

FIG. 35A to FIG. 35D, FIG. 36A to FIG. 36D, FIG. 37A, FIG. 37B, FIG. 38A, and FIG. 38B illustrate structural examples of the pixel 230. The pixel 230 includes a pixel circuit 51 (a pixel circuit 51A, a pixel circuit 51B, a pixel circuit 51C, a pixel circuit 51D, a pixel circuit 51E, a pixel circuit 51F, a pixel circuit 51G, a pixel circuit 51H, a pixel circuit 511, a pixel circuit 51J, a pixel circuit 51K, or a pixel circuit 51L) and a light-emitting element 61.

The light-emitting element (also referred to as a light-emitting device) described in this embodiment and the like refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

The pixel circuit 51A illustrated in FIG. 35A is a 2Tr1C-type pixel circuit including a transistor 52A, a transistor 52B, and a capacitor 53.

One of a source and a drain of the transistor 52A is electrically connected to a wiring SL, and a gate of the transistor 52A is electrically connected to a wiring GL. The one of the source and the drain of the transistor 52A is electrically connected to a gate of the transistor 52B and one terminal of the capacitor 53. One of a source and a drain of the transistor 52B is electrically connected to a wiring ANO. The other of the source and the drain of the transistor 52B is electrically connected to the other terminal of the capacitor 53 and an anode of the light-emitting element 61. A cathode of the light-emitting element 61 is electrically connected to a wiring VCOM. A region where the other of the source and the drain of the transistor 52A, the gate of the transistor 52B, and the one terminal of the capacitor 53 are electrically connected to one another functions as a node ND.

The wiring GL corresponds to the wiring 236, and the wiring SL corresponds to the wiring 237. The wiring VCOM is a wiring for supplying a potential for supplying current to the light-emitting element 61. The transistor 52A has a function of controlling electrical continuity between the wiring SL and the gate of the transistor 52B in accordance with the potential of the wiring GL. For example, VDD is supplied to the wiring ANO, and VSS is supplied to the wiring VCOM.

When the transistor 52A is turned on, an image signal is supplied from the wiring SL to the node ND. After that, when the transistor 52A is turned off, the image signal is held in the node ND. In order to surely hold the image signal supplied to the node ND, a transistor with a low off-state current is preferably used as the transistor 52A. For example, an OS transistor is preferably used as the transistor 52A.

With the use of the OS transistor as the transistor 52A, displaying an image on the display portion 235 can be kept even when the frame frequency is extremely low (e.g., 1 Hz or less). For example, in the case of displaying a still image for which rewriting every frame is not required, displaying an image can be kept even when the operation of the peripheral driver circuit 233 is stopped. Such a driving method in which the operation of the peripheral driver circuit 233 is stopped during displaying a still image is also referred to as “idling stop driving”. The power consumption of a display device can be reduced by performing idling stop driving.

The transistor 52B has a function of controlling the amount of current flowing through the light-emitting element 61. The capacitor 53 has a function of holding a gate potential of the transistor 52B. The intensity of light emitted from the light-emitting element 61 is controlled in accordance with an image signal supplied to the gate of the transistor 52B (the node ND).

The pixel circuit 51B illustrated in FIG. 35B is a 3Tr1C-type pixel circuit including the transistor 52A, the transistor 52B, a transistor 52C, and the capacitor 53. The pixel circuit 51B illustrated in FIG. 35B has a structure in which the transistor 52C is added to the pixel circuit 51A illustrated in FIG. 35A.

One of a source and a drain of the transistor 52C is electrically connected to the other of the source and the drain of the transistor 52B. A gate of the transistor 52C is electrically connected to the wiring GL. The other of the source and the drain of the transistor 52C is electrically connected to a wiring V0. A reference potential is supplied to the wiring V0, for example.

The transistor 52C has a function of controlling electrical continuity between the wiring VO and the other of the source and the drain of the transistor 52B in accordance with the potential of the wiring GL. The wiring V0 is a wiring for supplying a reference potential. In the case where an n-channel transistor is used as the transistor 52B, a variation in the gate-source potential of the transistor 52B can be reduced by the reference potential of the wiring V0 supplied through the transistor 52C.

A current value that can be used for setting of pixel parameters can be obtained using the wiring V0. Specifically, the wiring V0 can function as a monitor line for outputting current flowing through the transistor 52B or current flowing through the light-emitting element 61 to the outside. Current output to the wiring V0 can be converted into voltage by a source follower circuit or the like and can be output to the outside. Alternatively, the current can be converted into a digital signal by an A-D converter or the like and can be output to the outside.

The pixel circuit 51C illustrated in FIG. 35C is an example of the case where a transistor which includes a back gate and in which the back gate is electrically connected to a gate is used as each of the transistor 52A and the transistor 52B in the pixel circuit 51A. The pixel circuit 51D illustrated in FIG. 35D is an example of the case where such transistors are employed in the pixel circuit 51B. Thus, current that can flow through the transistors can be increased. Although a transistor in which a gate and a back gate are electrically connected to each other is used as each of the transistors here, one embodiment of the present invention is not limited thereto. A transistor which includes a gate and a back gate and in which the gates are electrically connected to different wirings may be used. For example, with the use of a transistor in which one of a gate and a back gate is electrically connected to a source, the reliability can be increased.

The pixel circuit 51E illustrated in FIG. 36A has a structure in which a transistor 52D is added to the pixel circuit 51B illustrated in FIG. 35B. The pixel circuit 51E illustrated in FIG. 36A is a 4Tr1C-type pixel circuit including the transistor 52A, the transistor 52B, the transistor 52C, the transistor 52D, and the capacitor 53.

One of a source and a drain of the transistor 52D is electrically connected to the node ND, and the other is electrically connected to the wiring V0.

A wiring GL1, a wiring GL2, and a wiring GL3 are electrically connected to the pixel circuit 51E. The wiring GL1 is electrically connected to the gate of the transistor 52A, the wiring GL2 is electrically connected to the gate of the transistor 52C, and the wiring GL3 is electrically connected to a gate of the transistor 52D. Note that in this embodiment and the like, the wiring GL1, the wiring GL2, and the wiring GL3 are sometimes collectively referred to as the wiring GL. Thus, the wiring GL may be one wiring or a plurality of wirings.

When the transistor 52C and the transistor 52D are turned on at the same time, the source and the gate of the transistor 52B have the same potential, so that the transistor 52B can be turned off. Thus, current flowing to the light-emitting element 61 can be blocked forcibly. Such a pixel circuit is suitable for the case of using a display method in which a display period and a non-lighting period are alternately provided.

The pixel circuit 51F illustrated in FIG. 36B is an example of the case where a capacitor 53A is added to the pixel circuit 51E. The capacitor 53A functions as a storage capacitor. The pixel circuit 51E illustrated in FIG. 36A is a 4Tr1C-type pixel circuit. The pixel circuit 51F illustrated in FIG. 36B is a 4Tr2C-type pixel circuit.

The pixel circuit 51G illustrated in FIG. 36C and the pixel circuit 51H illustrated in FIG. 36D are each an example of the case where a transistor including a back gate is employed in the pixel circuit 51E or the pixel circuit 51F. A transistor in which a gate and a back gate are electrically connected to each other is used as each of the transistor 52A, the transistor 52C, and the transistor 52D, and a transistor in which one of a gate and a back gate is electrically connected to a source is used as the transistor 52B.

The pixel circuit 511 illustrated in FIG. 37A is a 6Tr1C-type pixel circuit including the transistor 52A, the transistor 52B, the transistor 52C, the transistor 52D, a transistor 52E, a transistor 52F, and the capacitor 53.

One of the source and the drain of the transistor 52A is electrically connected to the wiring SL, and the gate of the transistor 52A is electrically connected to the wiring GLI. One of the source and the drain of the transistor 52D is electrically connected to the wiring ANO, and the gate of the transistor 52D is electrically connected to the wiring GL2. The other of the source and the drain of the transistor 52D is electrically connected to one of the source and the drain of the transistor 52B. The other of the source and the drain of the transistor 52B is electrically connected to the other of the source and the drain of the transistor 52A and one of a source and a drain of the transistor 52F. A gate of the transistor 52F is electrically connected to the wiring GL3.

One of a source and a drain of the transistor 52E is electrically connected to the other of the source and the drain of the transistor 52D and the one of the source and the drain of the transistor 52B. The other of the source and the drain of the transistor 52E is electrically connected to the gate of the transistor 52B and one terminal of the capacitor 53. The other terminal of the capacitor 53 is electrically connected to the other of the source and the drain of the transistor 52F, the anode of the light-emitting element 61, and one of the source and the drain of the transistor 52C.

A gate of the transistor 52E and the gate of the transistor 52C are electrically connected to a wiring GL4. The other of the source and the drain of the transistor 52C is electrically connected to the wiring V0. A region where the other of the source and the drain of the transistor 52E, the gate of the transistor 52B, and the one terminal of the capacitor 53 are electrically connected to one another functions as the node ND. In the pixel circuit 511, an OS transistor is preferably used particularly as the transistor 52E.

As illustrated in FIG. 37B, a transistor having a back gate may be used as the transistor included in the pixel circuit 51J. A transistor in which a gate and a back gate are electrically connected to each other is used as each of the transistor 52A, the transistor 52C, the transistor 52D, the transistor 52E, and the transistor 52F, and a transistor in which a back gate is electrically connected to the other of the source and the drain is used as the transistor 52B.

The transistor 10 of one embodiment of the present invention can be used as each of the transistor 52A, the transistor 52C, the transistor 52D, the transistor 52E, and the transistor 52F.

The pixel 230 illustrated in FIG. 38A includes the pixel circuit 51K and a liquid crystal element 62. The pixel circuit 51K includes the transistor 52A and the capacitor 53. In FIG. 38A, one of the source and the drain of the transistor 52A is electrically connected to the wiring SL, and the gate of the transistor 52A is electrically connected to the wiring GL. The other of the source and the drain of the transistor 52A is electrically connected to one terminal of the capacitor 53 and the liquid crystal element 62. The other terminal of the capacitor 53 is electrically connected to the wiring VCOM. A region where the other of the source and the drain of the transistor 52A, the one terminal of the capacitor 53, and the liquid crystal element 62 are electrically connected to one another functions as the node ND. The alignment state of the liquid crystal element 62 is set depending on data written to the node ND.

As a driving method of the display device including the liquid crystal element 62, for example, a TN (Twisted Nematic) mode, an STN (Super Twisted Nematic) mode, a VA mode, an ASM (Axially Symmetric Aligned Micro-cell) mode, an OCB (Optically Compensated Birefringence) mode, an FLC (Ferroelectric Liquid Crystal) mode, an AFLC (AntiFerroelectric Liquid Crystal) mode, an MVA mode, a PVA (Patterned Vertical Alignment) mode, an IPS mode, an FFS mode, a TBA (Transverse Bend Alignment) mode, or the like may be used. Examples of driving methods of the display device include, in addition to the above driving methods, an ECB (Electrically Controlled Birefringence) mode, a PDLC (Polymer Dispersed Liquid Crystal) mode, a PNLC (Polymer Network Liquid Crystal) mode, and a guest-host mode. However, without limitation to the above, a variety of liquid crystal elements and the driving methods thereof can be used.

When the liquid crystal element is used as the display element, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

A liquid crystal exhibiting a blue phase for which an alignment film is not needed may be used. The blue phase is one of liquid crystal phases, which is generated just before a cholesteric phase changes into an isotropic phase while the temperature of a cholesteric liquid crystal is increased. Since the blue phase is only generated within a narrow temperature range, a liquid crystal composition that contains a chiral material at greater than or equal to 5 wt % is used for a liquid crystal layer in order to improve the temperature range. The liquid crystal composition that contains a liquid crystal exhibiting the blue phase and a chiral material has a short response time of 1 msec or less, and has optical isotropy, which makes the alignment process unneeded and the viewing angle dependence small. An alignment film does not need to be provided and rubbing treatment is thus not necessary; accordingly, electrostatic discharge damage caused by the rubbing treatment can be prevented and defects and damage of the liquid crystal display device in the fabrication process can be reduced. Thus, the productivity of the liquid crystal display device can be increased.

Moreover, it is possible to use a method called domain multiplication or multi-domain design, in which a pixel (pixel) is divided into some regions (subpixels) and molecules are aligned in different directions in their respective regions.

The specific resistance of a liquid crystal material is greater than or equal to 1×10⁹ Ω·cm, preferably greater than or equal to 1×10¹¹Ω.cm, further preferably greater than or equal to 1×10¹² Ω·cm. Note that the value of the specific resistance in this specification is a value measured at 20° C.

As illustrated in FIG. 38B, the pixel 230 may include the pixel circuit 51L instead of the pixel circuit 51K. The pixel circuit 51L includes the transistor 52A having a back gate. In the transistor 52A illustrated in FIG. 38B, the gate is electrically connected to the back gate. Thus, the gate and the back gate always have the same potential.

The use of the transistor 10 of one embodiment of the present invention in the pixel circuit of the display device can reduce the area occupied by the pixel circuit. Thus, the resolution of the display device can be improved. For example, a display device with a resolution higher than or equal to 1000 ppi, preferably higher than or equal to 2000 ppi, further preferably higher than or equal to 3000 ppi, still further preferably higher than or equal to 4000 ppi, yet further preferably higher than or equal to 5000 ppi, yet still further preferably higher than or equal to 6000 ppi, and lower than or equal to 10000 ppi, lower than or equal to 9000 ppi, or lower than or equal to 8000 ppi can be obtained.

The reduction in the area occupied by the pixel circuit can increase the number of pixels of the display device (can increase the definition). For example, a display device with an extremely high definition of HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320) can be obtained.

Accordingly, the use of the transistor 10 of one embodiment of the present invention in the pixel circuit of the display device can increase the display quality of the display device. A bottom-emission display device using an EL element can have a high aperture ratio of a pixel. A pixel with a high aperture ratio can have a lower current density than a pixel with a low aperture ratio when the pixel with a high aperture ratio and the pixel with a low aperture ratio emit light with the same luminance. Thus, the reliability of the display device can be improved.

### [Structural Example of Peripheral Circuit]

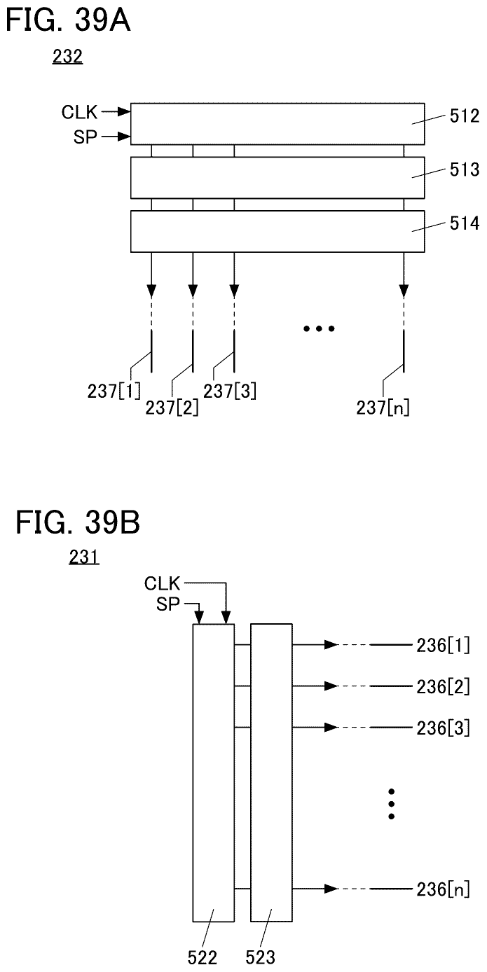

FIG. 39A illustrates a structural example of the second driver circuit portion 232. The second driver circuit portion 232 includes a shift register 512, a latch circuit 513, and a buffer 514. A wiring 237[1], a wiring 237[2], a wiring 237[3], and a wiring 237[n] are illustrated as the wirings 237. FIG. 39B illustrates a structural example of the first driver circuit portion 231. The first driver circuit portion 231 includes a shift register 522 and a buffer 523. A wiring 236[1], a wiring 236[2], a wiring 236[3], and a wiring 236[n] are illustrated as the wirings 236.

A start pulse SP, a clock signal CLK, and the like are input to the shift register 512 and the shift register 522. The shift register 100 described in the above embodiment can be used as each of the shift register 512 and the shift register 522.

### [Pixel Layout]

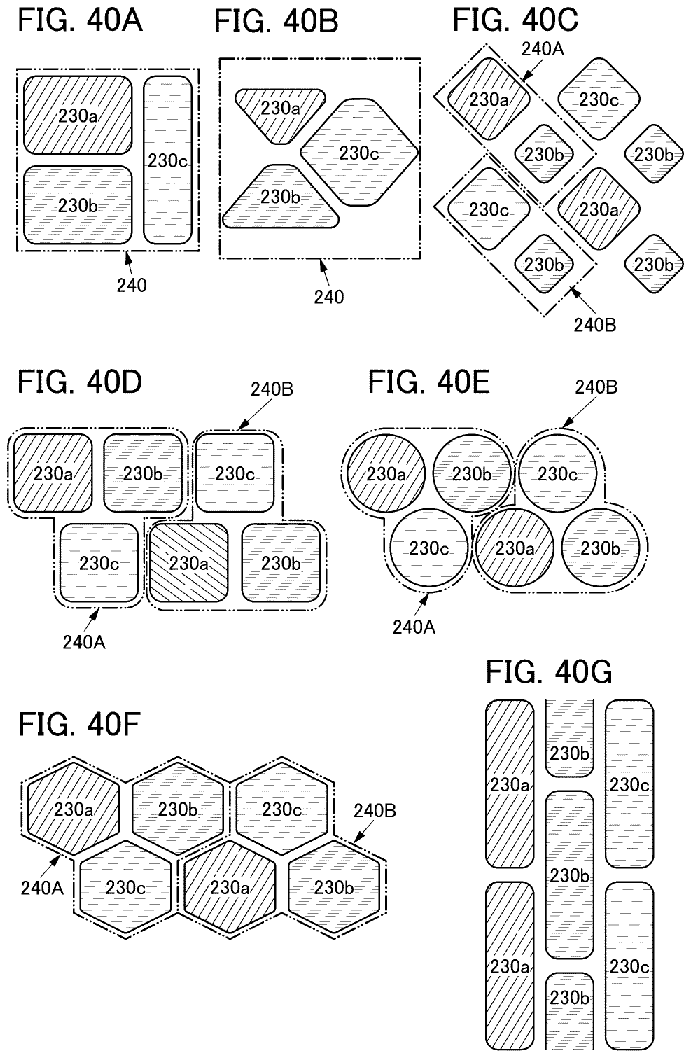

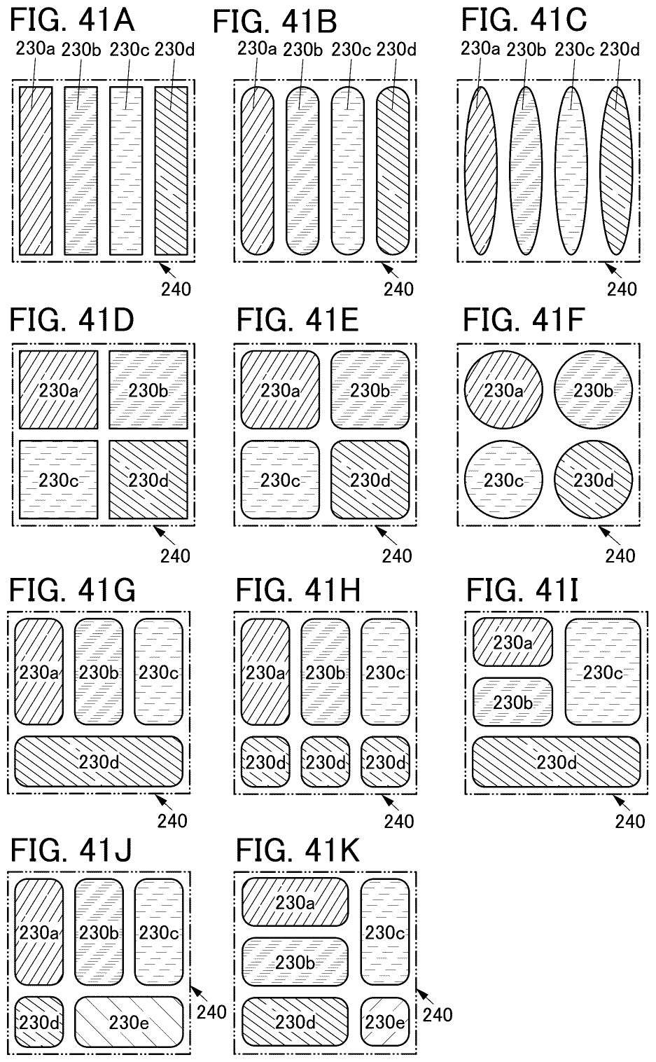

Pixel layouts different from that in FIG. 34A will be mainly described with reference to FIG. 40A to FIG. 40G and FIG. 41A to FIG. 41K. There is no particular limitation on the arrangement of subpixels, and a variety of pixel layouts can be employed. Examples of the arrangement of subpixels include stripe arrangement, S-stripe arrangement, matrix arrangement, delta arrangement, Bayer arrangement, and PenTile arrangement.

Note that the planar shapes of the subpixels illustrated in FIG. 34A, FIG. 40A to FIG. 40G, and FIG. 41A to FIG. 41K correspond to the planar shapes of light-emitting regions.

Examples of the planar shape of the subpixel include polygons such as a triangle, a tetragon (including a rectangle and a square), and a pentagon; polygons with rounded corners; an ellipse; and a circle.

The pixel circuit 51 included in the subpixel (the pixel 230) may be placed to overlap with a light-emitting region or may be placed outside the light-emitting region.

The pixel 240 illustrated in FIG. 40A employs S-stripe arrangement. The pixel 240 illustrated in FIG. 40A is composed of three types of subpixels that are the pixel 230a, the pixel 230b, and the pixel 230c.

The pixel 240 illustrated in FIG. 40B includes the pixel 230a having a rough trapezoidal planar shape with rounded corners, the pixel 230b having a rough triangle planar shape with rounded corners, and the pixel 230c having a rough tetragonal or rough hexagonal planar shape with rounded corners. The pixel 230a has a larger light-emitting area than the pixel 230b. In this manner, the shapes and sizes of the subpixels can be determined independently. For example, the size of a subpixel including a light-emitting device with higher reliability can be smaller.

A pixel 240A and a pixel 240B illustrated in FIG. 40C employ PenTile arrangement. FIG. 40C illustrates an example in which the pixels 240A including the pixel 230a and the pixel 230b and the pixels 240B including the pixel 230b and the pixel 230c are alternately arranged.

The pixel 240A and the pixel 240B illustrated in FIG. 40D to FIG. 40F employ delta arrangement. The pixel 240A includes two subpixels (the pixel 230a and the pixel 230b) in the upper row (first row) and one subpixel (the pixel 230c) in the lower row (second row). The pixel 240B includes one subpixel (the pixel 230c) in the upper row (first row) and two subpixels (the pixel 230a and the pixel 230b) in the lower row (second row).

FIG. 40D illustrates an example where each subpixel has a rough tetragonal planar shape with rounded corners, FIG. 40E illustrates an example where each subpixel has a circular planar shape, and FIG. 40F illustrates an example where each subpixel has a rough hexagonal planar shape with rounded corners.

In FIG. 40F, each subpixel is placed inside one of close-packed hexagonal regions. Focusing on one of the subpixels, the subpixel is placed so as to be surrounded by six subpixels. The subpixels are arranged such that subpixels that emit light of the same color are not adjacent to each other. For example, focusing on the pixel 230a, the pixel 230a is surrounded by three pixels 230b and three pixels 230c that are alternately arranged.

FIG. 40G illustrates an example in which subpixels of different colors are arranged in a zigzag manner. Specifically, the positions of the top sides of two subpixels arranged in the column direction (e.g., the pixel 230a and the pixel 230b or the pixel 230b and the pixel 230c) are not aligned in a plan view.

For example, in each pixel illustrated in FIG. 40A to FIG. 40G, it is preferable that the pixel 230a be a subpixel R emitting red light, the pixel 230b be a subpixel G emitting green light, and the pixel 230c be a subpixel B emitting blue light. Note that the structure of the subpixels is not limited to this, and the colors and arrangement order of the subpixels can be determined as appropriate. For example, the pixel 230b may be the subpixel R emitting red light and the pixel 230a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a subpixel sometimes has a polygonal planar shape with rounded corners, an elliptical planar shape, a circular planar shape, or the like.

In the case where the EL layer is processed into an island shape using a resist mask, a resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape after being processed. As a result, the EL layer may have a polygonal planar shape with rounded corners, an elliptical planar shape, a circular planar shape, or the like. For example, when a resist mask having a square planar shape is intended to be formed, a resist mask having a circular planar shape may be formed, and the EL layer may have a circular planar shape.

Note that to obtain a desired planar shape of the EL layer, a technique of correcting a mask pattern in advance such that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 41A to FIG. 411, the pixel can be configured to include four types of subpixels.

The pixels 240 illustrated in FIG. 41A to FIG. 41C employ stripe arrangement.

FIG. 41A illustrates an example where each subpixel has a rectangular planar shape, FIG. 41B illustrates an example where each subpixel has a planar shape formed by combining two half circles and a rectangle, and FIG. 41C illustrates an example where each subpixel has an elliptical planar shape.

The pixels 240 illustrated in FIG. 41D to FIG. 41F employ matrix arrangement.

FIG. 41D illustrates an example where each subpixel has a square planar shape, FIG. 41E illustrates an example where each subpixel has a substantially square planar shape with rounded corners, and FIG. 41F illustrates an example where each subpixel has a circular planar shape.

FIG. 41G and FIG. 41H each illustrate an example in which one pixel 240 is composed of subpixels arranged in two rows and three columns.

The pixel 240 illustrated in FIG. 41G includes three subpixels (the pixel 230a, the pixel 230b, and the pixel 230c) in the upper row (first row) of the pixel 240 and one subpixel (a pixel 230d) in the lower row (second row) thereof. In other words, the pixel 240 includes the pixel 230a in the left column (first column), the pixel 230b in the center column (second column), the pixel 230c in the right column (third column), and the pixel 230d across these three columns.

The pixel 240 illustrated in FIG. 41H includes three subpixels (the pixel 230a, the pixel 230b, and the pixel 230c) in the upper row (first row) and three pixels 230d in the lower row (second row). In other words, the pixel 240 includes the pixel 230a and the pixel 230d in the left column (first column) of the pixel 240, the pixel 230b and the pixel 230d in the center column (second column) thereof, and the pixel 230c and the pixel 230d in the right column (third column) thereof. Aligning the positions of the subpixels in the upper row and the lower row as illustrated in FIG. 41H enables dust and the like that would be produced in the manufacturing process to be removed efficiently. Thus, a display device with high display quality can be provided.

FIG. 41I illustrates an example in which one pixel 240 is composed of subpixels arranged in three rows and two columns.

The pixel 240 illustrated in FIG. 411 includes the pixel 230a in the upper row (first row) of the pixel 240, the pixel 230b in the center row (second row) thereof, the pixel 230c across the first row and the second row, and one subpixel (the pixel 230d) in the lower row (third row) thereof. In other words, the pixel 240 includes the pixel 230a and the pixel 230b in the left column (first column) of the pixel 240, the pixel 230c in the right column (second column) thereof, and the pixel 230d across these two columns thereof.

The pixels 240 illustrated in FIG. 41A to FIG. 41I are each composed of four subpixels: the pixel 230a, the pixel 230b, the pixel 230c, and the pixel 230d.

The pixel 230a, the pixel 230b, the pixel 230c, and the pixel 230d can be configured to include light-emitting devices whose emission colors are different. The pixel 230a, the pixel 230b, the pixel 230c, and the pixel 230d can be subpixels of four colors of R, G, B, and white (W), subpixels of four colors of R, G, B, and Y, or subpixels of R, G, B, and infrared light (IR), for example.

In the pixels 240 illustrated in FIG. 41A to FIG. 411, the pixel 230a may be the subpixel R emitting red light, the pixel 230b may be the subpixel G emitting green light, the pixel 230c may be the subpixel B emitting blue light, and the pixel 230d may be any of a subpixel W emitting white light, a subpixel emitting yellow light, and a subpixel emitting near-infrared light, for example. In the case of such a structure, stripe arrangement is employed as the layout of R, G, and B in the pixels 240 illustrated in FIG. 41G and FIG. 41H, leading to higher display quality. In addition, what is called S-stripe arrangement is employed as the layout of R, G, and B in the pixel 240 illustrated in FIG. 41I, leading to higher display quality.

Note that the pixel 240 may include a subpixel including a light-receiving element (also referred to as a light-receiving device).

In the pixels 240 illustrated in FIG. 41A to FIG. 41I, any one of the pixel 230a to the pixel 230d may be a subpixel including a light-receiving device.

In the pixels 240 illustrated in FIG. 41A to FIG. 41I, the pixel 230a may be the subpixel R emitting red light, the pixel 230b may be the subpixel G emitting green light, the pixel 230c may be the subpixel B emitting blue light, and the pixel 230d may be a subpixel S including a light-receiving device, for example. In the case of such a structure, stripe arrangement is employed as the layout of R, G, and B in the pixels 240 illustrated in FIG. 41G and FIG. 41H, leading to higher display quality. In addition, what is called S-stripe arrangement is employed as the layout of R, G, and B in the pixel 240 illustrated in FIG. 41I, leading to higher display quality.

There is no particular limitation on the wavelength of light detected by the subpixel S including a light-receiving device. The subpixel S can be configured to detect one or both of visible light and infrared light.

As illustrated in FIG. 41J and FIG. 41K, one pixel 240 may be configured to include five types of subpixels.

FIG. 41J illustrates an example in which one pixel 240 is composed of subpixels arranged in two rows and three columns.

The pixel 240 illustrated in FIG. 41J includes three subpixels (the pixel 230a, the pixel 230b, and the pixel 230c) in the upper row (first row) of the pixel 240 and two subpixels (the pixel 230d and a pixel 230e) in the lower row (second row) thereof. In other words, the pixel 240 includes the pixel 230a and the pixel 230d in the left column (first column) of the pixel 240, the pixel 230b in the center column (second column) thereof, the pixel 230c in the right column (third column) thereof, and the pixel 230e across the second column and the third column thereof.

FIG. 41K illustrates an example in which one pixel 240 is composed of subpixels arranged in three rows and two columns.

The pixel 240 illustrated in FIG. 41K includes the pixel 230a in the upper row (first row) of the pixel 240, the pixel 230b in the center row (second row) thereof, the pixel 230c across the first row and the second row, and two subpixels (the pixel 230d and the pixel 230e) in the lower row (third row) thereof. In other words, the pixel 240 includes the pixel 230a, the pixel 230b, and the pixel 230d in the left column (first column) and the pixel 230c and the pixel 230e in the right column (second column).

In the pixels 240 illustrated in FIG. 41J and FIG. 41K, it is preferable that the pixel 230a be the subpixel R emitting red light, the pixel 230b be the subpixel G emitting green light, and the pixel 230c be the subpixel B emitting blue light, for example. In the case of such a structure, stripe arrangement is employed as the layout of subpixels in the pixels 240 illustrated in FIG. 41J, leading to higher display quality. In addition, what is called S-stripe arrangement is employed as the layout of subpixels in the pixel 240 illustrated in FIG. 41K, leading to higher display quality.

In the pixels 240 illustrated in FIG. 41J and FIG. 41K, for example, the subpixel S including a light-receiving device may be used as at least one of the pixel 230d and the pixel 230e. In the case where light-receiving devices are used in both the pixel 230d and the pixel 230e, the light-receiving devices may have different structures. For example, the wavelength ranges of detected light may be different at least partly. Specifically, one of the pixel 230d and the pixel 230e may include a light-receiving device mainly detecting visible light and the other may include a light-receiving device mainly detecting infrared light.

In the pixels 240 illustrated in FIG. 41J and FIG. 41K, for example, the subpixel S including a light-receiving device may be used as one of the pixel 230d and the pixel 230e and a subpixel including a light-emitting device that can be used as a light source may be used as the other. For example, one of the pixel 230d and the pixel 230e may be a subpixel IR (not illustrated) emitting infrared light and the other may be the subpixel S (not illustrated) including a light-receiving device detecting infrared light.

In a pixel including the subpixels R, G, B, IR, and S, while an image is displayed using the subpixels R, G, and B, reflected light of infrared light emitted from the subpixel IR that is used as a light source can be detected by the subpixel S.

As described above, in the display device of one embodiment of the present invention, various layouts of the subpixels (the pixels 230) can be employed for the pixel 240. Furthermore, the pixel 240 may be configured to include both a light-emitting device and a light-receiving device. Also in this case, any of various layouts can be employed.

The structure described in this embodiment can be used in an appropriate combination with the structures described in the other embodiments.

### Embodiment 4

In this embodiment, a light-emitting device that can be used as the light-emitting element 61 is described.

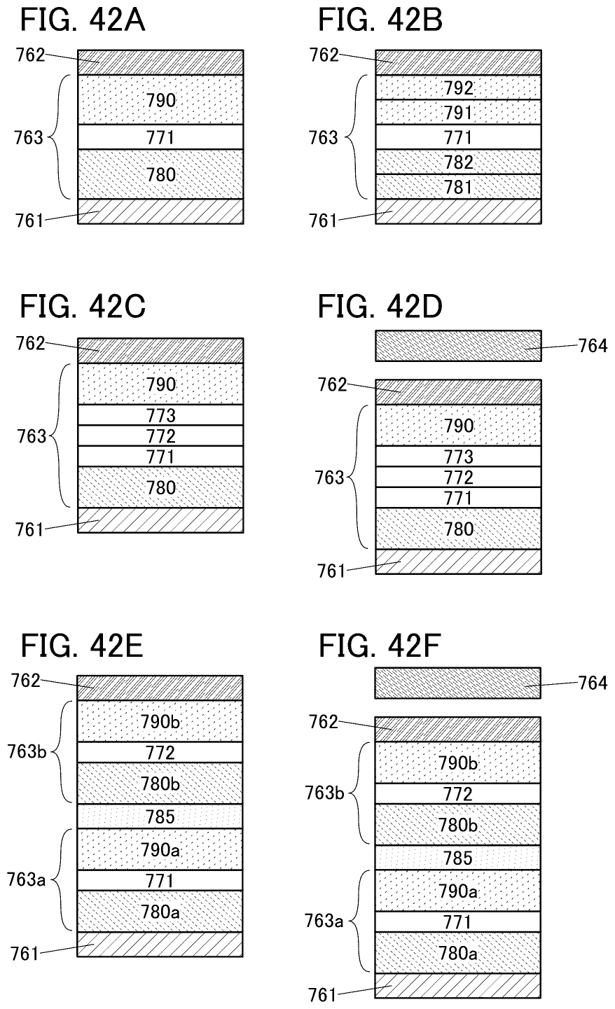

As illustrated in FIG. 42A, the light-emitting device includes an EL layer 763 between a pair of electrodes (a lower electrode 761 and an upper electrode 762). The EL layer 763 can be formed using a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the above structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 42A is referred to as a single structure in this specification.

FIG. 42B is a modification example of the EL layer 763 included in the light-emitting device illustrated in FIG. 42A. Specifically, the light-emitting device illustrated in FIG. 42B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected into the light-emitting layer 771, and the efficiency of the recombination of carriers in the light-emitting layer 771 can be increased.

Note that structures in which a plurality of light-emitting layers (light-emitting layers 771, 772, and 773) are provided between the layer 780 and the layer 790 as illustrated in FIG. 42C and FIG. 42D are also variations of the single structure. Although FIG. 42C and FIG. 42D illustrate the examples where three light-emitting layers are included, the light-emitting device having a single structure may include two light-emitting layers or four or more light-emitting layers. In addition, the light-emitting device having a single structure may include a buffer layer between two light-emitting layers. A carrier-transport layer (a hole-transport layer or an electron-transport layer) can be used as the buffer layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 42E and FIG. 42F is referred to as a tandem structure in this specification. Note that the tandem structure may be referred to as a stack structure. The tandem structure enables a light-emitting device capable of high-luminance light emission. Furthermore, the tandem structure can reduce the amount of current needed for obtaining the same luminance as compared with the single structure, and thus can improve the reliability.

Note that FIG. 42D and FIG. 42F illustrate examples where the display device includes a layer 764 overlapping with the light-emitting device. FIG. 42D illustrates an example in which the layer 764 overlaps with the light-emitting device illustrated in FIG. 42C, and FIG. 42F illustrates an example in which the layer 764 overlaps with the light-emitting device illustrated in FIG. 42E. In FIG. 42D and FIG. 42F, a conductive film transmitting visible light is used for the upper electrode 762 to extract light from the upper electrode 762 side.

One or both of a color conversion layer and a color filter (a coloring layer) can be used as the layer 764.

In FIG. 42C and FIG. 42D, light-emitting substances emitting light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 42D for converting blue light emitted from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the desired color can be absorbed by the coloring layer, and color purity of light emitted by a subpixel can be improved.

In FIG. 42C and FIG. 42D, light-emitting substances that emit light of different colors may be used for the light-emitting layer 771, the light-emitting layer 772, and the light-emitting layer 773. White light emission can be obtained when light emitted from the light-emitting layer 771, light emitted from the light-emitting layer 772, and light emitted from the light-emitting layer 773 have a relationship of complementary colors. The light-emitting device having a single structure preferably includes a light-emitting layer containing a light-emitting substance that emits blue light and a light-emitting layer containing a light-emitting substance that emits visible light with a longer wavelength than blue light, for example.

A color filter may be provided as the layer 764 illustrated in FIG. 42D. When white light passes through the color filter, light of a desired color can be obtained.

In the case where the light-emitting device having a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be R, G, and B from the anode side or R, B, and G from the anode side, for example. In that case, a buffer layer may be provided between R and G or between R and B.

For example, in the case where the light-emitting device having a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a light-emitting device having a BY single structure.

A light-emitting device that emits white light preferably contains two or more kinds of light-emitting substances. To obtain white light emission, two or more light-emitting substances are selected such that they emit light having a relationship of complementary colors. For example, when the emission color of a first light-emitting layer and the emission color of a second light-emitting layer have a relationship of complementary colors, it is possible to obtain a light-emitting device which emits white light as a whole. The same applies to a light-emitting device including three or more light-emitting layers.

Also in FIG. 42C and FIG. 42D, the layer 780 and the layer 790 may each independently have a stacked-layer structure of two or more layers as illustrated in FIG. 42B.

In FIG. 42E and FIG. 42F, light-emitting substances emitting light of the same color, or moreover, the same light-emitting substance may be used for the light-emitting layer 771 and the light-emitting layer 772. For example, in light-emitting devices included in subpixels that emit light of different colors, a light-emitting substance that emits blue light may be used for each of the light-emitting layer 771 and the light-emitting layer 772. In a subpixel that emits blue light, blue light emitted from the light-emitting device can be extracted. In each of the subpixel that emits red light and the subpixel that emits green light, a color conversion layer is provided as the layer 764 illustrated in FIG. 42F for converting blue light emitted from the light-emitting device into light with a longer wavelength, so that red light or green light can be extracted. As the layer 764, both a color conversion layer and a coloring layer are preferably used.

In the case where the light-emitting device having the structure illustrated in FIG. 42E or FIG. 42F is used for the subpixels emitting different colors, the subpixels may use different light-emitting substances. Specifically, in the light-emitting device included in the subpixel emitting red light, a light-emitting substance that emits red light can be used for each of the light-emitting layer 771 and the light-emitting layer 772. Similarly, in the light-emitting device included in the subpixel emitting green light, a light-emitting substance that emits green light can be used for each of the light-emitting layer 771 and the light-emitting layer 772. In the light-emitting device included in the subpixel emitting blue light, a light-emitting substance that emits blue light can be used for each of the light-emitting layer 771 and the light-emitting layer 772. A display device with such a structure includes a light-emitting device with a tandem structure and can be regarded as having an SBS (Side By Side) structure. Thus, the display device can take advantages of both the tandem structure and the SBS structure. Accordingly, a light-emitting device being capable of high-luminance light emission and having high reliability can be obtained.

In FIG. 42E and FIG. 42F, light-emitting substances that emit light of different colors may be used for the light-emitting layer 771 and the light-emitting layer 772. When light emitted from the light-emitting layer 771 and light emitted from the light-emitting layer 772 have a relationship of complementary colors, white light emission can be obtained. A color filter may be provided as the layer 764 illustrated in FIG. 42F. When white light passes through the color filter, light of a desired color can be obtained.

Although FIG. 42E and FIG. 42F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 42E and FIG. 42F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 42E and FIG. 42F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the above structures of the layer 780a and the layer 790a are replaced with each other, and the above structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

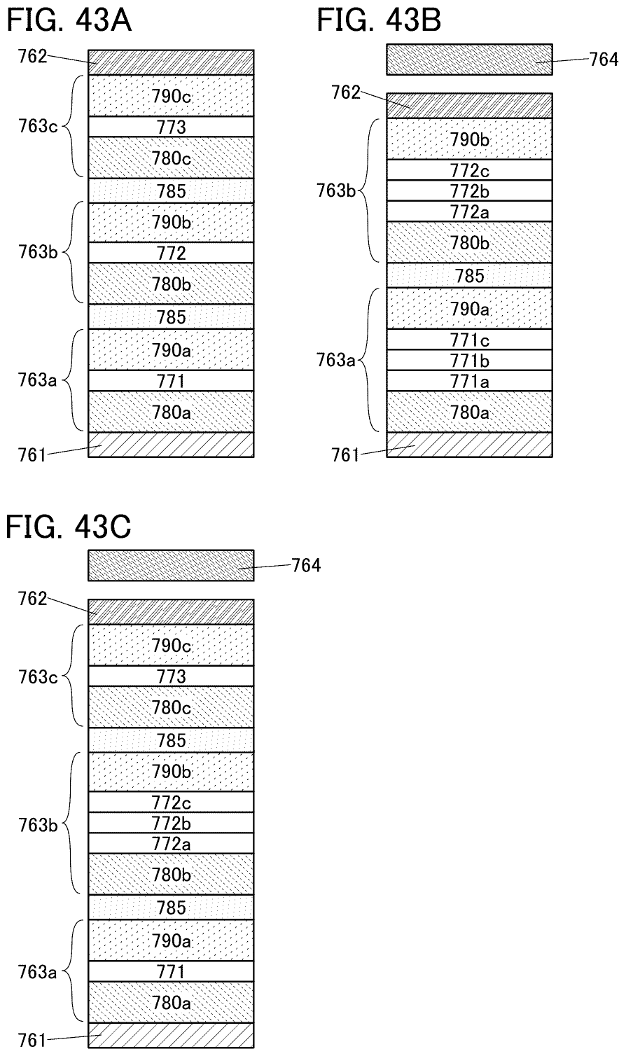

Examples of the light-emitting device having a tandem structure include structures illustrated in FIG. 43A to FIG. 43C.

FIG. 43A illustrates a structure including three light-emitting units. In FIG. 43A, a plurality of light-emitting units (the light-emitting unit 763a, the light-emitting unit 763b, and a light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 43A, the light-emitting layer 771, the light-emitting layer 772, and the light-emitting layer 773 preferably contain light-emitting substances that emit light of the same color.

Specifically, the light-emitting layer 771, the light-emitting layer 772, and the light-emitting layer 773 can each contain a red (R) light-emitting substance (a so-called three-unit tandem structure of R\R\R); the light-emitting layer 771, the light-emitting layer 772, and the light-emitting layer 773 can each contain a green (G) light-emitting substance (a so-called three-unit tandem structure of G\G\G); or the light-emitting layer 771, the light-emitting layer 772, and the light-emitting layer 773 can each contain a blue (B) light-emitting substance (a so-called three-unit tandem structure of B\B\B). Note that “alb” means that a light-emitting unit containing a light-emitting substance that emits light of b is provided over a light-emitting unit containing a light-emitting substance that emits light of a with a charge-generation layer therebetween, where a and b represent colors.

In FIG. 43A, light-emitting substances that emit light of different colors may be used for some or all of the light-emitting layer 771, the light-emitting layer 772, and the light-emitting layer 773. Examples of the combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 43B. FIG. 43B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 43B, the light-emitting unit 763a is configured to emit white (W) light by selecting light-emitting substances to satisfy the relationship of complementary colors for the light-emitting layer 771a, the light-emitting layer 771b, and the light-emitting layer 771c. Furthermore, the light-emitting unit 763b is configured to emit white (W) light by selecting light-emitting substances to satisfy the relationship of complementary colors for the light-emitting layer 772a, the light-emitting layer 772b, and the light-emitting layer 772c. That is, the structure illustrated in FIG. 43B is a two-unit tandem structure of WWW. Note that there is no particular limitation on the stacking order of the light-emitting substances satisfying the relationship of complementary colors. The practitioner can select the optimal stacking order as appropriate. Although not illustrated, a three-unit tandem structure of WWWWW or a tandem structure with four or more units may be employed.

In the case of a light-emitting device with a tandem structure, examples of the structure include a two-unit tandem structure of BY or Y\B including a light-emitting unit that emits yellow (Y) light and a light-emitting unit that emits blue (B) light; a two-unit tandem structure of R·G\B or B\R.G including a light-emitting unit that emits red (R) and green (G) light and a light-emitting unit that emits blue (B) light; a three-unit tandem structure of BY\B including a light-emitting unit that emits blue (B) light, a light-emitting unit that emits yellow (Y) light, and a light-emitting unit that emits blue (B) light in this order; a three-unit tandem structure of BYG\B including a light-emitting unit that emits blue (B) light, a light-emitting unit that emits yellow-green (YG) light, and a light-emitting unit that emits blue (B) light in this order; and a three-unit tandem structure of BIG\B including a light-emitting unit that emits blue (B) light, a light-emitting unit that emits green (G) light, and a light-emitting unit that emits blue (B) light in this order. Note that “a.b” means that one light-emitting unit contains a light-emitting substance that emits light of a and a light-emitting substance that emits light of b.

As illustrated in FIG. 43C, a light-emitting unit including one light-emitting layer and a light-emitting unit including a plurality of light-emitting layers may be used in combination.

Specifically, in the structure illustrated in FIG. 43C, a plurality of light-emitting units (the light-emitting unit 763a, the light-emitting unit 763b, and the light-emitting unit 763c) are connected in series with the charge-generation layers 785 therebetween. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 43C, for example, a three-unit tandem structure of B\R.G.YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device are described.

A conductive film that transmits visible light is used for the electrode through which light is extracted, which is either the lower electrode 761 or the upper electrode 762. A conductive film that reflects visible light is preferably used as the electrode through which light is not extracted. In the case where a display device includes a light-emitting device that emits infrared light, it is preferable that a conductive film that transmits visible light and infrared light be used for the electrode through which light is extracted and a conductive film that reflects visible light and infrared light be used for the electrode through which light is not extracted.

A conductive film that transmits visible light may be used also for the electrode through which light is not extracted. In that case, the electrode is preferably placed between a reflective layer and the EL layer 763. That is, light emitted from the EL layer 763 may be reflected by the reflective layer to be extracted from the display device.

As a material that forms the pair of electrodes of the light-emitting device, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Therefore, one of the pair of electrodes of the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The light transmittance of the electrode having a property of transmitting visible light is higher than or equal to 40%. For example, an electrode having a visible light (light with a wavelength greater than or equal to 400 nm and less than 750 nm) transmittance higher than or equal to 40% is preferably used as the electrode having a property of transmitting visible light in the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ω·cm.

The light-emitting device includes at least the light-emitting layer. The light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may also be contained. Each of the layers included in the light-emitting device can be formed by an evaporation method (including a vacuum evaporation method), a transfer method, a printing method, an inkjet method, a coating method, or the like.

The light-emitting layer contains one or more kinds of light-emitting substances. As the light-emitting substance, a substance whose emission color is blue, purple, blue-purple, green, yellow-green, yellow, orange, red, or the like is appropriately used. As the light-emitting substance, a substance emitting near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative having an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a material having a high hole-transport property which can be used for the hole-transport layer and will be described later. As the electron-transport material, it is possible to use a material having a high electron-transport property which can be used for the electron-transport layer and will be described later. As one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting device can be achieved at the same time.

The hole-injection layer is a layer that injects holes from the anode to the hole-transport layer and contains a material with a high hole-injection property. Examples of the material with a high hole-injection property include an aromatic amine compound, and a composite material containing a hole-transport material and an acceptor material (an electron-accepting material).

As the hole-transport material, it is possible to use a material having a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the material with a high hole-injection property, a material containing a hole-transport material and the above-described oxide of a metal belonging to any of Group 4 to Group 8 of the periodic table (typically, molybdenum oxide) may be used, for example.

The hole-transport layer is a layer that transports holes, which are injected from the anode by the hole-injection layer, to the light-emitting layer. The hole-transport layer is a layer that contains a hole-transport material. The hole-transport material is preferably a substance having a hole mobility greater than or equal to 1×10⁻⁶ cm²/Vs. Note that other substances can also be used as long as they have a property of transporting more holes than electrons. The hole-transport material is preferably a material with a high hole-transport property, such as a T-electron rich heteroaromatic compound (e.g., a carbazole derivative, a thiophene derivative, or a furan derivative) or an aromatic amine (a compound having an aromatic amine skeleton).

The electron-blocking layer is provided in contact with the light-emitting layer. The electron-blocking layer is a layer that has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer that transports electrons, which are injected from the cathode by the electron-injection layer, to the light-emitting layer. The electron-transport layer is a layer that contains an electron-transport material. The electron-transport material is preferably a substance having an electron mobility greater than or equal to 1×10⁻⁶ cm²/Vs. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a x-electron deficient heteroaromatic compound such as a nitrogen-containing heteroaromatic compound.

The hole-blocking layer is provided in contact with the light-emitting layer. The hole-blocking layer is a layer that has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer that injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the lowest unoccupied molecular orbital (LUMO) level of the material having a high electron-injection property and the work function value of the material used for the cathode is preferably small (specifically, smaller than or equal to 0.5 eV).

For the electron-injection layer, it is possible to use an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation:Liq), 2-(2-pyridyl) phenolatolithium (abbreviation:LiPP), 2-(2-pyridyl)-3-pyridinolatolithium (abbreviation: LiPPy), 4-phenyl-2-(2-pyridyl) phenolatolithium (abbreviation: LiPPP), lithium oxide (LiOx), or cesium carbonate, for example. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di (naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-α: 2′, 3′-c] phenazine (abbreviation: HATNA), 2,4,6-tris[3′-(pyridin-3-yl) biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (LizO)). Alternatively, a material that can be used for the above-described electron-injection layer is suitable for the electron-injection buffer layer.

The charge-generation layer preferably includes a layer containing a material having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the above-described charge-generation region, electron-injection buffer layer, and electron-relay layer cannot be clearly distinguished from each other in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the above-described electron-injection layer.

When the light-emitting units are stacked, provision of a charge-generation layer between the two light-emitting units can suppress an increase in driving voltage.

The structure described in this embodiment can be used in an appropriate combination with the structures described in the other embodiments.

### Embodiment 5

An example of a method for forming the light-emitting element 61 will be described in this embodiment.

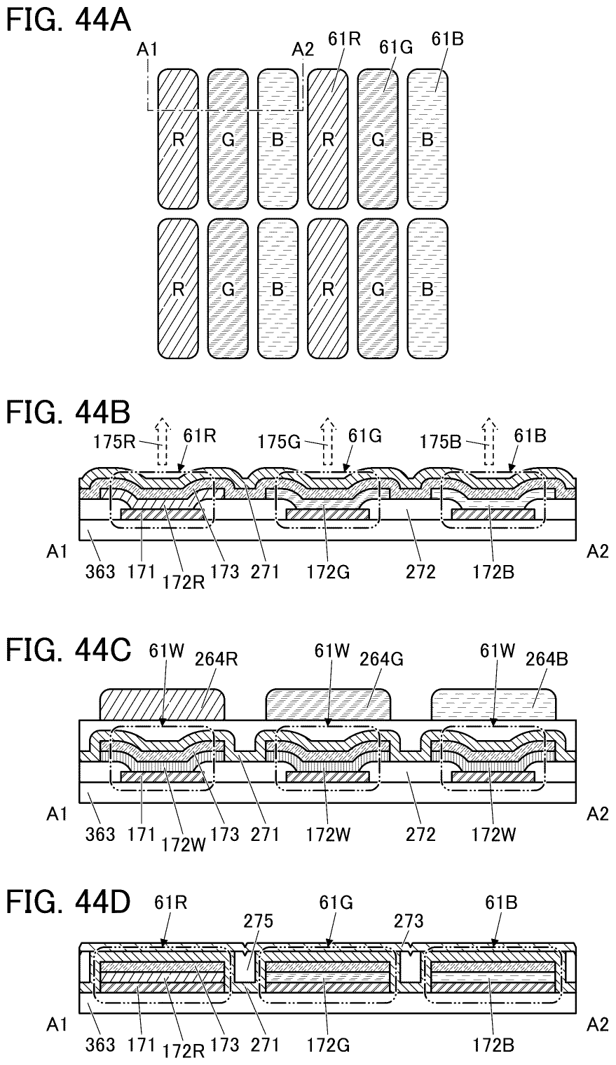

FIG. 44A illustrates a schematic plan view of the light-emitting element 61. The light-emitting element 61 includes a plurality of light-emitting elements 61R exhibiting red, a plurality of light-emitting elements 61G exhibiting green, and a plurality of light-emitting elements 61B exhibiting blue. In FIG. 44A, light-emitting regions of the light-emitting elements are denoted by R, G, and B to easily differentiate the light-emitting elements. Although FIG. 44A illustrates the structure having three emission colors of red (R), green (G), and blue (B), one embodiment of the present invention is not limited thereto. For example, the structure may have four or more colors.

The light-emitting elements 61R, the light-emitting elements 61G, and the light-emitting elements 61B are arranged in a matrix. Although FIG. 44A illustrates what is called a stripe arrangement in which the light-emitting elements of the same color are arranged in one direction, the arrangement method of the light-emitting elements is not limited thereto.

As each of the light-emitting element 61R, the light-emitting element 61G, and the light-emitting element 61B, an organic EL device such as an OLED (Organic Light Emitting Diode) or a QOLED (Quantum-dot Organic Light Emitting Diode) is preferably used. A light-emitting substance contained in the EL element can be a substance that emits fluorescent light (a fluorescent material), a substance that emits phosphorescent light (a phosphorescent material), or a substance that exhibits thermally activated delayed fluorescence (a thermally activated delayed fluorescence (TADF) material). As the light-emitting substance contained in the EL element, not only an organic compound but also an inorganic compound (a quantum dot material or the like) can be used.

FIG. 44B is a schematic cross-sectional view corresponding to the dashed-dotted line A1-A2 in FIG. 44A. FIG. 44B illustrates cross sections of the light-emitting element 61R, the light-emitting element 61G, and the light-emitting element 61B. The light-emitting element 61R, the light-emitting element 61G, and the light-emitting element 61B are each provided over an insulator 363 and include a conductor 171 functioning as a pixel electrode and a conductor 173 functioning as a common electrode. For the insulator 363, one or both of an inorganic insulating film and an organic insulating film can be used. An inorganic insulating film is preferably used for the insulator 363. Examples of the inorganic insulating film include an oxide insulating film and a nitride insulating film, such as a silicon oxide film, a silicon oxynitride film, a silicon nitride oxide film, a silicon nitride film, an aluminum oxide film, an aluminum oxynitride film, and a hafnium oxide film.

The light-emitting element 61R includes an EL layer 172R between the conductor 171 functioning as a pixel electrode and the conductor 173 functioning as a common electrode. The EL layer 172R contains at least a light-emitting organic compound that emits light with a peak in a red wavelength range. An EL layer 172G included in the light-emitting element 61G contains at least a light-emitting organic compound that emits light with a peak in a green wavelength range. An EL layer 172B included in the light-emitting element 61B contains at least a light-emitting organic compound that emits light with a peak in a blue wavelength range.

The EL layer 172R, the EL layer 172G, and the EL layer 172B may each include one or more of an electron-injection layer, an electron-transport layer, a hole-injection layer, and a hole-transport layer in addition to the layer containing a light-emitting substance (the light-emitting layer).

The conductor 171 functioning as a pixel electrode is provided in each of the light-emitting elements. The conductor 173 functioning as a common electrode is provided as a continuous layer shared by the light-emitting elements. A conductive film that has a property of transmitting visible light is used for either the conductor 171 functioning as a pixel electrode or the conductor 173 functioning as a common electrode, and a conductive film that has a reflective property is used for the other. When the conductor 171 functioning as a pixel electrode has a light-transmitting property and the conductor 173 functioning as a common electrode has a reflective property, a bottom-emission display device can be obtained, whereas when the conductor 171 functioning as a pixel electrode has a reflective property and the conductor 173 functioning as a common electrode has a light-transmitting property, a top-emission display device can be obtained. Note that when both the conductor 171 functioning as a pixel electrode and the conductor 173 functioning as a common electrode have a light-transmitting property, a dual-emission display device can be obtained.

For example, in the case where the light-emitting element 61R has a top-emission structure, light 175R is emitted from the light-emitting element 61R to the conductor 173 side. In the case where the light-emitting element 61G has a top-emission structure, light 175G is emitted from the light-emitting element 61G to the conductor 173 side. In the case where the light-emitting element 61B has a top-emission structure, light 175B is emitted from the light-emitting element 61B to the conductor 173 side.

An insulator 272 is provided to cover end portions of the conductor 171 functioning as a pixel electrode. End portions of the insulator 272 are preferably tapered. For the insulator 272, a material similar to the material that can be used for the insulator 363 can be used.

The insulator 272 is provided to prevent an unintentional electric short-circuit between adjacent light-emitting elements 61 and unintended light emission therefrom. The insulator 272 also has a function of preventing the contact of a metal mask with the conductor 171 in the case where the metal mask is used to form the EL layer 172.

The EL layer 172R, the EL layer 172G, and the EL layer 172B each include a region in contact with the planar surface of the conductor 171 functioning as a pixel electrode and a region in contact with a surface of the insulator 272. End portions of the EL layer 172R, the EL layer 172G, and the EL layer 172B are positioned over the insulator 272.

As illustrated in FIG. 44B, there is a gap between the two EL layers of the light-emitting elements with different light emission colors. In this manner, the EL layer 172R, the EL layer 172G, and the EL layer 172B are preferably provided so as not to be in contact with each other. This can prevent unintentional light emission (also referred to as crosstalk) from being caused by current flowing through two adjacent EL layers. As a result, the contrast can be increased to obtain a display device with high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of a photolithography method enables a display device to have a high resolution, which is difficult to obtain in the case of using a metal mask. Furthermore, leakage current between adjacent EL layers is reduced, enabling the display device to perform extremely clear display with high contrast and high display quality.

Although it is difficult to set the distance between adjacent light-emitting elements 61 to be less than 10 μm by a formation method using a metal mask, for example, a photolithography method can shorten the distance to be less than or equal to 8 μm, less than or equal to 3 μm, less than or equal to 2 μm, or less than or equal to 1 μm. Here, the distance between adjacent light-emitting elements 61 can be determined by the distance between end portions of two adjacent pixel electrodes. Alternatively, the distance between adjacent light-emitting elements 61 can be determined by the distance between end portions of two adjacent EL layers.

In this specification and the like, a device fabricated using a metal mask or an FMM (a fine metal mask, a high-resolution metal mask) may be referred to as a device having an MM (a metal mask) structure. In this specification and the like, a device fabricated without using a metal mask or an FMM may be referred to as a device having an MML (metal maskless) structure.

By shortening the interval between adjacent light-emitting elements 61 in the above manner, the area of a non-light-emitting region that may exist between two light-emitting elements can be significantly reduced, and the aperture ratio can be close to 100%. For example, the aperture ratio is higher than or equal to 50%, higher than or equal to 60%, higher than or equal to 70%, higher than or equal to 80%, or higher than or equal to 90%; that is, an aperture ratio lower than 100% can be achieved.

Furthermore, a pattern (also referred to as a processing size) of the EL layer itself can be made much smaller than that in the case of using a metal mask. For example, in the case of using a metal mask for forming EL layers separately, a variation in the thickness occurs between the center and the edge of the EL layer. This causes a reduction in an effective area that can be used as a light-emitting region with respect to the area of the EL layer. In contrast, in the above fabrication method, an EL layer is formed by processing a film deposited to have a uniform thickness, which enables a uniform thickness in the EL layer. Thus, even in a fine pattern, almost the whole area can be used as a light-emitting region. Therefore, the above fabrication method makes it possible to achieve both high resolution and a high aperture ratio.

In many cases, an organic film formed using an FMM has an extremely small taper angle (e.g., greater than 0° and less than) 30° so that the thickness of the film becomes smaller in a portion closer to an end portion. Therefore, it is difficult to clearly observe the side surface of an organic film formed using an FMM because the side surface and the planar surface are continuously connected. In contrast, an EL layer processed without using an FMM has a clear side surface. Part of the side surface of the EL layer preferably has a taper angle greater than or equal to 30° and less than or equal to 120°, further preferably greater than or equal to 60° and less than or equal to 120°.

A protective layer 271 is provided over the conductor 173 functioning as a common electrode so as to cover the light-emitting element 61R, the light-emitting element 61G, and the light-emitting element 61B. The protective layer 271 has a function of preventing diffusion of impurities such as water into the light-emitting elements from above.

The protective layer 271 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide (IGZO) may be used for the protective layer 271. Note that the protective layer 271 is formed by an ALD method, a CVD method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

Note that in this specification, a nitride oxide refers to a compound that contains more nitrogen than oxygen. An oxynitride refers to a compound that contains more oxygen than nitrogen. Note that the content of each element can be measured by Rutherford backscattering spectrometry (RBS), for example.

In the case where indium gallium zinc oxide is used for the protective layer 271, indium gallium zinc oxide can be processed by a wet etching method or a dry etching method. For example, in the case where IGZO is used for the protective layer 271, a chemical solution of oxalic acid, phosphoric acid, a mixed chemical solution (e.g., a mixed chemical solution of phosphoric acid, acetic acid, nitric acid, and water (also referred to as a mixed acid aluminum etchant)), or the like can be used. Note that the volume ratio of phosphoric acid to acetic acid to nitric acid to water in the mixed acid aluminum etchant can be 53.3:6.7:3.3:36.7 or the neighborhood thereof.

Note that the structure illustrated in FIG. 44B may be referred to as an SBS structure.

FIG. 44C illustrates an example different from the above. Specifically, in FIG. 44C, light-emitting elements 61 W that emit white light are provided. The light-emitting elements 61 W each include an EL layer 172 W that emits white light between the conductor 171 functioning as a pixel electrode and the conductor 173 functioning as a common electrode.

The EL layer 172 W can have, for example, a structure in which two or more light-emitting layers that are selected so that their emission colors have a relationship of complementary colors are stacked. It is also possible to use a stacked EL layer in which a charge-generation layer is provided between light-emitting layers.

FIG. 44C illustrates three light-emitting elements 61 W side by side. A coloring layer 264R is provided above the light-emitting element 61 W on the left. The coloring layer 264R functions as a band-pass filter that transmits red light. Similarly, a coloring layer 264G that transmits green light is provided above the light-emitting element 61 W in the middle, and a coloring layer 264B that transmits blue light is provided above the light-emitting element 61 W on the right. Thus, the display device can display an image with colors.

Here, the EL layer 172 W and the conductor 173 functioning as a common electrode are each separated between two adjacent light-emitting elements 61 W. This can prevent unintentional light emission from being caused by a current flowing through the EL layers 172 W of the two adjacent light-emitting elements 61 W. Particularly when a stacked EL layer in which a charge-generation layer is provided between two light-emitting layers is used as the EL layer 172 W, the effect of crosstalk becomes more significant as the resolution increases, i.e., as the distance between adjacent pixels decreases, leading to lower contrast. Thus, the above structure enables a display device to have both high resolution and high contrast.

The EL layer 172 W and the conductor 173 functioning as a common electrode are preferably separated by a photolithography method. This can reduce an interval between light-emitting elements, enabling a display device to have a higher aperture ratio than that formed using, for example, a shadow mask such as a metal mask.

Note that in the case of a bottom-emission light-emitting element, a coloring layer is provided between the conductor 171 functioning as a pixel electrode and the insulator 363.

FIG. 44D illustrates an example different from the above. Specifically, in FIG. 44D, the insulator 272 is not provided between the light-emitting element 61R, the light-emitting element 61G, and the light-emitting element 61B. With such a structure, the display device can have a high aperture ratio. When the insulator 272 is not provided, unevenness formed by the light-emitting elements 61 can be reduced, thereby improving the viewing angle of the display device. Specifically, the viewing angle can be greater than or equal to 150 degrees and less than 180 degrees, preferably greater than or equal to 160 degrees and less than 180 degrees.

The protective layer 271 covers side surfaces of the EL layer 172R, the EL layer 172G, and the EL layer 172B. With this structure, impurities (typically, water or the like) can be inhibited from entering the EL layer 172R, the EL layer 172G, and the EL layer 172B through their side surfaces. In addition, leakage current between adjacent light-emitting elements 61 is reduced, so that color saturation and contrast ratio are improved and power consumption is reduced.

In the structure illustrated in FIG. 44D, the planar shapes of the conductor 171, the EL layer 172R, and the conductor 173 are substantially the same. This structure can be formed in such a manner that the conductor 171, the EL layer 172R, and the conductor 173 are formed and collectively processed using a resist mask or the like. In this process, the EL layer 172R and the conductor 173 are processed using the conductor 173 as a mask, and thus this process can be called self-aligned patterning. Although the EL layer 172R is described here, the EL layer 172G and the EL layer 172B can each have a similar structure.

In FIG. 44D, a protective layer 273 is further provided over the protective layer 271. For example, the protective layer 271 can be formed with an apparatus that can deposit a film with excellent coverage (typically, an ALD apparatus or the like), and the protective layer 273 can be formed with an apparatus that can deposit a film with coverage inferior to that of the protective layer 271 (typically, a sputtering apparatus or the like), whereby a region 275 can be provided between the protective layer 271 and the protective layer 273. In other words, the region 275 is positioned between the EL layer 172R and the EL layer 172G and between the EL layer 172G and the EL layer 172B.

Note that the region 275 includes, for example, any one or more selected from air, nitrogen, oxygen, carbon dioxide, and Group 18 elements (typically, helium, neon, argon, xenon, krypton, and the like). Furthermore, for example, a gas used during the deposition of the protective layer 273 is sometimes included in the region 275. For example, in the case where the protective layer 273 is deposited by a sputtering method, any one or more of the above-described Group 18 elements is sometimes included in the region 275. In the case where a gas is included in the region 275, a gas can be identified with a gas chromatography method or the like. Alternatively, in the case where the protective layer 273 is deposited by a sputtering method, a gas used in the sputtering is sometimes contained in the protective layer 273. In that case, an element such as argon is sometimes detected when the protective layer 273 is analyzed by an energy dispersive X-ray analysis (EDX analysis) or the like.

In the case where the refractive index of the region 275 is lower than the refractive index of the protective layer 271, light emitted from the EL layer 172R, the EL layer 172G, or the EL layer 172B is reflected at the interface between the protective layer 271 and the region 275. Thus, light emitted from the EL layer 172R, the EL layer 172G, or the EL layer 172B can be inhibited from entering an adjacent pixel in some cases. This can inhibit color mixture of light emitted from adjacent pixels and thus can improve the display quality of the display device.

In the case of the structure illustrated in FIG. 44D, a region between the light-emitting element 61R and the light-emitting element 61G or a region between the light-emitting element 61G and the light-emitting element 61B (hereinafter simply referred to as a distance between the light-emitting elements) can be small. Specifically, the distance between the light-emitting elements can be less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device includes a region in which an interval between the side surface of the EL layer 172R and the side surface of the EL layer 172G or an interval between the side surface of the EL layer 172G and the side surface of the EL layer 172B is less than or equal to 1 μm, preferably less than or equal to 0.5 μm (500 nm), further preferably less than or equal to 100 nm.

In the case where the region 275 includes a gas, the light-emitting elements can be separated from each other and color mixture of light from the light-emitting elements, crosstalk, or the like can be inhibited.

The region 275 may be a space or may be filled with a filler. Examples of the filler include an epoxy resin, an acrylic resin, a silicone resin, a phenol resin, polyimide, a PVC (polyvinyl chloride) resin, a PVB (polyvinyl butyral) resin, and an EVA (ethylene vinyl acetate) resin. Alternatively, a photoresist may be used as the filler. The photoresist used as the filler may be a positive photoresist or a negative photoresist.

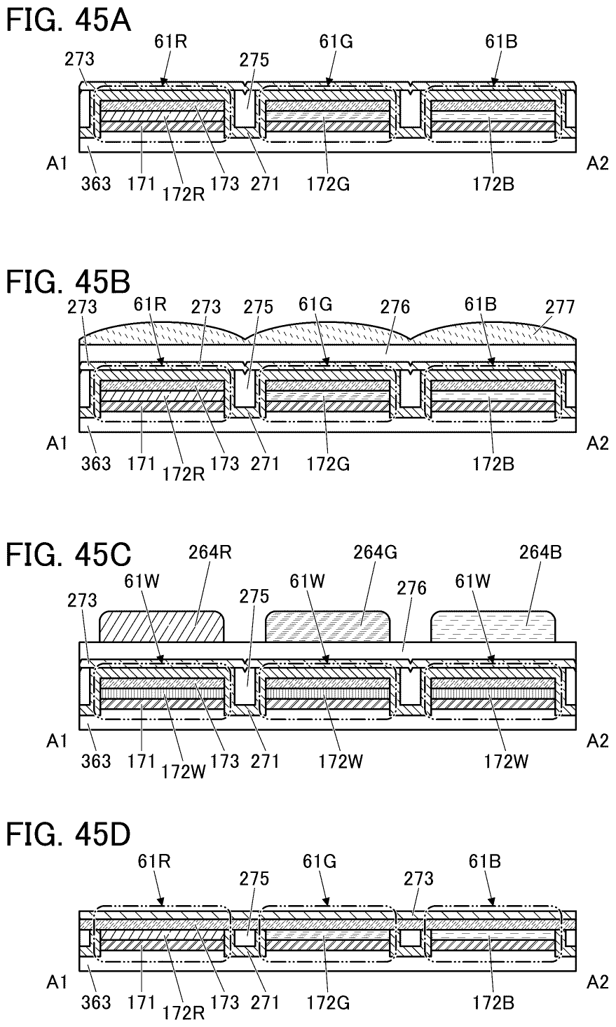

FIG. 45A illustrates an example different from the above. Specifically, the structure illustrated in FIG. 45A is different from the structure illustrated in FIG. 44D in the structure of the insulator 363. The planar surface of the insulator 363 is partly removed when the light-emitting element 61R, the light-emitting element 61G, and the light-emitting element 61B are processed, so that the insulator 363 has a depressed portion. In addition, the protective layer 271 is formed in the depressed portion. In other words, in the cross-sectional view, a region is provided in which the bottom surface of the protective layer 271 is positioned below the bottom surface of the conductor 171. With the region, impurities (typically, water or the like) can be inhibited from entering the light-emitting element 61R, the light-emitting element 61G, and the light-emitting element 61B from below. Note that the depressed portion can be formed when impurities (also referred to as residue) that could be attached to the side surfaces of the light-emitting element 61R, the light-emitting element 61G, and the light-emitting element 61B in processing of the light-emitting elements are removed by wet etching or the like. After the residue is removed, the side surfaces of the light-emitting elements are covered with the protective layer 271, whereby a highly reliable display device can be provided.

FIG. 45B illustrates an example different from the above. Specifically, the structure illustrated in FIG. 45B includes an insulator 276 and a microlens array 277 in addition to the structure illustrated in FIG. 45A. The insulator 276 functions as an adhesive layer. Note that when the refractive index of the insulator 276 is lower than that of the microlens array 277, the microlens array 277 can condense light emitted from the light-emitting element 61R, the light-emitting element 61G, and the light-emitting element 61B. This can increase the light extraction efficiency of the display device. In particular, this is suitable because a user can see bright images when the user sees the display surface from the front of the display device. As the insulator 276, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, polyimide, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component resin may be used. An adhesive sheet or the like may be used.

FIG. 45C illustrates an example different from the above. Specifically, the structure illustrated in FIG. 45C includes three light-emitting elements 61 W instead of the light-emitting element 61R, the light-emitting element 61G, and the light-emitting element 61B in the structure illustrated in FIG. 45A. In addition, the insulator 276 is provided above the three light-emitting elements 61 W, and the coloring layer 264R, the coloring layer 264G, and the coloring layer 264B are provided above the insulator 276. Specifically, the coloring layer 264R that transmits red light is provided at a position overlapping with the light-emitting element 61 W on the left, the coloring layer 264G that transmits green light is provided at a position overlapping with the light-emitting element 61 W in the middle, and the coloring layer 264B that transmits blue light is provided at a position overlapping with the light-emitting element 61 W on the right. Thus, the semiconductor device can display an image with colors. The structure illustrated in FIG. 45C is also a modification example of the structure illustrated in FIG. 44C.

FIG. 45D illustrates an example different from the above. Specifically, in the structure illustrated in FIG. 45D, the protective layer 271 is provided adjacent to the side surfaces of the conductor 171 and the EL layer 172. The conductor 173 is provided as a continuous layer shared by the light-emitting elements. In the structure illustrated in FIG. 45D, the region 275 is preferably filled with a filler.

The color purity of emitted light can be increased when the light-emitting element 61 has a microcavity structure. In order that the light-emitting element 61 has a microcavity structure, a product of a distance d between the conductor 171 and the conductor 173 and a refractive index n of the EL layer 172 (optical path length) is set to m times half of a wavelength λ (m is an integer greater than or equal to 1). The distance d can be obtained by Formula 1.

$$d = m \times λ / ( 2 \times n ) . \qquad Formula 1$$

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G, in some cases.

To be exact, the distance d is a distance from a reflection region in the conductor 171 functioning as a reflective electrode to a reflection region in the conductor 173 functioning as an electrode having properties of transmitting and reflecting emitted light (a transflective electrode). For example, in the case where the conductor 171 is a stack of silver and ITO (Indium Tin Oxide) that is a transparent conductive film and the ITO is positioned on the EL layer 172 side, the distance d suitable for the emission color can be set by adjusting the thickness of the ITO. That is, even when the EL layer 172R, the EL layer 172G, and the EL layer 172B have the same thickness, the distance d suitable for the emission color can be obtained by changing the thickness of the ITO.

However, it is sometimes difficult to determine the exact position of the reflection region in each of the conductor 171 and the conductor 173. In that case, it is assumed that the effect of the microcavity can be fully obtained with a certain position in each of the conductor 171 and the conductor 173 being supposed as the reflection region.

The light-emitting element 61 includes a hole-injection layer, a hole-transport layer, a light-emitting layer, an electron-transport layer, an electron-injection layer, and the like. A specific structural example of the light-emitting element 61 is described in another embodiment. In order to increase the light extraction efficiency in the microcavity structure, the optical path length from the conductor 171 functioning as a reflective electrode to the light-emitting layer is preferably set to an odd multiple of λ/4. In order to achieve this optical path length, the thicknesses of the layers in the light-emitting element 61 are preferably adjusted as appropriate.

In the case where light is emitted to the conductor 173 side, the reflectance of the conductor 173 is preferably higher than the transmittance thereof. The light transmittance of the conductor 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductor 173 is set low (the reflectance is set high), the effect of the microcavity can be enhanced.

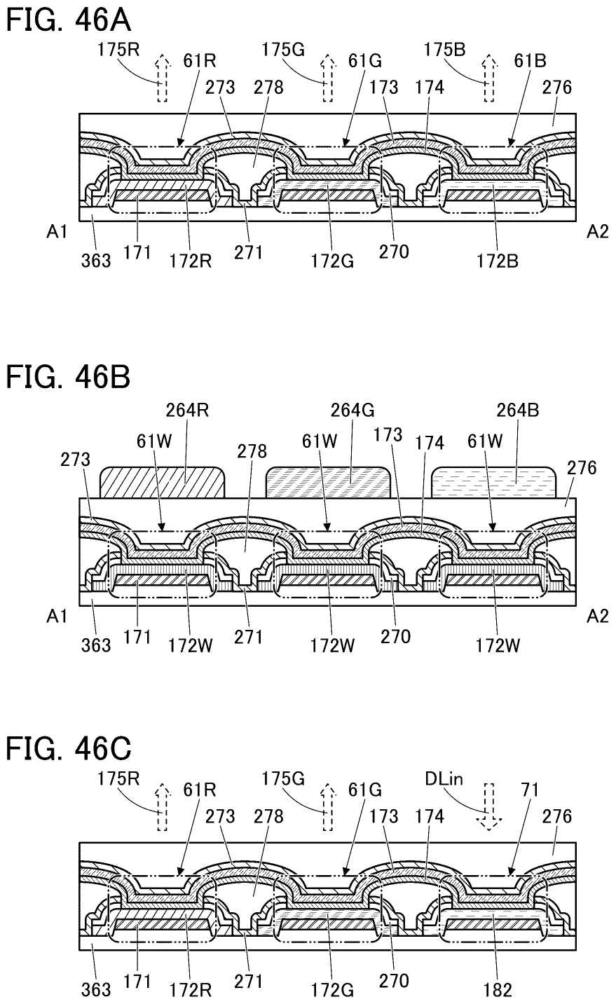

FIG. 46A illustrates an example different from the above. Specifically, in the structure illustrated in FIG. 46A, the EL layer 172 extends beyond the end portions of the conductor 171 in each of the light-emitting element 61R, the light-emitting element 61G, and the light-emitting element 61B. For example, in the light-emitting element 61R, the EL layer 172R extends beyond the end portions of the conductor 171. In the light-emitting element 61G, the EL layer 172G extends beyond the end portions of the conductor 171. In the light-emitting element 61B, the EL layer 172B extends beyond the end portions of the conductor 171.

The light-emitting element 61R, the light-emitting element 61G, and the light-emitting element 61B each include a region where the EL layer 172 overlaps with the protective layer 271 with an insulator 270 therebetween. In a region between adjacent light-emitting elements 61, an insulator 278 is provided over the protective layer 271.

Examples of the insulator 278 include an epoxy resin, an acrylic resin, a silicone resin, a phenol resin, polyimide, a PVC (polyvinyl chloride) resin, a PVB (polyvinyl butyral) resin, and an EVA (ethylene vinyl acetate) resin. Alternatively, a photoresist may be used as the insulator 278. The photoresist used as the insulator 278 may be a positive photoresist or a negative photoresist.

A common layer 174 is provided over the light-emitting element 61R, the light-emitting element 61G, the light-emitting element 61B, and the insulator 278, and the conductor 173 is provided over the common layer 174. The common layer 174 includes a region in contact with the EL layer 172R, a region in contact with the EL layer 172G, and a region in contact with the EL layer 172B. The common layer 174 is shared by the light-emitting element 61R, the light-emitting element 61G, and the light-emitting element 61B.

As the common layer 174, one or more of a hole-injection layer, a hole-transport layer, a hole-blocking layer, an electron-blocking layer, an electron-transport layer, and an electron-injection layer can be used. For example, the common layer 174 may be a carrier-injection layer (a hole-injection layer or an electron-injection layer). The common layer 174 can also be regarded as part of the EL layer 172. Note that the common layer 174 is provided as necessary. In the case where the common layer 174 is provided, a layer having the same function as the common layer 174 among the layers included in the EL layer 172 is not necessarily provided.

The protective layer 273 is provided over the conductor 173, and the insulator 276 is provided over the protective layer 273.

FIG. 46B illustrates an example different from the above. Specifically, the structure illustrated in FIG. 46B includes three light-emitting elements 61 W instead of the light-emitting element 61R, the light-emitting element 61G, and the light-emitting element 61B in the structure illustrated in FIG. 46A. In addition, the insulator 276 is provided above the three light-emitting elements 61 W, and the coloring layer 264R, the coloring layer 264G, and the coloring layer 264B are provided above the insulator 276. Specifically, the coloring layer 264R that transmits red light is provided at a position overlapping with the light-emitting element 61 W on the left, the coloring layer 264G that transmits green light is provided at a position overlapping with the light-emitting element 61 W in the middle, and the coloring layer 264B that transmits blue light is provided at a position overlapping with the light-emitting element 61 W on the right. Thus, the semiconductor device can display an image with colors. The structure illustrated in FIG. 46B is also a modification example of the structure illustrated in FIG. 45C.

As illustrated in FIG. 46C, the light-emitting element 61R, the light-emitting element 61G, and a light-receiving element 71 may be provided over the insulator 363. The light-receiving element 71 illustrated in FIG. 46C can be obtained by replacing the EL layer 172 of the light-emitting element 61 with an active layer 182 (also referred to as a “light-receiving layer”) functioning as a photoelectric conversion layer. The active layer 182 has a function of changing a resistance value depending on the wavelength and intensity of the incident light. The active layer 182 can be formed with an organic compound similar to that of the EL layer 172. Note that an inorganic material such as silicon may be used for the active layer 182.

The light-receiving element 71 has a function of detecting light DLin entering from the outside of the display device through the protective layer 273, the conductor 173, and the common layer 174. A coloring layer transmitting light in a given wavelength range may be provided on the incident side of the light DLin so as to overlap with the light-receiving element 71.

The structure described in this embodiment can be used in an appropriate combination with the structures described in the other embodiments.

### Embodiment 6

In this embodiment, electronic devices in which the display device of one embodiment of the present invention that is described in the above embodiment can be used will be described.

The display device of one embodiment of the present invention can be used in a display portion of an electronic device. Thus, an electronic device with high display quality can be obtained. Alternatively, an electronic device with an extremely high resolution can be obtained. Alternatively, an electronic device with high reliability can be obtained.

Examples of electronic devices including the display device, the shift register, the signal output circuit, or the like of one embodiment of the present invention include display devices such as televisions and monitors, lighting devices, desktop or laptop personal computers, word processors, image reproduction devices which reproduce still images or moving images stored in recording media such as DVDs (Digital Versatile Discs), portable CD players, radios, tape recorders, headphone stereos, stereos, table clocks, wall clocks, cordless phone handsets, transceivers, car phones, cellular phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, tools such as chain saws, smoke detectors, and medical equipment such as dialyzers. Other examples include industrial equipment such as guide lights, traffic lights, conveyor belts, elevators, escalators, industrial robots, power storage systems, and power storage devices for leveling the amount of power supply and smart grid. In addition, moving objects and the like driven by fuel engines or electric motors using electric power from power storage units may also be included in the category of electronic devices. Examples of the moving objects include electric vehicles (EVs), hybrid electric vehicles (HVs) that include both an internal-combustion engine and a motor, plug-in hybrid electric vehicles (PHVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic device may include a secondary battery (a battery), and it is preferable that the secondary battery be capable of being charged by contactless power transmission.

Examples of the secondary battery include a lithium-ion secondary battery, a nickel-hydride battery, a nickel-cadmium battery, an organic radical battery, a lead-acid battery, an air secondary battery, a nickel-zinc battery, and a silver-zinc battery.

The electronic device may include an antenna. With the antenna receiving a signal, the electronic device can display a video, information, and the like on the display portion. When the electronic device includes an antenna and a secondary battery, the antenna may be used for contactless power transmission.

The electronic device may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, a gradient, oscillation, odor, or infrared rays).

The electronic device including the display device, the shift register, the signal output circuit, or the like of one embodiment of the present invention can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device including a plurality of display portions can have a function of displaying image information mainly on one display portion while displaying text information mainly on another display portion, a function of displaying a three-dimensional image by displaying images on a plurality of display portions with parallax taken into account, or the like. Furthermore, an electronic device including an image receiving portion can have a function of taking a still image or a moving image, a function of automatically or manually correcting a taken image, a function of storing a taken image in a recording medium (an external recording medium or a recording medium incorporated in the electronic device), a function of displaying a taken image on a display portion, or the like. Note that functions of the electronic device of one embodiment of the present invention are not limited thereto, and the electronic device can have a variety of functions.

The display device including the display device, the shift register, the signal output circuit, or the like of one embodiment of the present invention can display a high-resolution image. Thus, the display device is suitable especially for a portable electronic device, a wearable electronic device (wearable device), an e-book reader, and the like. For example, the display device is suitable for VR (Virtual Reality) devices, AR (Augmented Reality) devices, or the like.

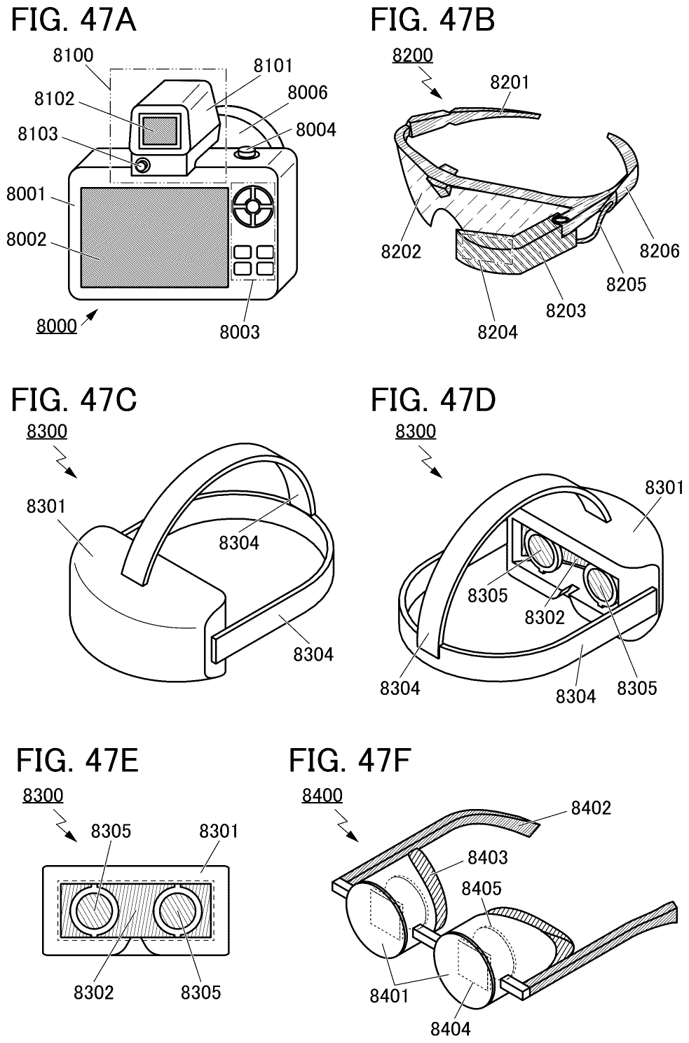

FIG. 47A is a diagram illustrating the appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing may be integrated with each other in the camera 8000.

Images can be taken with the camera 8000 at the press of the shutter button 8004 or the touch of the display portion 8002 functioning as a touch panel.

The housing 8001 includes a mount including an electrode, so that the finder 8100, a stroboscope, or the like can be connected to the housing 8001.

The finder 8100 includes a housing 8101, a display portion 8102, a button 8103, and the like.

The housing 8101 is attached to the camera 8000 with a mount engaging with the mount of the camera 8000. The finder 8100 can display, for example, a video received from the camera 8000 on the display portion 8102.

The button 8103 has a function of a power supply button or the like.

The display device of one embodiment of the present invention can be used in the display portion 8002 of the camera 8000 and the display portion 8102 of the finder 8100. Note that the finder 8100 may be incorporated in the camera 8000.

FIG. 47B is a diagram illustrating the appearance of a head-mounted display 8200.

The head-mounted display 8200 includes a wearing portion 8201, a lens 8202, a main body 8203, a display portion 8204, a cable 8205, and the like. A battery 8206 is incorporated in the wearing portion 8201.

The cable 8205 supplies electric power from the battery 8206 to the main body 8203. The main body 8203 includes a wireless receiver or the like to receive video data and display it on the display portion 8204. The main body 8203 includes a camera, and data on the movement of eyeballs or eyelids of a user can be used as an input means.

The wearing portion 8201 may be provided with a plurality of electrodes capable of detecting current flowing in response to the movement of the user's eyeball in a position in contact with the user to have a function of recognizing the user's sight line. Furthermore, the wearing portion 8201 may have a function of monitoring the user's pulse with use of the current flowing through the electrodes. The wearing portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, or the like. The display device of one embodiment of the present invention can be used in the display portion 8204.

FIG. 47C to FIG. 47E are diagrams illustrating the appearance of a head-mounted display 8300. The head-mounted display 8300 includes a housing 8301, a display portion 8302, a band-like fixing member 8304, and a pair of lenses 8305.

A user can see display on the display portion 8302 through the lenses 8305. Note that the display portion 8302 is preferably placed in the curved state, in which case the user can feel a high realistic sensation. When another image displayed in another region of the display portion 8302 is seen through the lenses 8305, three-dimensional display using parallax or the like can be performed. Note that the structure is not limited to the structure in which one display portion 8302 is provided; two display portions 8302 may be provided so that one display portion is provided per eye of the user.

The display device of one embodiment of the present invention can be used in the display portion 8302. The display device of one embodiment of the present invention can achieve an extremely high resolution. For example, a pixel is not easily seen by the user even when the user sees display that is magnified with use of the lenses 8305 as illustrated in FIG. 47E. In other words, a video with a strong sense of reality can be seen by the user with use of the display portion 8302.

FIG. 47F is a diagram illustrating the appearance of a goggles-type head-mounted display 8400. The head-mounted display 8400 includes a pair of housings 8401, a wearing portion 8402, and a cushion 8403. A display portion 8404 and a lens 8405 are provided in each of the pair of housings 8401. The display device of one embodiment of the present invention can be used in the display portion 8404. When the pair of display portions 8404 display different images, three-dimensional display using parallax can be performed.

A user can see display on the display portion 8404 through the lens 8405. The lens 8405 has a focus adjustment mechanism and can adjust the position according to the user's eyesight.

The display portion 8404 is preferably a square or a horizontal rectangle. This can improve a realistic sensation.

The wearing portion 8402 preferably has plasticity and elasticity so as to be adjusted to fit the size of the user's face and not to slide down. In addition, part of the wearing portion 8402 preferably has a vibration mechanism functioning as a bone conduction earphone. Thus, without additionally requiring an audio device such as earphones or a speaker, the user can enjoy video and sound only by wearing the head-mounted display 8400. Note that the housing 8401 may have a function of outputting sound data by wireless communication.

The wearing portion 8402 and the cushion 8403 are portions to be in contact with the user's face (forehead, cheek, or the like). When the cushion 8403 is in close contact with the user's face, light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. When a sponge or the like whose surface is covered with cloth, leather (natural leather or synthetic leather), or the like is used, a gap is unlikely to be generated between the user's face and the cushion 8403, whereby light leakage can be prevented. Using such a material is preferable because it has a soft texture and the user does not feel cold when wearing the head-mounted display 8400 in a cold season, for example. The member to be in contact with the user's skin, such as the cushion 8403 or the wearing portion 8402, is preferably detachable, in which case cleaning or replacement can be easily performed.

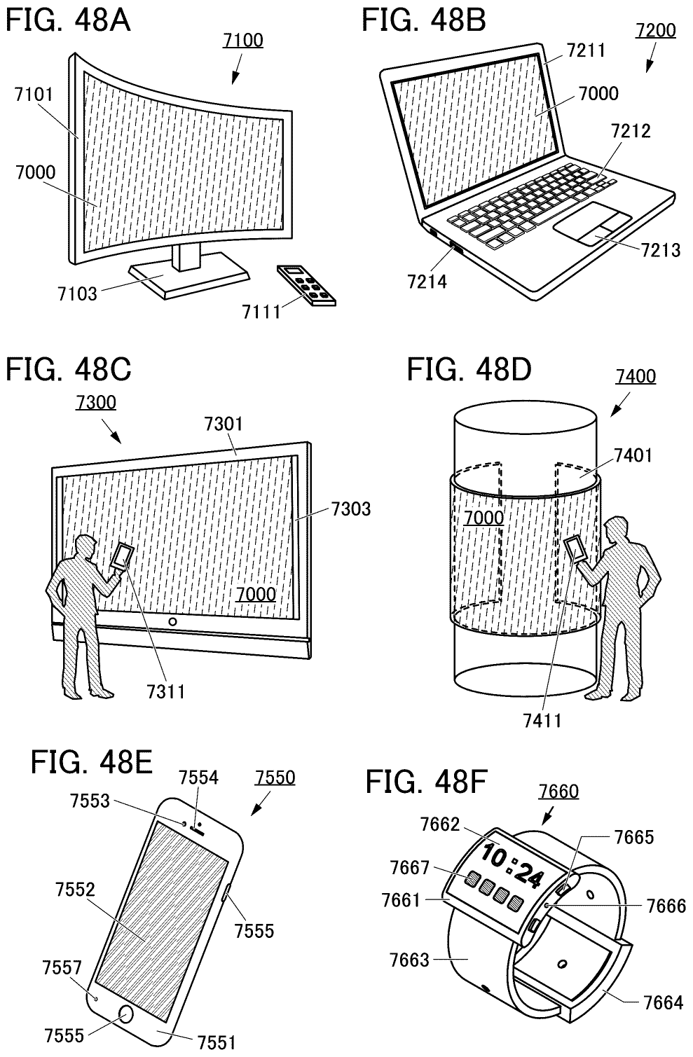

FIG. 48A illustrates an example of a television device. In a television device 7100, a display portion 7000 is incorporated in a housing 7101. Here, a structure in which the housing 7101 is supported by a stand 7103 is illustrated. The display device of one embodiment of the present invention can be used in the display portion 7000.

Operation of the television device 7100 illustrated in FIG. 48A can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 48B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated. The display device of one embodiment of the present invention can be used in the display portion 7000.

FIG. 48C and FIG. 48D illustrate examples of digital signage.

Digital signage 7300 illustrated in FIG. 48C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 48D is digital signage 7400 attached to a cylindrical pillar 7401. The digital signage 7400 includes the display portion 7000 provided along a curved surface of the pillar 7401.

In FIG. 48C and FIG. 48D, the display device of one embodiment of the present invention can be used in the display portion 7000.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 48C and FIG. 48D, it is preferable that the digital signage 7300 or the digital signage 7400 be capable of working with an information terminal device 7311 or an information terminal device 7411 such as a smartphone a user has through wireless communication. For example, information of an advertisement displayed on the display portion 7000 can be displayed on a screen of the information terminal device 7311 or the information terminal device 7411. By operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

An information terminal 7550 illustrated in FIG. 48E includes a housing 7551, a display portion 7552, a microphone 7557, a speaker portion 7554, a camera 7553, operation switches 7555, and the like. The display device of one embodiment of the present invention can be used in the display portion 7552. The display portion 7552 has a function of a touch panel. In addition, the information terminal 7550 includes an antenna, a battery, and the like inside the housing 7551. The information terminal 7550 can be used as, for example, a smartphone, a mobile phone, a tablet information terminal, a tablet personal computer, an e-book reader, or the like.

FIG. 48F illustrates an example of a watch-type information terminal. An information terminal 7660 includes a housing 7661, a display portion 7662, a band 7663, a buckle 7664, an operation switch 7665, an input/output terminal 7666, and the like. In addition, the information terminal 7660 includes an antenna, a battery, and the like inside the housing 7661. The information terminal 7660 is capable of executing a variety of applications such as mobile phone calls, e-mailing, viewing and creating texts, music reproduction, Internet communication, and a computer game.

The display portion 7662 includes a touch sensor, and operation can be performed by touching the screen with a finger, a stylus, or the like. For example, with a touch on an icon 7667 displayed on the display portion 7662, an application can be started. The operation switch 7665 can have a variety of functions such as time setting, power on/off operation, on/off operation of wireless communication, setting and cancellation of a silent mode, and setting and cancellation of a power saving mode. For example, the functions of the operation switch 7665 can be set by an operating system incorporated in the information terminal 7660.

The information terminal 7660 can execute near field communication conformable to a communication standard. For example, mutual communication with a headset capable of wireless communication enables hands-free calling. The information terminal 7660 includes the input/output terminal 7666, and can perform data transmission and reception with another information terminal through the input/output terminal 7666. In addition, charging can be performed via the input/output terminal 7666. Note that the charging operation may be performed by wireless power feeding without using the input/output terminal 7666.

The structure described in this embodiment can be used in an appropriate combination with the structures described in the other embodiments.

### EXAMPLE

The transistor 10 described with reference to FIG. 11 and the like was fabricated, and the transistor characteristics thereof were measured. This example shows measurement results of the transistor characteristics of the transistor 10 fabricated.

Table 1 shows the stacked-layer structure of the transistor fabricated. As the opening 159, an opening with a diameter of 2 μm was formed.

TABLE 1

| Layer | Material | Thickness | |
|---|---|---|---|
| Insulating layer 164 | Silicon nitride | 300 | nm |
| Conductive layer 163 | Ti\Al\Ti | 50\200\50 | nm |
| Insulating layer 162 | Silicon oxynitride | 100 | nm |
| Semiconductor layer 161 | IGZO(1:1:1) | 20 | nm |
| Conductive layer 160 | ITSO | 100 | nm |
| Insulating layer 158 | Silicon nitride | 30 | nm |
| Insulating layer 157 | Silicon oxynitride | 500 | nm |
| Insulating layer 156 | Silicon nitride | 30 | nm |
| Conductive layer 155 | ITSO | 100 | nm |

Specifically, a 100-nm-thick ITSO film was formed over a substrate by a sputtering method, a resist mask was formed over the ITSO film by a photolithography method, and the ITSO film was selectively removed using the resist mask as a mask, whereby the conductive layer 155 was formed. After the conductive layer 155 was formed, the resist mask was removed.

Next, a 30-nm-thick silicon nitride film was formed as the insulating layer 156 over the conductive layer 155 by a CVD method, a 500-nm-thick silicon oxynitride film was formed as the insulating layer 157 over the insulating layer 156 by a CVD method, and a 30-nm-thick silicon nitride film was formed as the insulating layer 158 over the insulating layer 157 by a CVD method.

Next, a 100-nm-thick ITSO film was formed over the insulating layer 158 by a sputtering method, a resist mask was formed over the ITSO film by a photolithography method, and the ITSO film was selectively removed using the resist mask as a mask, whereby the conductive layer 160 was formed. After the conductive layer 160 was formed, the resist mask was removed.

Next, a resist mask was formed over the conductive layer 160 and the insulating layer 158 by a photolithography method, and the conductive layer 160, the insulating layer 158, the insulating layer 157, and the insulating layer 156 were selectively removed using the resist mask as a mask, whereby the opening 159 was formed. After the opening 159 was formed, the resist mask was removed.

Next, a 20-nm-thick IGZO film with an atomic ratio of metal elements of In:Ga:Zn=1:1:1 was formed over the opening 159, the conductive layer 160, and the insulating layer 158 by a sputtering method. Then, a resist mask was formed over the IGZO film by a photolithography method, and the IGZO film was selectively removed using the resist mask as a mask, whereby the semiconductor layer 161 was formed.

Next, a 100-nm-thick silicon oxynitride film was formed as the insulating layer 162 over the semiconductor layer 161, the conductive layer 160, and the insulating layer 158 by a CVD method.

Next, a 50-nm-thick titanium (Ti) film, a 200-nm-thick aluminum (Al) film, and a 50-nm-thick titanium (Ti) film were sequentially stacked as metal films over the insulating layer 162. Next, a resist mask was formed over the metal films by a photolithography method, and the metal films were selectively removed using the resist mask as a mask, whereby the conductive layer 163 was formed.

Next, a 300-nm-thick silicon nitride film was formed as the insulating layer 164 over the conductive layer 163 and the insulating layer 162 by a CVD method.

In the transistor 10 that is a VFET, one of the conductive layer 155 and the conductive layer 160 is used as a source, and the other is used as a drain. In that case, the transistor characteristics may change depending on which of the conductive layer 155 and the conductive layer 160 is used as the source.

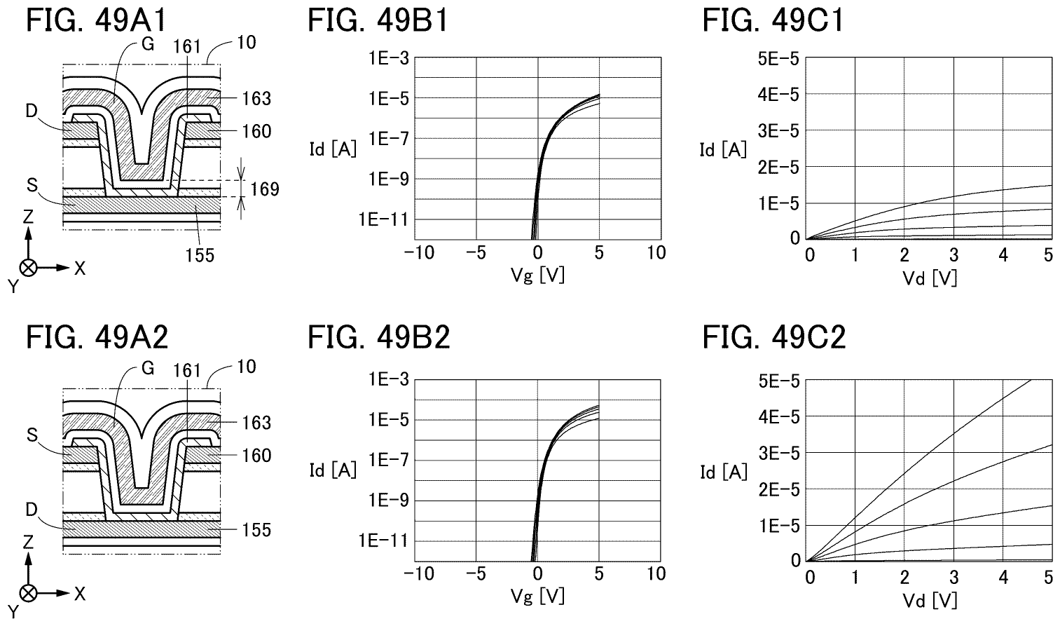

FIG. 49A1 and FIG. 49A2 illustrate schematic cross-sectional views of the transistor 10. FIG. 49B1, FIG. 49C1, FIG. 49B2, and FIG. 49C2 show measurement results of the transistor characteristics of the transistor 10 fabricated.

FIG. 49B1 and FIG. 49C1 show the transistor characteristics of the transistor 10 in the case where the conductive layer 163 was used as a gate (G), the conductive layer 155 was used as the source(S), and the conductive layer 160 was used as the drain (D) (see FIG. 49A1). FIG. 49B2 and FIG. 49C2 show the transistor characteristics of the transistor 10 in the case where the conductive layer 163 was used as the gate (G), the conductive layer 155 was used as the drain (D), and the conductive layer 160 was used as the source(S) (see FIG. 49A2).

FIG. 49B1 and FIG. 49B2 show Id-Vg characteristics, which are a kind of transistor characteristics. In each of FIG. 49B1 and FIG. 49B2, the horizontal axis represents the gate voltage (Vg), and the vertical axis logarithmically represents the drain current (Id). In addition, FIG. 49B1 and FIG. 49B2 each show Id-Vg characteristics measured at five levels of potential differences between the drain and the source (also referred to as “drain voltage” or “Vd”) set to 1 V, 2 V, 3 V, 4 V, and 5 V.

FIG. 49C1 and FIG. 49C2 show Id-Vd characteristics, which are a kind of transistor characteristics. In each of FIG. 49C1 and FIG. 49C2, the horizontal axis represents the drain voltage (Vd), and the vertical axis represents Id. In addition, FIG. 49C1 and FIG. 49C2 each show Id-Vd characteristics measured at five levels of Vg set to 1 V, 2 V, 3 V, 4 V, and 5 V.

Both the Id-Vg characteristics in FIG. 49B1 and FIG. 49B2 and the Id-Vd characteristics in FIG. 49C1 and FIG. 49C2 show that the on-state current Id is increased in the case where the conductive layer 155 is used as the drain and the conductive layer 160 is used as the source. Specifically, the on/off ratio of the transistor 10 is improved (see FIG. 49B1 and FIG. 49B2) and the resistance between the source and the drain of the transistor in the on state (also referred to as “on-state resistance”) is decreased (see FIG. 49C1 and FIG. 49C2) by using the conductive layer 155 as the drain and the conductive layer 160 as the source. It was confirmed that the transistor characteristics of the transistor 10 are improved by using the conductive layer 155 as the drain and the conductive layer 160 as the source.

The asymmetry of the transistor characteristics in which the on-state current changes when the source and the drain are interchanged with each other is probably attributable to the VFET structure. The top surface of the conductive layer 155 and the bottom surface of the conductive layer 163 are positioned at different levels with respect to the bottom surface of the conductive layer 155, for example (see FIG. 49A1 and the like). Thus, a region 169 not overlapping with the conductive layer 163 functioning as the gate is partly generated in the semiconductor layer 161 at the bottom portion of the opening 159.

Since the region 169 of the semiconductor layer 161 does not overlap with the conductive layer 163, the resistance value of the region 169 is less likely to decrease even when the potential H is supplied to the conductive layer 163. It can be presumed that the use of the conductive layer 155 as the drain leads to DIBL (Drain-induced barrier lowering), thereby decreasing the resistance value of the region 169 and increasing the on-state current.

### REFERENCE NUMERALS

10: transistor, 51: pixel circuit, 53: capacitor, 61: light-emitting element, 62: liquid crystal element, 71: light-receiving element, 100: shift register, 110: signal output circuit, 111: terminal

1. A shift register comprising:
a plurality of signal output circuits comprising a first signal output circuit;
wherein the first signal output circuit comprises a first transistor,
wherein the first signal output circuit is configured to output a first signal through the first; transistor,
wherein the shift register comprises:
a first conductive layer comprising a region being one of a source electrode and a drain electrode of the first transistor;
a first insulating layer comprising a region over the first conductive layer;
a second conductive layer comprising:
a first region being the other of the source electrode and the drain electrode of the first transistor; and
a second region over the first insulating layer;
a first opening penetrating the first insulating layer and the second conductive layer and overlapping with the first conductive layer;
a first semiconductor layer comprising:
a region in contact with the first insulating layer;
a region in contact with the first conductive layer; and
a region in contact with the second conductive layer;
a third conductive layer comprising a region being a gate electrode of the first transistor; and
a second insulating layer comprising:
a region being a gate insulating film of the first transistor; and
a region sandwiched between the first semiconductor layer and the third conductive layer in the first opening, and
wherein the first signal is input to the one of the source electrode and the drain electrode of the first transistor.

2. The shift register according to claim 1, wherein the third conductive layer comprises a region overlapping with the first conductive layer in the first opening and a region overlapping with the second conductive layer over the first insulating layer.

3. The shift register according to claim 1,
wherein the first signal output circuit further comprises a second transistor,
wherein the shift register further comprises:
a fourth conductive layer comprising a region being one of a source electrode and a drain electrode of the second transistor;
a fifth conductive layer comprising:
a region being the other of the source electrode and the drain electrode of the first transistor; and
a region over the first insulating layer;
a second opening penetrating the first insulating layer and the fifth conductive layer and overlapping with the fourth conductive layer;
a second semiconductor layer comprising:
a region in contact with the first insulating layer;
a region in contact with the fourth conductive layer; and
a region in contact with the fifth conductive layer; and
a sixth conductive layer comprising:
a region being a gate electrode of the second transistor; and
a region over the second insulating layer,
wherein the second insulating layer further comprises:
a region being a gate insulating film of the second transistor; and
a region sandwiched between the second semiconductor layer and the sixth conductive layer in the second opening,
wherein the first insulating layer further comprises a region over the fourth conductive layer, and
wherein the fourth conductive layer and the third conductive layer are electrically connected to each other.

4. The shift register according to claim 3, wherein a top surface of the fourth conductive layer and a bottom surface of the sixth conductive layer are at different levels with respect to a bottom surface of the fourth conductive layer.

5. The shift register according to claim 1, wherein the first semiconductor layer comprises an oxide semiconductor.

6. The shift register according to claim 3, wherein the second semiconductor layer comprises an oxide semiconductor.

7. The shift register according to claim 4, wherein the second semiconductor layer comprises an oxide semiconductor.
